(19) United States
(12) Patent Application Publication
(10) Pub. No.: US 2024/0224790 A1
(43) Pub. Date: Jul. 4, 2024

(54) ORGANIC LIGHT EMITTING DIODE

(71) Applicant: LG DISPLAY CO., LTD., Seoul (KR)

(72) Inventor: Ji-Ae LEE, Paju-si (KR)

(73) Assignee: LG DISPLAY CO., LTD., Seoul (KR)

(21) Appl. No.: 18/378,562

(22) Filed: Oct. 10, 2023

(30) Foreign Application Priority Data
Dec. 16, 2022 (KR) 10-2022-0176580

(51) Int. Cl. H10K 85/60; C09K 11/06; H10K 85/30

(52) U.S. Cl. CPC H10K 85/615; C09K 11/06; H10K 85/342; H10K 85/622; H10K 85/654; H10K 85/6572; H10K 85/6574; H10K 85/6576

(57) ABSTRACT

An organic light emitting diode including a first electrode; a second electrode facing the first electrode; and an emissive layer disposed between the first electrode and the second electrode. The emissive layer includes at least one emitting material layer that includes a first compound including a first organic compound represented by Chemical Formula 1, and a second compound including an organometallic compound represented by Chemical Formula 4. The first organic compound may include multiple aromatic and heteroaromatic fused rings. The second compound may be a phosphorescent material. The first compound may have a wide plate-like structure and the first compound may receive efficiently exciton energy from the second compound. The present disclose also relates to an organic light emitting device including the diode. The luminous efficiency, luminous lifespan and color purity of the diode and device may be improved by introducing the first and second compounds into the emissive layer.

### CROSS-REFERENCE TO RELATED APPLICATION

This application claims the benefit of and the priority to Korean Patent Application No. 10-2022-0176580, filed in the Republic of Korea on Dec. 16, 2022, which is expressly incorporated hereby in its entirety into the present application.

### BACKGROUND

### Technical Field

The present disclosure relates to an organic light emitting diode, and more particularly to, an organic light emitting diode that may have beneficial luminous efficiency and luminous lifespan. The present disclosure also relates to an organic light emitting device including the diode.

### Discussion of the Related Art

A flat display device including an organic light emitting diode (OLED) has attracted attention as a display device that may replace a liquid crystal display device (LCD). The electrode configurations in the OLED may implement unidirectional or bidirectional images. Also, the OLED may be formed even on a flexible transparent substrate such as a plastic substrate so that a flexible or a foldable display device may be realized with ease using the OLED. In addition, the OLED may be driven at a lower voltage and the OLED has advantageous high color purity compared to the LCD.

Since fluorescent material uses only singlet excitons in the luminous process, the fluorescent material in the related art shows low luminous efficiency. On the contrary, phosphorescent material may show high luminous efficiency since it uses triplet exciton as well as singlet excitons in the luminous process. However, examples of phosphorescent material include metal complexes, which have a short luminous lifespan for commercial use. It may be necessary to develop a compound or an organic light emitting diode having improved luminous efficiency and luminous lifespan.

### SUMMARY

Accordingly, embodiments of the present disclosure are directed to an organic light emitting diode and an organic light emitting device that substantially obviate one or more of the problems due to the limitations and disadvantages of the related art.

An object of the present disclosure is to provide an organic light emitting diode having beneficial luminous efficiency and advantageous luminous lifespan, and an organic light emitting device including the diode.

Additional features and objects will be set forth in the description that follows, and in part will be apparent from the description, or may be learned by practice of the disclosed concepts provided herein. Other features and aspects of the disclosed concept may be realized and attained by the structure particularly pointed out in the written description, or derivable therefrom, and the claims hereof as well as the appended drawings.

To achieve these and other advantages and in accordance with objects of the disclosure, as embodied and broadly described, an organic light emitting diode includes a first electrode; a second electrode facing the first electrode; and an emissive layer disposed between the first electrode and the second electrode, the emissive layer including at least one emitting material layer that includes a first compound including a first organic compound represented by Chemical Formula 1, and a second compound including an organometallic compound represented by Chemical Formula 4:

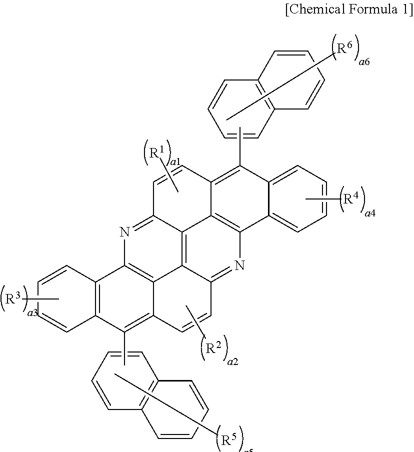

wherein, in the Chemical Formula 1,
each of R¹, R², R³, R⁴, R⁵, and R⁶ is independently a halogen atom, a cyano group, an unsubstituted or substituted C₁-C₂₀ alkyl group, an unsubstituted or substituted C₁-C₂₀ alkyl amino group, an unsubstituted or substituted C₆-C₃₀ aryl group, an unsubstituted or substituted C₃-C₃₀ heteroaryl group, an unsubstituted or substituted C₆-C₃₀ aryl amino group or an unsubstituted or substituted C₃-C₃₀ heteroaryl amino group, where each R¹ is identical to or different from each other when a1 is 2, each R² is identical to or different from each other when a2 is 2, each R³ is identical to or different from each other when a3 is 2, 3 or 4, each R⁴ is identical to or different from each other when a4 is 2, 3 or 4, each R⁵ is identical to or different from each other when a5 is 2, 3, 4, 5, 6 or 7, and each R⁶ is identical to or different from each other when a6 is 2, 3, 4, 5, 6 or 7;
each of a1 and a2 is independently 0, 1 or 2;
each of a3 and a4 is independently 0, 1, 2, 3 or 4; and
each of a5 and a6 is independently 0, 1, 2, 3, 4, 5, 6 or 7,

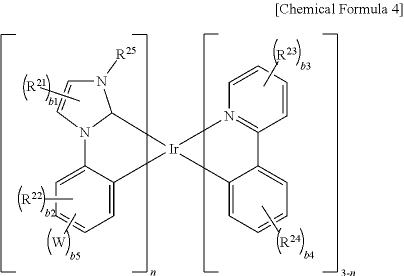

wherein, in the Chemical Formula 4,
each of R²¹, R²², R²³, and R²⁴ is independently an unsubstituted or substituted C₁-C₂₀ alkyl group, an unsubstituted or substituted C₁-C₂₀ alkyl amino group, an unsubstituted or substituted C₆-C₃₀ aryl group, an unsubstituted or substituted C₃-C₃₀ heteroaryl group, an unsubstituted or substituted C₆-C₃₀ aryl amino group or an unsubstituted or substituted C₃-C₃₀ heteroaryl amino group, where each R²¹ is identical to or different from each other when b1 is 2, each R²² is identical to or different from each other when b2 is 2 or 3, each R²³ is identical to or different from each other when b3 is 2, 3 or 4, and each R²⁴ is identical to or different from each other when b4 is 2, 3 or 4, or
optionally, two adjacent R²¹ are linked together to form an unsubstituted or substituted C₆-C₂₀ aromatic ring or an unsubstituted or substituted C₃-C₂₀ heteroaromatic ring when b1 is 2, two adjacent R²² are linked together to form an unsubstituted or substituted C₆-C₂₀ aromatic ring or an unsubstituted or substituted C₃-C₂₀ heteroaromatic ring when b2 is 2 or 3, two adjacent R²³ are linked together to form an unsubstituted or substituted C₆-C₂₀ aromatic ring or an unsubstituted or substituted C₃-C₂₀ heteroaromatic ring when b3 is 2, 3 or 4, and/or two adjacent R²⁴ are linked together to form an unsubstituted or substituted C₆-C₂₀ aromatic ring or an unsubstituted or substituted C₃-C₂₀ heteroaromatic ring when b4 is 2, 3 or 4;
R²⁵ is hydrogen or an unsubstituted or substituted C₁-C₂₀ alkyl group;
W is a cyano group, a nitro group, a halogen atom, a C₁-C₂₀ alkyl group, a C₆-C₃₀ aryl group or a C₃-C₃₀ heteroaryl group, where each of the C₁-C₂₀ alkyl group, the C₆-C₃₀ aryl group, and the C₃-C₃₀ heteroaryl group is optionally substituted with at least one group selected from a cyano group, a nitro group, and a halogen atom;
b1 is 0, 1 or 2;
b2 is 0, 1, 2 or 3;
each of b3 and b4 is independently 0, 1, 2, 3 or 4;
b5 is 1 or 2, where b2+b5=1, 2, 3 or 4; and
n is 1, 2 or 3.

In some embodiments, the first organic compound may be represented by Chemical Formula 2A or Chemical Formula 2B:

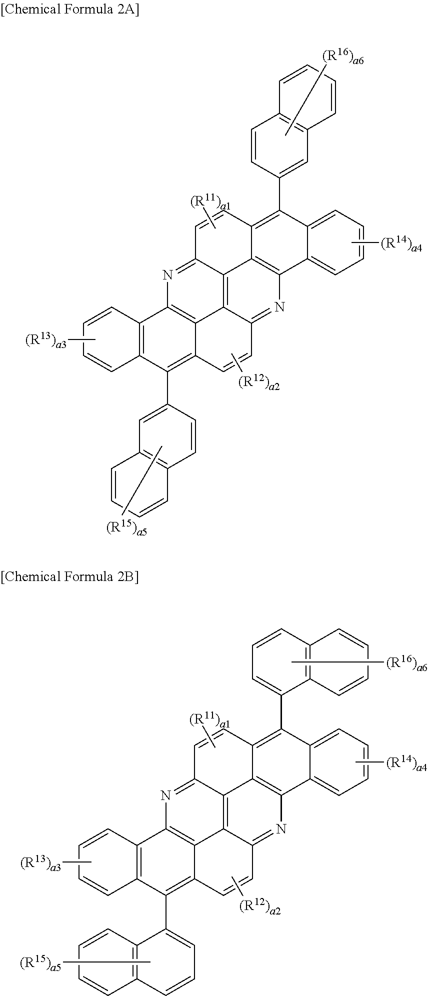

wherein, in the Chemical Formulae 2A and 2B,
each of a1, a2, a3, a4, a5, and a6 is as defined in Chemical Formula 1, each of R¹¹, R¹², R¹³, R¹⁴, R¹⁵ and R¹⁶ is independently an unsubstituted or a substituted C₁-C₁₀ alkyl group or an unsubstituted or C₁-C₁₀ alkyl-substituted C₆-C₃₀ aryl group, where each R¹¹ is identical to or different from each other when a1 is 2, each R¹² is identical to or different from each other when a2 is 2, each R¹³ is identical to or different from each other when a3 is 2, 3 or 4, each R¹⁴ is identical to or different from each other when a4 is 2, 3 or 4, each R¹⁵ is identical to or different from each other when a5 is 2, 3, 4, 5, 6 or 7, and each R¹⁶ is identical to or different from each other when a6 is 2, 3, 4, 5, 6 or 7.

In some embodiments, each of a1 and a2 may be 0, each of a3, a4, a5, and a6 may be independently 0 or 1, and each of R¹, R², R³, R⁴, R⁵, and R⁶ may be independently a C₁-C₁₀ alkyl or an unsubstituted or C₁-C₁₀ alkyl-substituted C₆-C₃₀ aryl group.

In some embodiments, each of a1 and a2 may be 0, each of R³ and R⁴ may be independently an unsubstituted or C₁-C₁₀ alkyl-substituted C₆-C₃₀ aryl group, each of a3 and a4 may be independently 0 or 1, each of R⁵, and R⁶ may be independently an unsubstituted or a substituted C₁-C₁₀ alkyl group, and each of a5 and a6 may be independently 0 or 1.

In some embodiments, the first organic compound may include at least one of the compounds from Chemical Formula 3.

In some embodiments, the organometallic compound may include at least one of the compounds from Chemical Formula 5.

In some embodiments, the first compound may have an absorption spectrum that overlaps 30% or more of a luminescence spectrum of the second compound.

In some embodiments, the first compound may have a maximum absorption wavelength of about 30 nm or less away from a maximum luminescence wavelength of the second compound.

In some embodiments, the at least one emitting material layer may further include a third compound.

In some embodiments, the third compound may include a second organic compound represented by Chemical Formula 6:

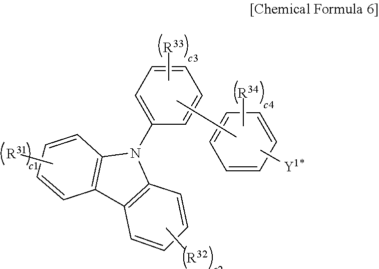

wherein, in the Chemical Formula 6,
each of R³¹ and R³² is independently an unsubstituted or substituted C₁-C₂₀ alkyl group or an unsubstituted or substituted C₆-C₃₀ aryl group, where each R³¹ is identical to or different from each other when c1 is 2, 3 or 4, and each R³² is identical to or different from each other when c2 is 2, 3 or 4;
each of R³³ and R³⁴ is independently an unsubstituted or substituted C₁-C₂₀ alkyl group or an unsubstituted or substituted C₆-C₃₀ aryl group, where each R³³ is identical to or different from each other when c3 is 2, 3 or 4, and each R³⁴ is identical to or different from each other when c4 is 2, 3 or 4, or R³³ or R³⁴ is linked to the adjacent 6-membered aromatic ring to form a heteroring that is optionally substituted with an unsubstituted or substituted C₆-C₃₀ aryl group;
Y¹ is represented by Chemical Formula 7A or Chemical Formula 7B;
each of c1, c2, c3 and c4 is independently 0, 1, 2, 3 or 4; and
an asterisk indicates a link position to the Chemical Formula 7A or Chemical Formula 7B,

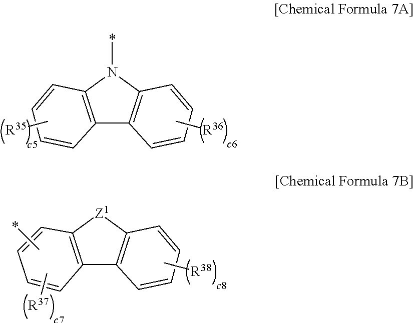

wherein, in the Chemical Formulae 7A and 7B,
each of R³⁵, R³⁶, R³⁷ and R³⁸ is independently an unsubstituted or substituted C₁-C₂₀ alkyl group or an unsubstituted or substituted C₆-C₃₀ aryl group, where each R³⁵ is identical to or different from each other when c5 is 2, 3 or 4, each R³⁶ is identical to or different from each other when c6 is 2, 3 or 4, each R³⁷ is identical to or different from each other when c7 is 2, or 3 and each R³⁸ is identical to or different from each other when c8 is 2, 3 or 4;
Z¹ is NR³⁹, O or S, where R³⁹ is hydrogen, an unsubstituted or substituted C₁-C₂₀ alkyl group or an unsubstituted or substituted C₆-C₃₀ aryl group;
each of c5, c6, and c8 is independently 0, 1, 2, 3 or 4;
c7 is 0, 1, 2 or 3; and
an asterisk indicates a link position to the Chemical Formula 6.

In some embodiments, the second organic compound may include at least one of the compounds from Chemical Formula 8.

In some embodiments, the at least one emitting material layer may further include a fourth compound.

In some embodiments, the fourth compound may include a third organic compound represented by Chemical Formula 9:

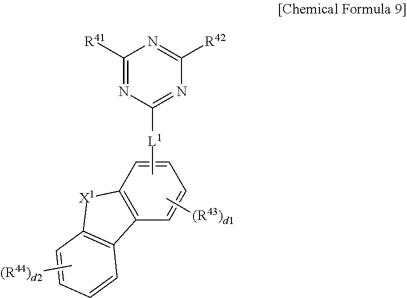

wherein, in the Chemical Formula 9,
X¹ is O or S;
each of R⁴¹, R⁴², R⁴³, and R⁴⁴ is independently an unsubstituted or substituted C₁-C₂₀ alkyl group, an unsubstituted or substituted C₁-C₂₀ alkyl amino group, an unsubstituted or substituted C₆-C₃₀ aryl group, an unsubstituted or substituted C₃-C₃₀ heteroaryl group, an unsubstituted or substituted C₆-C₃₀ aryl amino group or an unsubstituted or substituted C₃-C₃₀ heteroaryl amino group, where each R⁴³ is identical to or different from each other when d1 is 2 or 3, each R⁴⁴ is identical to or different from each other when d2 is 2, 3 or 4, or
optionally,
two adjacent R⁴³ 4 are linked together to form an unsubstituted or substituted C₆-C₂₀ aromatic ring or an unsubstituted or substituted C₃-C₂₀ heteroaromatic ring when d1 is 2 or 3 and/or two adjacent R⁴⁴ 4 are linked together to form an unsubstituted or substituted C₆-C₂₀ aromatic ring or an unsubstituted or substituted C₃-C₂₀ heteroaromatic ring when d2 is 2, 3 or 4;
L¹ is a single bond or an unsubstitued or substituted C₆-C₃₀ arylene group;
d1 is 0, 1, 2 or 3; and
d2 is 0, 1, 2, 3 or 4.

In some embodiments, the third organic compound may be represented by Chemical Formula 10:

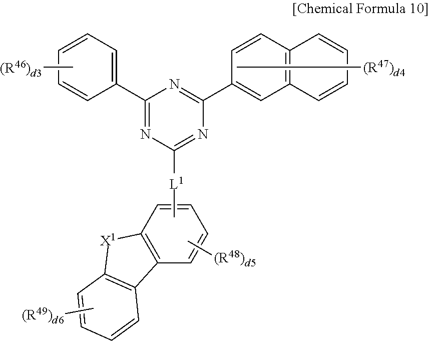

wherein, in the Chemical Formula 10,
each of X¹ and L¹ is as defined in the Chemical Formula 9;
each of R⁴⁶, R⁴⁷, R⁴⁸ and R⁴⁹ is independently an unsubstituted or substituted C₁-C₂₀ alkyl group, an unsubstituted or substituted C₆-C₃₀ aryl group or an unsubstituted or substituted C₃-C₃₀ heteroaryl group, where each R⁴⁶ is identical to or different from each other when d3 is 2, 3, 4 or 5, each R⁴⁷ is identical to or different from each other when d4 is 2, 3, 4, 5, 6 or 7, each R⁴⁸ is identical to or different from each other when d5 is 2 or 3 and each R⁴⁹ is identical to or different from each other when d6 is 2, 3 or 4, or
optionally,
two adjacent R⁴⁶ are linked together to form an unsubstituted or substituted C₆-C₂₀ aromatic ring when d3 is 2, 3, 4 or 5 and/or two adjacent R⁴⁷ are linked together to form an unsubstituted or substituted C₆-C₂₀ aromatic ring when d4 is 2, 3, 4, 5, 6 or 7;
d3 is 0, 1, 2, 3, 4 or 5;
d4 is 0, 1, 2, 3, 4, 5, 6 or 7;
d5 is 0, 1, 2 or 3; and
d6 is 0, 1, 2, 3 or 4.

In some embodiments, the third organic compound may include at least one of the compounds from Chemical Formula 11.

In some embodiments, the emissive layer may have a single emitting part or may have multiple emitting parts to form a tandem structure.

In some embodiments, the emissive layer may include: a first emitting part disposed between the first and second electrodes and including a first emitting material layer; a second emitting part disposed between the first emitting part and the second electrode and including a second emitting material layer; and a first charge generation layer disposed between the first emitting part and the second emitting part, wherein at least one of the first emitting material layer and the second emitting material layer may include the first compound and the second compound.

In some embodiments, the second emitting material layer may be the at least one emitting material layer, and the second emitting material layer may include: a first layer disposed between the first charge generation layer and the second electrode; and a second layer disposed between the first layer and the second electrode, wherein at least one of the first layer and the second layer may include the first compound and the second compound.

In some embodiments, the emissive layer may further include: a third emitting part disposed between the second emitting part and the second electrode and including a third emitting material layer; and a second charge generation layer disposed between the second emitting part and the third emitting part, wherein the second emitting material layer may be the at least one emitting material layer.

In some embodiments, the second emitting material layer may be the at least one emitting material layer, and the second emitting material layer may include: a first layer disposed between the first charge generation layer and the second charge generation layer; and a second layer disposed between the first layer and the second charge generation layer, wherein at least one of the first layer and the second layer may include the first compound and the second compound.

In some embodiments, the first layer of the second emitting material layer may include the first compound and the second compound.

The first compound may have a fused structure including multiple aromatic and/or heteroaromatic rings to have a wide plate-like structure. The emitting material layer may include the second compound having a luminescence wavelength with large overlap degree to the absorption wavelength of the first compound. In some embodiments, the emitting material layer may include the second compound having a luminescence spectrum that overlaps with the absorption spectrum of the first compound. The second compound may transfer exciton energy to the first compound by Forster Resonance Energy Transfer (FRET) mechanism where the singlet exciton of the second compound may be transferred to the singlet exciton of the first compound of the emitter.

The first compound may utilize only the singlet exciton because the first compound may be a fluorescent material. The amount of the singlet exciton, which may be utilized by the first compound and may contribute the emission of the first compound, may be increased as the exciton energy is transferred to the first compound by FRET mechanism that may transfer singlet-singlet exciton energy. The second compound may be a phosphorescent material that may utilize both the singlet exciton and the triplet exciton. The exciton energy may be transferred efficiently to the first compound having beneficial color purity from the second compound having advantageous luminous efficiency. Accordingly, the luminous efficiency, the luminous lifespan and color purity of an organic light emitting diode may be improved by using the second compound as an assistant emitter and the first compound as final emitting material.

It is to be understood that both the foregoing general description and the following detailed description are merely by way of example and explanatory, and are intended to provide further explanation of the inventive concepts as claimed.

### BRIEF DESCRIPTION OF THE DRAWINGS

The accompanying drawings, which are included to provide a further understanding of the disclosure, are incorporated in and constitute a part of this application, illustrate embodiments of the disclosure and together with the description serve to explain principles of the disclosure.

FIG. 1 illustrates a schematic circuit diagram of an organic light emitting display device in accordance with the present disclosure.

FIG. 2 illustrates a schematic cross-sectional view of an organic light emitting display device as an example of an organic light emitting device in accordance with an example embodiment of the present disclosure.

FIG. 3 illustrates a schematic cross-sectional view of an organic light emitting diode having a single emitting part in accordance with an example embodiment of the present disclosure.

FIG. 4 illustrates spectra of luminous materials of lower luminous efficiency with small overlap degree between the absorption spectrum of the first compound and the luminescence spectrum of the second compound.

FIG. 5 illustrates spectra of luminous materials of beneficial luminous efficiency with large overlap degree between the absorption spectrum of the first compound and the luminescence spectrum of the second compound.

FIG. 6 illustrates a schematic cross-sectional view of an organic light emitting display device in accordance with another example embodiment of the present disclosure.

FIG. 7 illustrates a schematic cross-sectional view of an organic light emitting diode with two emitting parts forming a tandem structure in accordance with another example embodiment of the present disclosure.

FIG. 8 illustrates a schematic cross-sectional view of an organic light emitting diode with three emitting parts forming a tandem structure in accordance with another example embodiment of the present disclosure.

### DETAILED DESCRIPTION

Reference will now be made in detail to aspects of the disclosure, examples of which are illustrated in the accompanying drawings. Wherever possible, the same reference numbers will be used throughout the drawings to refer to the same or like parts.

Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure may be sufficiently thorough and complete to assist those skilled in the art to fully understand the scope of the present disclosure. Further, the protected scope of the present disclosure is defined by claims and their equivalents.

The shapes, sizes, ratios, angles, numbers, and the like, which are illustrated in the drawings to describe various example embodiments of the present disclosure, are merely given by way of example. Therefore, the present disclosure is not limited to the illustrations in the drawings. The same or similar elements are designated by the same reference numerals throughout the specification unless otherwise specified.

In the following description, where the detailed description of the relevant known function or configuration may unnecessarily obscure an important point of the present disclosure, a detailed description of such known function of configuration may be omitted.

In the present specification, where the terms “comprise,” “have,” “include,” and the like are used, one or more other elements may be added unless the term, such as “only,” is used. An element described in the singular form is intended to include a plurality of elements, and vice versa, unless the context clearly indicates otherwise.

In construing an element, the element is to be construed as including an error or tolerance range even where no explicit description of such an error or tolerance range is provided.

In the description of the various embodiments of the present disclosure, where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third layer or element may be interposed therebetween.

In describing a temporal relationship, when the temporal order is described as, for example, “after,” “subsequent,” “next,” or “before,” a case which is not continuous may be included unless a more limiting term, such as “just,” “immediate(ly),” or “direct(ly),” is used.

Although the terms “first,” “second,” and the like may be used herein to describe various elements, the elements should not be limited by these terms. These terms are used only to identify one element from another. For example, a first element could be termed a second element, and similarly, a second element could be termed a first element, without departing from the scope of the present disclosure.

Although the terms “first,” “second,” A, B, (a), (b), and the like may be used herein to describe various elements, the elements should not be interpreted to be limited by these terms as they are not used to define a particular order, precedence, or number of the corresponding elements. These terms are used only to identify one element from another.

The expression that an element or layer is “connected” to another element or layer means that the element or layer can not only be directly connected to another element or layer, but also be indirectly connected or adhered to another element or layer with one or more intervening elements or layers “disposed,” or “interposed” between the elements or layers, unless otherwise specified.

The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

Features of various embodiments of the present disclosure may be partially or overall coupled to or combined with each other, and may be variously inter-operated with each other and driven technically as those skilled in the art can sufficiently understand. Embodiments of the present disclosure may be carried out independently from each other, or may be carried out together in a co-dependent relationship.

Hereinafter, example embodiments of the present disclosure will be described in detail with reference to the accompanying drawings. In adding reference numerals to elements of each of the drawings, although the same elements are illustrated in other drawings, like reference numerals may refer to like elements. Also, for convenience of description, a scale in which each of elements is illustrated in the accompanying drawings may differ from an actual scale. Thus, the illustrated elements are not limited to the specific scale in which they are illustrated in the drawings.

The present disclosure relates to an organic light emitting diode including a first compound having a plate-like structure and a second compound that may transfer efficiently exciton energy to the first compound, and an organic light emitting device including the diode. In one example embodiment, an emissive layer including the first compound and the second compound may be applied to an organic light emitting diode having a single emitting part in a red pixel region. Alternatively, the emissive layer including the first and second compound may be applied to an organic light emitting diode having a tandem structure where at least two emitting parts are stacked.

The organic light emitting diode where an emissive layer includes the first compound and the second compound may be applied to an organic light emitting device such as an organic light emitting display device or an organic light emitting illumination device. As an example, an organic light emitting display device will be described.

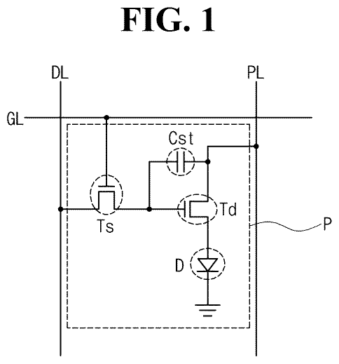

FIG. 1 illustrates a schematic circuit diagram of an organic light emitting display device in accordance with the present disclosure. As illustrated in FIG. 1, a gate line GL, a data line DL and power line PL, each of which crosses each other to define a pixel region P, in an organic light emitting display device. A switching thin film transistor Ts, a driving thin film transistor Td, a storage capacitor Cst and an organic light emitting diode D are disposed within the pixel region P. The pixel region P may include a red (R) pixel region, a green (G) pixel region and a blue (B) pixel region. However, embodiments of the present disclosure are not limited to such examples.

The switching thin film transistor Ts is connected to the gate line GL and the data line DL. The driving thin film transistor Td and the storage capacitor Cst are connected between the switching thin film transistor Ts and the power line PL. The organic light emitting diode D is connected to the driving thin film transistor Td. When the switching thin film transistor Ts is turned on by a gate signal applied to the gate line GL, a data signal applied to the data line DL is applied to a gate electrode of the driving thin film transistor Td and one electrode of the storage capacitor Cst through the switching thin film transistor Ts.

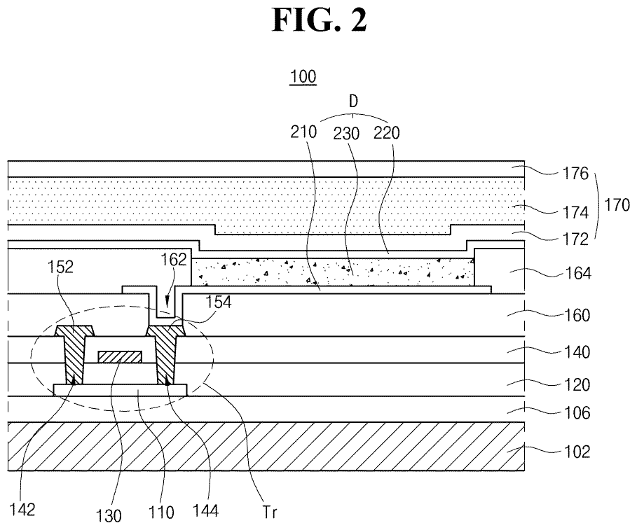

The driving thin film transistor Td is turned on by the data signal applied to the gate electrode 130 (FIG. 2) so that a current proportional to the data signal is supplied from the power line PL to the organic light emitting diode D through the driving thin film transistor Td. And then, the organic light emitting diode D emits light having a luminance proportional to the current flowing through the driving thin film transistor Td. In this case, the storage capacitor Cst is charged with a voltage proportional to the data signal so that the voltage of the gate electrode in the driving thin film transistor Td is kept constant during one frame. Therefore, the organic light emitting display device may display a desired image.

FIG. 2 illustrates a schematic cross-sectional view of an organic light emitting display device in accordance with an example embodiment of the present disclosure. As illustrated in FIG. 2, the organic light emitting display device 100 includes a substrate 102, a thin-film transistor Tr on the substrate 102, and an organic light emitting diode D connected to the thin film transistor Tr.

As an example, the substrate 102 may include a red pixel region, a green pixel region and a blue pixel region and an organic light emitting diode D may be located in each pixel region. Each of the organic light emitting diodes D emitting red, green and blue light, respectively, is located correspondingly in the red pixel region, the green pixel region and the blue pixel region.

The substrate 102 may include, but is not limited to, glass, thin flexible material and/or polymer plastics. For example, the flexible material may be selected from the group of, but is not limited to, polyimide (PI), polyethersulfone (PES), polyethylenenaphthalate (PEN), polyethylene terephthalate (PET), polycarbonate (PC) and/or combinations thereof. The substrate 102, on which the thin film transistor Tr and the organic light emitting diode D are arranged, forms an array substrate.

A buffer layer 106 may be disposed on the substrate 102. The thin film transistor Tr may be disposed on the buffer layer 106. The buffer layer 106 may be omitted.

A semiconductor layer 110 is disposed on the buffer layer 106. In one example embodiment, the semiconductor layer 110 may include, but is not limited to, oxide semiconductor materials. In this case, a light-shield pattern may be disposed under the semiconductor layer 110, and the light-shield pattern may prevent or reduce chances of light from being incident toward the semiconductor layer 110, and thereby, preventing or reducing the semiconductor layer 110 from being degraded by the light. Alternatively, the semiconductor layer 110 may include polycrystalline silicon. In this case, opposite edges of the semiconductor layer 110 may be doped with impurities.

A gate insulating layer 120 including an insulating material is disposed on the semiconductor layer 110. The gate insulating layer 120 may include, but is not limited to, an inorganic insulating material such as silicon oxide (SiOₓ, wherein 0<x≤2) or silicon nitride (SiNₓ, wherein 0<x≤2).

A gate electrode 130 made of a conductive material such as a metal is disposed on the gate insulating layer 120 so as to correspond to a center of the semiconductor layer 110. While the gate insulating layer 120 is disposed on a whole area of the substrate 102 as shown in FIG. 2, the gate insulating layer 120 may be patterned identically as the gate electrode 130.

An interlayer insulating layer 140 including an insulating material is disposed on the gate electrode 130 and covers an entire surface of the substrate 102. The interlayer insulating layer 140 may include, but is not limited to, an inorganic insulating material such as silicon oxide (SiOₓ) or silicon nitride (SiNₓ), or an organic insulating material such as benzocyclobutene or photo-acryl.

The interlayer insulating layer 140 has first and second semiconductor layer contact holes 142 and 144 that expose the semiconductor layer 110 or do not cover a portion of the surface of the semiconductor layer 110 nearer to the opposing ends than to a center of the semiconductor layer 110. The first and second semiconductor layer contact holes 142 and 144 are disposed on opposite sides of the gate electrode 130 and spaced apart from the gate electrode 130. The first and second semiconductor layer contact holes 142 and 144 are formed through the gate insulating layer 120 in FIG. 2. Alternatively, the first and second semiconductor layer contact holes 142 and 144 may be formed only through the interlayer insulating layer 140 when the gate insulating layer 120 is patterned identically as the gate electrode 130.

A source electrode 152 and a drain electrode 154, which are made of conductive material such as a metal, are disposed on the interlayer insulating layer 140. The source electrode 152 and the drain electrode 154 are spaced apart from each other on opposing sides of the gate electrode 130, and contact both sides of the semiconductor layer 110 through the first and second semiconductor layer contact holes 142 and 144, respectively.

The semiconductor layer 110, the gate electrode 130, the source electrode 152 and the drain electrode 154 constitute the thin film transistor Tr, which acts as a driving element. The thin film transistor Tr in FIG. 2 has a coplanar structure in which the gate electrode 130, the source electrode 152 and the drain electrode 154 are disposed on the semiconductor layer 110. Alternatively, the thin film transistor Tr may have an inverted staggered structure in which a gate electrode is disposed under a semiconductor layer and a source and drain electrodes are disposed on the semiconductor layer. In this case, the semiconductor layer may include amorphous silicon.

The gate line GL and the data line DL, which cross each other to define a pixel region P, and a switching element Ts, which is connected to the gate line GL and the data line DL, may be further formed in the pixel region P. The switching element Ts is connected to the thin film transistor Tr, which is a driving element. In addition, the power line PL is spaced apart in parallel from the gate line GL or the data line DL. The thin film transistor Tr may further include a storage capacitor Cst configured to constantly keep a voltage of the gate electrode 130 for one frame.

A passivation layer 160 is disposed on the source and drain electrodes 152 and 154. The passivation layer 160 covers the thin film transistor Tr on the whole substrate 102. The passivation layer 160 has a flat top surface and a drain contact hole 162 that exposes the drain electrode 154 or does not cover the drain electrode 154 of the thin film transistor Tr. While the drain contact hole 162 is disposed on the second semiconductor layer contact hole 144, it may be spaced apart from the second semiconductor layer contact hole 144.

The organic light emitting diode (OLED) D includes a first electrode 210 that is disposed on the passivation layer 160 and connected to the drain electrode 154 of the thin film transistor Tr. The OLED D further includes an emissive layer 230 and a second electrode 220 each of which is disposed sequentially on the first electrode 210.

The first electrode 210 is disposed in each pixel region. The first electrode 210 may be an anode and include conductive material having relatively high work function value. For example, the first electrode 210 may include a transparent conductive oxide (TCO). In some embodiments, the first electrode 210 may include, but is not limited to, indium tin oxide (ITO), indium zinc oxide (IZO), indium tin zinc oxide (ITZO), tin oxide (SnO), zinc oxide (ZnO), indium cerium oxide (ICO), aluminum doped zinc oxide (AZO), and/or combinations thereof.

In one example embodiment, when the organic light emitting display device 100 is a bottom-emission type, the first electrode 210 may have a single-layered structure of the TCO. Alternatively, when the organic light emitting display device 100 is a top-emission type, a reflective electrode or a reflective layer may be disposed under the first electrode 210. For example, the reflective electrode or the reflective layer may include, but is not limited to, silver (Ag) or aluminum-palladium-copper (APC) alloy. In the OLED D of the top-emission type, the first electrode 210 may have a triple-layered structure of ITO/Ag/ITO or ITO/APC/ITO.

In addition, a bank layer 164 is disposed on the passivation layer 160 in order to cover edges of the first electrode 210. The bank layer 164 exposes the first electrode 210 or does not cover a center of the first electrode 210 corresponding to each pixel region. The bank layer 164 may be omitted.

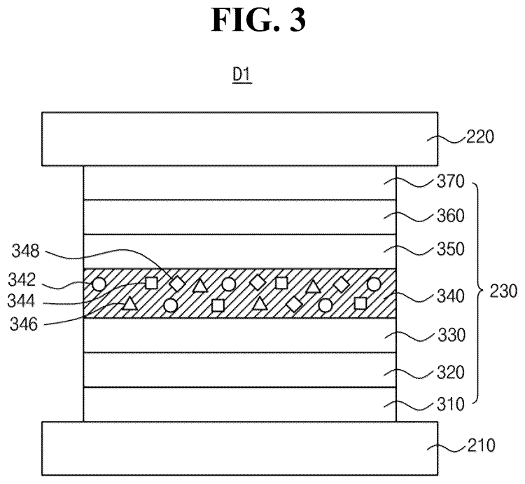

An emissive layer 230 is disposed on the first electrode 210. In one example embodiment, the emissive layer 230 may have a single-layered structure of an emitting material layer (EML). Alternatively, the emissive layer 230 may have a multiple-layered structure including a hole injection layer (HIL), a hole transport layer (HTL), an electron blocking layer (EBL), an EML, a hole blocking layer (HBL), an electron transport layer (ETL), an electron injection layer (EIL) and/or a charge generation layer (CGL) (FIG. 3). In one aspect, the emissive layer 230 may have a single emitting part. Alternatively, the emissive layer 230 may have multiple emitting parts to form a tandem structure. For example, the emissive layer 230 may be applied to an OLED with a single emitting part located each of the red pixel region, the green pixel region and the blue pixel region. Alternatively, the emissive layer 230 may be applied to a tandem-type OLED where at least two emitting parts are stacked.

The emissive layer 230 may include a first compound having a plate-like structure, a second compound, and optionally, one or more hosts transferring exciton energy to the first compound. The luminous efficiency and the luminous lifespan of the OLED D and the organic light emitting display device 100 may be improved by including the luminous materials.

The second electrode 220 is disposed on the substrate 102 above which the emissive layer 230 is disposed. The second electrode 220 may be disposed on a whole display area. The second electrode 220 may include a conductive material with a relatively low work function value compared to the first electrode 210. The second electrode 220 may be a cathode providing electrons. For example, the second electrode 220 may include at least one of, but is not limited to, aluminum (Al), magnesium (Mg), calcium (Ca), silver (Ag), alloy thereof and/or combinations thereof such as aluminum-magnesium alloy (Al—Mg). When the organic light emitting display device 100 is a top-emission type, the second electrode 220 is thin so as to have light-transmissive (semi-transmissive) property.

In addition, an encapsulation film 170 may be disposed on the second electrode 220 in order to prevent or reduce outer moisture from penetrating into the OLED D. The encapsulation film 170 may have, but is not limited to, a laminated structure of a first inorganic insulating film 172, an organic insulating film 174 and a second inorganic insulating film 176. The encapsulation film 170 may be omitted.

A polarizing plate may be attached onto the encapsulation film 170 to reduce reflection of external light. For example, the polarizing plate may be a circular polarizing plate. When the organic light emitting display device 100 is a bottom-emission type, the polarizing plate may be disposed under the substrate 102. Alternatively, when the organic light emitting display device 100 is a top-emission type, the polarizing plate may be disposed on the encapsulation film 170. In addition, a cover window may be attached to the encapsulation film 170 or the polarizing plate. In this case, the substrate 102 and the cover window may have a flexible property, thus the organic light emitting display device 100 may be a flexible display device.

The OLED D is described in more detail. FIG. 3 illustrates a schematic cross-sectional view of an organic light emitting diode having a single emitting part in accordance with an example embodiment of the present disclosure. As illustrated in FIG. 3, the organic light emitting diode (OLED) D1 in accordance with the present disclosure includes first and second electrodes 210 and 220 facing each other and an emissive layer 230 disposed between the first and second electrodes 210 and 220. The organic light emitting display device 100 includes a red pixel region, a green pixel region and a blue pixel region, and the OLED D1 may be disposed in the red pixel region, the green pixel region and the blue pixel region. As an example, the OLED D1 may be disposed in the red pixel region.

In an example embodiment, the emissive layer 230 includes an emitting material layer (EML) 340 disposed between the first and second electrodes 210 and 220. Also, the emissive layer 230 may include at least one of a hole transport layer (HTL) 320 disposed between the first electrode 210 and the EML 340 and an electron transport layer (ETL) 360 disposed between the second electrode 220 and the EML 340. In addition, the emissive layer 230 may further include at least one of a hole injection layer (HIL) 310 disposed between the first electrode 210 and the HTL 320 and an electron injection layer (EIL) 370 disposed between the second electrode 220 and the ETL 360. Alternatively, the emissive layer 230 may further comprise a first exciton blocking layer, i.e. an electron blocking layer (EBL) 330 disposed between the HTL 320 and the EML 340 and/or a second exciton blocking layer, i.e. a hole blocking layer (HBL) 350 disposed between the EML 340 and the ETL 360.

The first electrode 210 may be an anode that provides holes into the EML 340. The first electrode 210 may include a conductive material having a relatively high work function value, for example, a transparent conductive oxide (TCO). In an example embodiment, the first electrode 210 may include, but is not limited to, ITO, IZO, ITZO, SnO, ZnO, ICO, AZO, and/or combinations thereof.

The second electrode 220 may be a cathode that provides electrons into the EML 340. The second electrode 220 may include a conductive material having a relatively low work function values, i.e., a highly reflective material such as Al, Mg, Ca, Ag, and/or alloy thereof and/or combinations thereof such as Al—Mg.

The HIL 310 is disposed between the first electrode 210 and the HTL 320 and may improve an interface property between the inorganic first electrode 210 and the organic HTL 320. In one example embodiment, the HIL 310 may include, but is not limited to, 4,4′,4″-Tris(3-methylphenylamino)triphenylamine (MTDATA), 4,4′,4″-Tris(N,N-diphenyl-amino)triphenylamine (NATA), 4,4′,4″-Tris(N-(naphthalene-1-yl)-N-phenyl-amino)triphenylamine (1T-NATA), 4,4′,4″-Tris(N-(naphthalene-2-yl)-N-phenyl-amino)triphenylamine (2T-NATA), Copper phthalocyanine (CuPc), Tris(4-carbazoyl-9-yl-phenyl)amine (TCTA), N,N′-Diphenyl-N,N′-bis(1-naphthyl)-1,1′-biphenyl-4,4″-diamine (NPB; NPD), N,N′-Bis{4-[bis(3-methylphenyl)amnino]phenyl}-N,N′-diphenyl-4,4′-biphenyldiamine (DNTPD), 1,4,5,8,9,11-Hexaazatriphenylenehexacarbonitrile (Dipyrazino[2,3-f:2′3′-h]quinoxaline-2,3,6,7,10,11-hexacarbonitrile; HAT-CN), 2,3,5,6-tetrafluoro-7,7,8,8-tetracyanoquinodimethane (F4-TCNQ), 1,3,4,5,7,8-hexafluorotetracyanonaphthoquinodimethane (F6-TCNNQ), 1,3,5-tris[4-(diphenylamino)phenyl]benzene (TDAPB), poly(3,4-ethylenedioxythiphene)polystyrene sulfonate (PEDOT/PSS), N-(biphenyl-4-yl)-9,9-dimethyl-N-(4-(9-phenyl-9H-carbazol-3-yl)phenyl)-9H-fluoren-2-amine, N,N′-diphenyl-N,N′-di[4-(N,N′-diphenyl-amino)phenyl]benzidine (NPNPB) and/or combinations thereof.

In another example embodiment, the HIL 310 includes the hole transporting material doped with hole injecting material (e.g., HAT-CN, F4-TCNQ and/or F6-TCNNQ). In this case, the contents of the hole injection material in the HIL 310 may be between about 2 wt % and about 15 wt %. The HIL 310 may be omitted in compliance of the OLED D1 property.

The HTL 320 is disposed adjacent to the EML 340 between the first electrode 210 and the EML 340. In one example embodiment, the HTL 320 may include, but is not limited to, N,N′-Diphenyl-N,N′-bis(3-methylphenyl)-1,1′-biphenyl-4,4′-diamine (TPD), NPB(NPD), DNTPD, 4,4′-bis(N-carbazolyl)-1,1′-biphenyl (CBP), Poly[N,N′-bis(4-butylphenyl)-N,N′-bis(phenyl)-benzidine] (Poly-TPD), Poly[(9,9-dioctylfluorenyl-2,7-diyl)-co-(4,4′-(N-(4-sec-butylphenyl)diphenylamine))] (TFB), Di-[4-(N,N-di-p-tolyl-amino)-phenyl]cyclohexane (TAPC), 3,5-Di(9H-carbazol-9-yl)-N,N-diphenylaniline (DCDPA), N-(biphenyl-4-yl)-9,9-dimethyl-N-(4-(9-phenyl-9H-carbazol-3-yl)phenyl)-9H-fluoren-2-amine, N-(biphenyl-4-yl)-N-(4-(9-phenyl-9H-carbazol-3-yl)phenyl)biphenyl-4-amine, N-([1,1′-Biphenyl]-4-yl)-9,9-dimethyl-N-(4-(9-phenyl-9H-carbazol-3-yl)phenyl)-9H-fluoren-2-amine and/or combinations thereof.

The EML 340 may include a first compound 342 and a second compound 344, and optionally, a third compound 346 and/or a fourth compound 348, and ultimate emission may occur at the first compound 342. The EML 340 may emit red to yellow-green color light, for example, red color light.

The first compound 342 may be a fluorescent emitter (fluorescent dopant) emitting red to yellow-green color light. The first compound 342 has a wide plate-like structure and may be receive efficiently singlet exciton energy from the second compound 344 acting as an assistant emitter and/or the third and fourth compounds 346 and 348 acting as hosts. The luminous efficiency, luminous lifespan and color purity of the OLED D1 may be improved by using the first compound 342 as the final emitting material. The first compound may have the following structure of Chemical Formula 1:

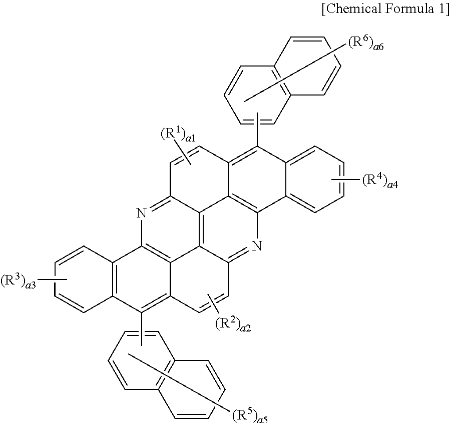

wherein, in the Chemical Formula 1,
each of R¹, R², R³, R⁴, R⁵, and R⁶ is independently a halogen atom, a cyano group, an unsubstituted or substituted C₁-C₂₀ alkyl group, an unsubstituted or substituted C₁-C₂₀ alkyl amino group, an unsubstituted or substituted C₆-C₃₀ aryl group, an unsubstituted or substituted C₃-C₃₀ heteroaryl group, an unsubstituted or substituted C₆-C₃₀ aryl amino group or an unsubstituted or substituted C₃-C₃₀ heteroaryl amino group, where each R¹ is identical to or different from each other when a1 is 2, each R² is identical to or different from each other when a2 is 2, each R³ is identical to or different from each other when a3 is 2, 3 or 4, each R⁴ is identical to or different from each other when a4 is 2, 3 or 4, each R⁵ is identical to or different from each other when a5 is 2, 3, 4, 5, 6 or 7, and each R⁶ is identical to or different from each other when a6 is 2, 3, 4, 5, 6 or 7;
each of a1 and a2 is independently 0, 1 or 2;
each of a3 and a4 is independently 0, 1, 2, 3 or 4; and
each of a5 and a6 is independently 0, 1, 2, 3, 4, 5, 6 or 7.

As used herein, the term “unsubstituted” means that hydrogen is directly linked to a carbon atom. “Hydrogen”, as used herein, may refer to protium, deuterium and tritium.

As used herein, “substituted” means that the hydrogen is replaced with a substituent. The substituent may comprise, but is not limited to, an unsubstituted or halogen-substituted C₁-C₂₀ alkyl group, an unsubstituted or halogen-substituted C₁-C₂₀ alkoxy, halogen, a cyano group, a hydroxyl group, a carboxylic group, a carbonyl group, an amino group, a C₁-C₁₀ alkyl amino group, a C₆-C₃₀ aryl amino group, a C₃-C₃₀ heteroaryl amino group, a nitro group, a hydrazyl group, a sulfonate group, an unsubstituted or halogen-substituted C₁-C₁₀ alkyl silyl group, an unsubstituted or a halogen-substituted C₁-C₁₀ alkoxy silyl group, an unsubstituted or halogen-substituted C₃-C₂₀ cyclo alkyl silyl group, an unsubstituted or halogen-substituted C₆-C₃₀ aryl silyl group, an unsubstituted or substituted C₆-C₃₀ aryl group, or an unsubstituted or substituted C₃-C₃₀ heteroaryl group.

For example, each of the C₆-C₃₀ aryl group and the C₃-C₃₀ heteroaryl group may be substituted with at least one of C₁-C₂₀ alkyl, C₆-C₃₀ aryl and C₃-C₃₀ heteroaryl.

As used herein, the term “hetero” in terms such as “a heteroaromatic group”, “a heterocyclo alkylene group”, “a heteroarylene group”, “a heteroaryl alkylene group”, “a heteroaryl oxylene group”, “a heterocyclo alkyl group”, “a heteroaryl group”, “a heteroaryl alkyl group”, “a heteroaryloxy group”, “a heteroaryl amino group” and the likes means that at least one carbon atom, for example 1 to 5 carbons atoms, constituting an aliphatic chain, an alicyclic group or ring or an aromatic group or ring is substituted with at least one heteroatom selected from the group consisting of N, O, S and P.

As used herein, the C₆-C₃₀ aryl group may include, but is not limited to, an unfused or fused aryl group such as phenyl, biphenyl, terphenyl, naphthyl, anthracenyl, pentalenyl, indenyl, indeno-indenyl, heptalenyl, biphenylenyl, indacenyl, phenalenyl, phenanthrenyl, benzo-phenanthrenyl, dibenzo-phenanthrenyl, azulenyl, pyrenyl, fluoranthenyl, triphenylenyl, chrysenyl, tetraphenylenyl, tetracenyl, pleiadenyl, picenyl, pentaphenylenyl, pentacenyl, fluorenyl, indeno-fluorenyl or spiro-fluorenyl. The C₆-C₃₀ arylene group may include, but is not limited to, any bivalent linking group corresponding to the above aryl group. As used herein, the C₆-C₃₀ arylene group may be a bivalent linking group corresponding to each of the C₆-C₃₀ aryl group.

As used herein, the C₃-C₃₀ heteroaryl group may comprise, but is not limited to, an unfused or fused heteroaryl group such as pyrrolyl, pyridinyl, pyrimidinyl, pyrazinyl, pyridazinyl, triazinyl, tetrazinyl, imidazolyl, pyrazolyl, indolyl, iso-indolyl, indazolyl, indolizinyl, pyrrolizinyl, carbazolyl, benzo-carbazolyl, dibenzo-carbazolyl, indolo-carbazolyl, indeno-carbazolyl, benzo-furo-carbazolyl, benzo-thieno-carbazolyl, carbolinyl, quinolinyl, iso-quinolinyl, phthlazinyl, quinoxalinyl, cinnolinyl, quinazolinyl, quinolizinyl, purinyl, benzo-quinolinyl, benzo-iso-quinolinyl, benzo-quinazolinyl, benzo-quinoxalinyl, acridinyl, phenazinyl, phenoxazinyl, phenothiazinyl, phenanthrolinyl, perimidinyl, phenanthridinyl, pteridinyl, naphthyridinyl, furanyl, pyranyl, oxazinyl, oxazolyl, oxadiazolyl, triazolyl, dioxinyl, benzo-furanyl, dibenzo-furanyl, thiopyranyl, xanthenyl, chromenyl, iso-chromenyl, thioazinyl, thiophenyl, benzo-thiophenyl, dibenzo-thiophenyl, difuro-pyrazinyl, benzofuro-dibenzo-furanyl, benzothieno-benzo-thiophenyl, benzothieno-dibenzo-thiophenyl, benzothieno-benzo-furanyl, benzothieno-dibenzo-furanyl, xanthene-linked spiro acridinyl, dihydroacridinyl substituted with at least one C₁-C₁₀ alkyl and N-substituted spiro fluorenyl. The C₃-C₃₀ heteroarylene group may include, but is not limited to, any bivalent linking group corresponding to the above heteroaryl group.

As an example, each of the aryl group or the heteroaryl group of R¹ to R⁶ in Chemical Formula 1 may consist of one to four, for example, one to three aromatic and/or heteroaromatic rings. When the number of the aromatic and/or heteroaromatic rings of R¹ to R⁶ becomes more than four, conjugated structure among the within the whole molecule becomes too long, thus, the organometallic compound may have too narrow energy bandgap. For example, each of the aryl group or the heteroaryl group of R¹ to R⁶ may comprise independently, but is not limited to, phenyl, biphenyl, naphthyl, anthracenyl, pyrrolyl, triazinyl, imidazolyl, pyrazolyl, pyridinyl, pyrazinyl, pyrimidinyl, pyridazinyl, furanyl, benzo-furanyl, dibenzo-furanyl, thiophenyl, benzo-thiophenyl, dibenzo-thiophenyl, carbazolyl, acridinyl, carbolinyl, phenazinyl, phenoxazinyl, or phenothiazinyl.

The first compound 342 having the structure of Chemical Formula 1 includes a fused ring system of multiple aromatic rings and/or heteroaromatic rings, so that the first compound 342 has a wide plate-like structure. The excited singlet exciton energy of the second compound 344 and/or the third and fourth compounds 346 and 348 may be transferred efficiently to the singlet exciton of the first compound 342 having the structure of Chemical Formula 1 through Forster Resonance Energy Transfer (FRET) mechanism.

The first compound 342 may not utilize triplet excitons because the first compound 342 having the structure of Chemical Formula 1 is fluorescent material. Only the singlet exciton energy transferred by the FRET mechanism may contribute to the emission of the first compound having the structure of Chemical Formula 1. The amount of singlet exciton energy that may be utilized by the first compound 342 having the structure of Chemical Formula 1 and be contribute the emission of the first compound 342 is increased as the exciton energies are transferred to the first compound 342 through the FRET mechanism that may transfer only singlet-singlet exciton energy that may contribute the emission of the first compound 342 having the structure of Chemical Formula 1.

In addition, the second compound 344 as the assistant emitter is phosphorescent material that may utilize both the singlet exciton and the triplet exciton, as described below. The exciton energy of the second compound 344 having beneficial luminous efficiency is transferred to the first compound 342. The luminous efficiency, luminous lifespan and color purity of the OLED D1 may be improved by using the first compound 342 having the structure of Chemical Formula 1 as the final emitting material.

For example, the first compound 342 having the structure of Chemical Formula 1 may emit red to yellow-green color light. Applying the first compound 342 into the emissive layer 230 may improve the luminous efficiency and luminous lifespan of OLED D1.

In one example embodiment, each of R₁, R², R³, R⁴, R⁵, and R⁶ in Chemical Formula 1 may be independently a C₁-C₁₀ alkyl or an unsubstituted or C₁-C₁₀ alkyl-substituted C₆-C₃₀ aryl group. The first compound 342 with such a structure may include an organic compound having the following structure of Chemical Formula 2A or Chemical Formula 2B:

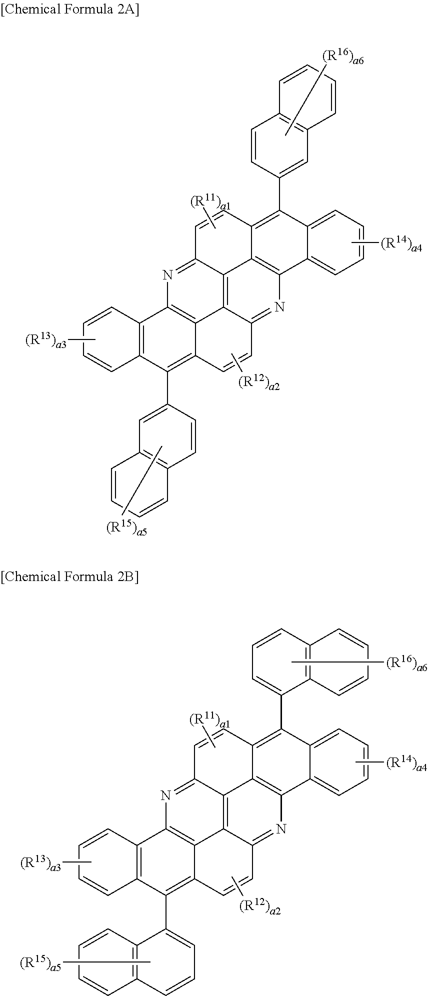

wherein, in the Chemical Formulae 2A and 2B,
each of a1, a2, a3, a4, a5, and a6 is as defined in Chemical Formula 1,
each of R¹¹, R¹², R¹³, R¹⁴, R¹⁵ and R¹⁶ is independently an unsubstituted or a substituted C₁-C₁₀ alkyl group or an unsubstituted or C₁-C₁₀ alkyl-substituted C₆-C₃₀ aryl group, where each R¹¹ is identical to or different from each other when a1 is 2, each R¹² is identical to or different from each other when a2 is 2, each R¹³ is identical to or different from each other when a3 is 2, 3 or 4, each R¹⁴ is identical to or different from each other when a4 is 2, 3 or 4, each R¹⁵ is identical to or different from each other when a5 is 2, 3, 4, 5, 6 or 7, and each R¹⁶ is identical to or different from each other when a6 is 2, 3, 4, 5, 6 or 7.

In another example embodiment, each of R¹, R², R³, R⁴, R⁵, and R⁶ in Chemical Formula 1 may be independently a C₁-C₁₀ alkyl group (e.g., methyl, iso-propyl or tert-butyl) or an unsubstituted or C₁-C₁₀ alkyl (e.g., methyl, iso-propyl or tert-butyl)-substituted C₆-C₃₀ aryl group (e.g., phenyl or naphthyl), each of a1 and a2 may be 0, and each of a3, a4, a5, and a6 may be independently 0 or 1, but is not limited thereto.

In another example embodiment, each of a1 and a2 may be 0, each of R³ and R⁴ may be independently an unsubstituted or C₁-C₁₀ alkyl (e.g., methyl, iso-propyl or tert-butyl)-substituted C₆-C₃₀ aryl group (e.g., phenyl or naphthyl), each of a3 and a4 may be independently 0 or 1, each of R⁵ and R⁶ may be independently a C₁-C₁₀ alkyl group (e.g., methyl, iso-propyl or tert-butyl), and each of a5 and a6 may be independently 0 or 1.

In some embodiments, the first compound 342 including the organic compound having the structure of Chemical Formula 1 may be, but is not limited to, at least one of the following compounds in Chemical Formula 3:

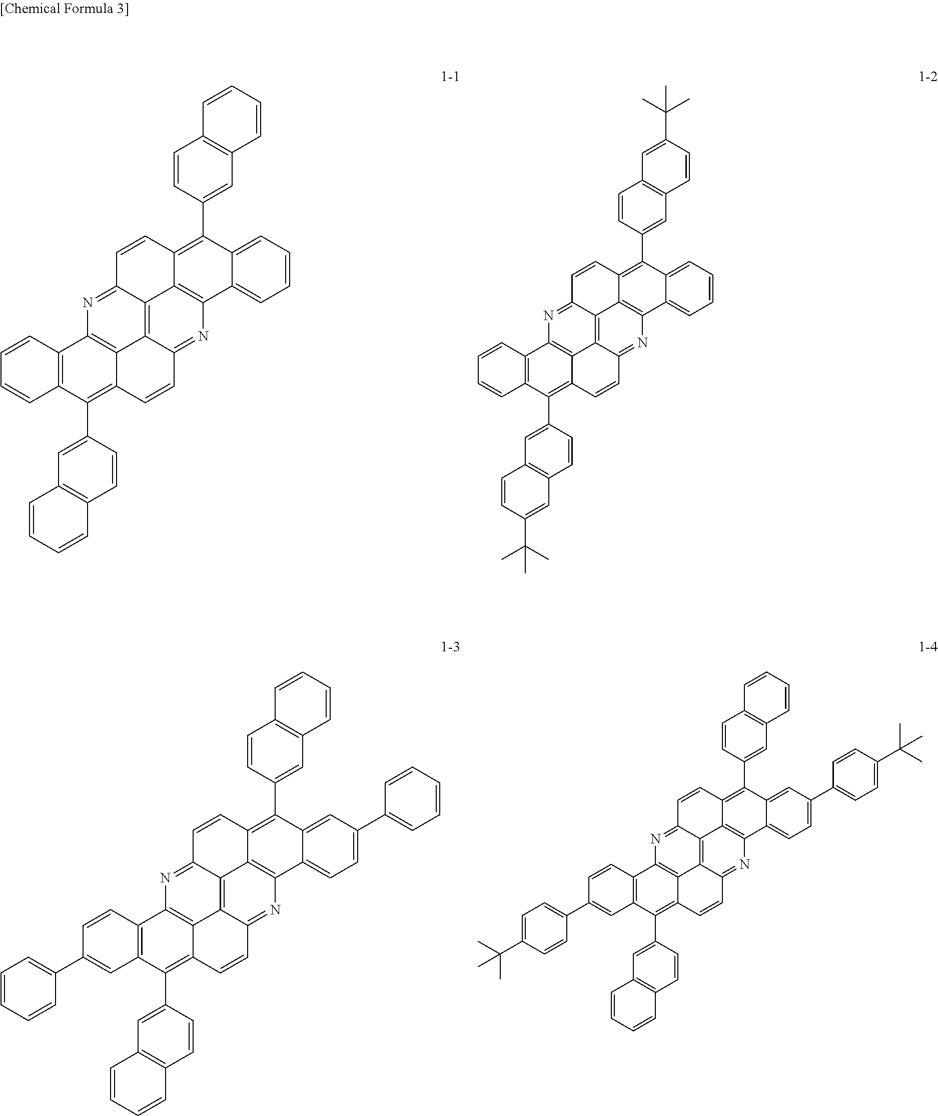 [SMILES: c1ccc2cc(-c3c4ccccc4c4nc5ccc6c(-c7ccc8ccccc8c7)c7ccccc7c7nc8ccc3c4c8c5c67)ccc2c1 ; CC(C)(C)c1ccc2cc(-c3c4ccccc4c4nc5ccc6c(-c7ccc8cc(C(C)(C)C)ccc8c7)c7ccccc7c7nc8ccc3c4c8c5c67)ccc2c1 ; c1ccc(-c2ccc3c(c2)c(-c2ccc4ccccc4c2)c2ccc4nc5c6ccc(-c7ccccc7)cc6c(-c6ccc7ccccc7c6)c6ccc7nc3c2c4c7c65)cc1 ; CC(C)(C)c1ccc(-c2ccc3c(c2)c(-c2ccc4ccccc4c2)c2ccc4nc5c6ccc(-c7ccc(C(C)(C)C)cc7)cc6c(-c6ccc7ccccc7c6)c6ccc7nc3c2c4c7c65)cc1]

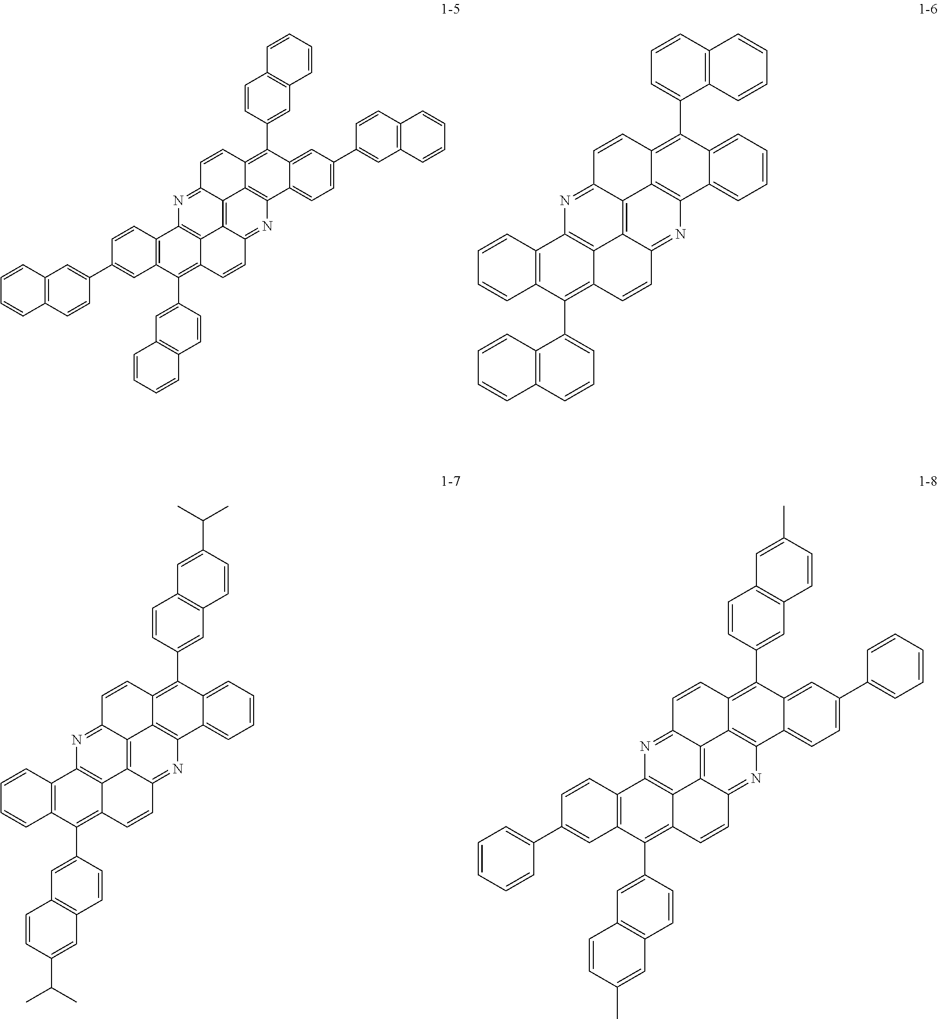 [SMILES: c1ccc2cc(-c3ccc4c(c3)c(-c3ccc5ccccc5c3)c3ccc5nc6c7ccc(-c8ccc9ccccc9c8)cc7c(-c7ccc8ccccc8c7)c7ccc8nc4c3c5c8c76)ccc2c1 ; c1ccc2c(-c3c4ccccc4c4nc5ccc6c(-c7cccc8ccccc78)c7ccccc7c7nc8ccc3c4c8c5c67)cccc2c1 ; CC(C)c1ccc2cc(-c3c4ccccc4c4nc5ccc6c(-c7ccc8cc(C(C)C)ccc8c7)c7ccccc7c7nc8ccc3c4c8c5c67)ccc2c1 ; Cc1ccc2cc(-c3c4cc(-c5ccccc5)ccc4c4nc5ccc6c(-c7ccc8cc(C)ccc8c7)c7cc(-c8ccccc8)ccc7c7nc8ccc3c4c8c5c67)ccc2c1]

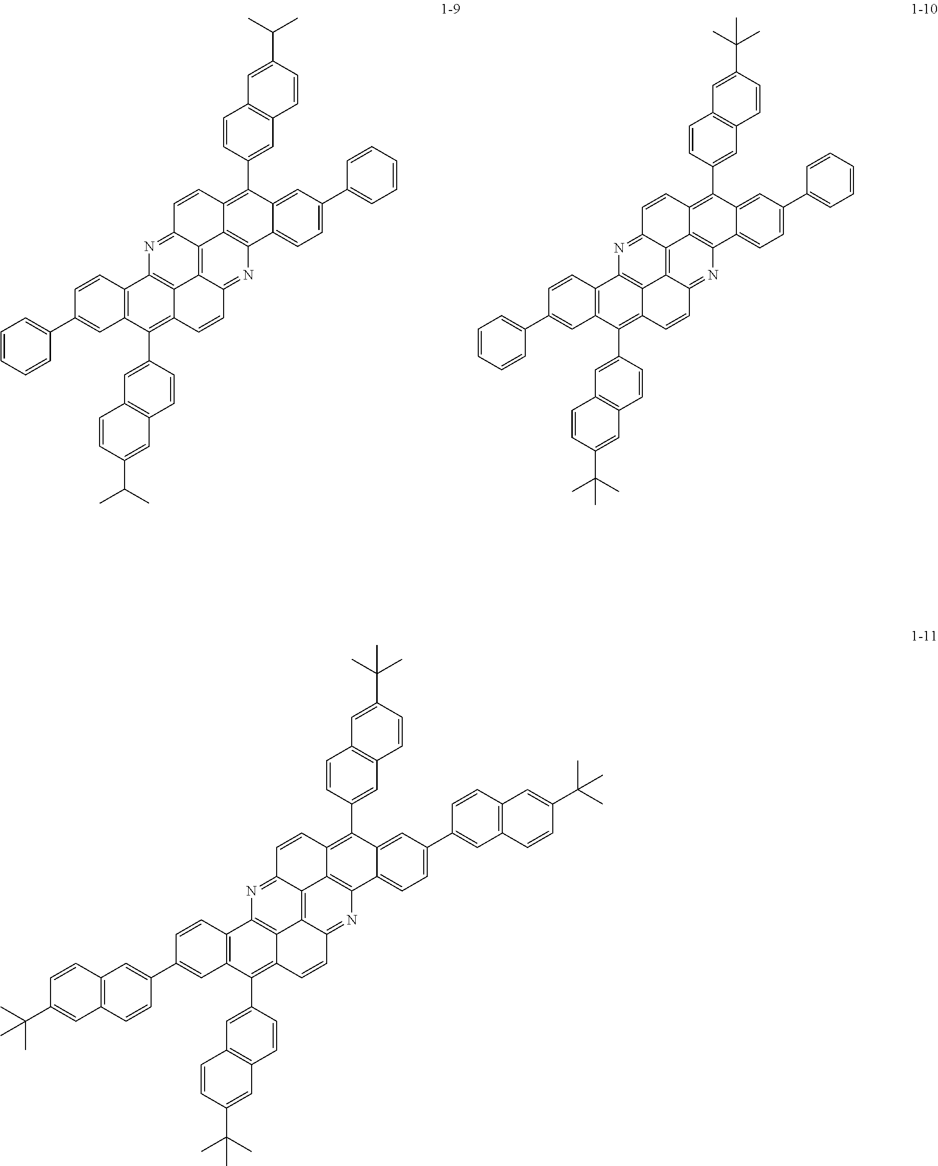 [SMILES: CC(C)c1ccc2cc(-c3c4cc(-c5ccccc5)ccc4c4nc5ccc6c(-c7ccc8cc(C(C)C)ccc8c7)c7cc(-c8ccccc8)ccc7c7nc8ccc3c4c8c5c67)ccc2c1 ; CC(C)(C)c1ccc2cc(-c3c4cc(-c5ccccc5)ccc4c4nc5ccc6c(-c7ccc8cc(C(C)(C)C)ccc8c7)c7cc(-c8ccccc8)ccc7c7nc8ccc3c4c8c5c67)ccc2c1 ; CC(C)(C)c1ccc2cc(-c3ccc4c(c3)c(-c3ccc5cc(C(C)(C)C)ccc5c3)c3ccc5nc6c7ccc(-c8ccc9cc(C(C)(C)C)ccc9c8)cc7c(-c7ccc8cc(C(C)(C)C)ccc8c7)c7ccc8nc4c3c5c8c76)ccc2c1]

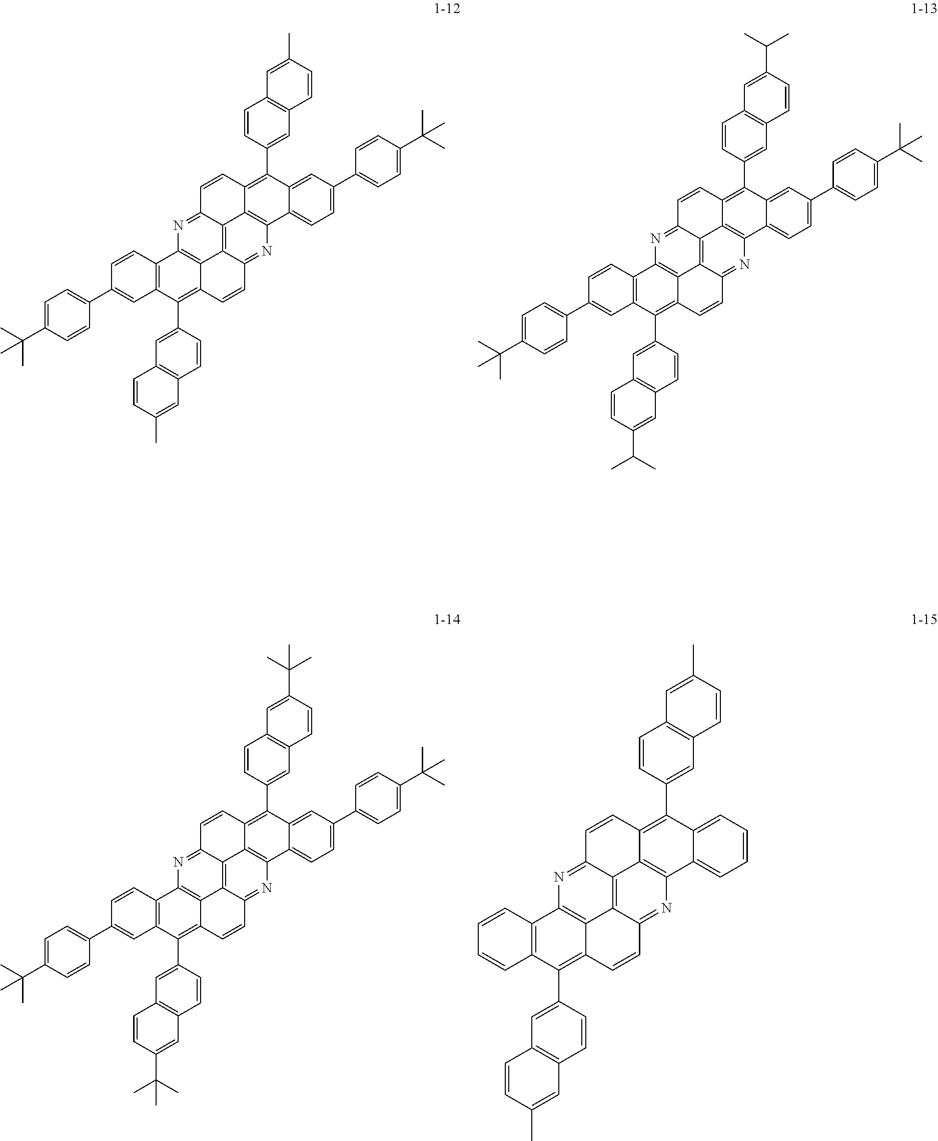 [SMILES: Cc1ccc2cc(-c3c4cc(-c5ccc(C(C)(C)C)cc5)ccc4c4nc5ccc6c(-c7ccc8cc(C)ccc8c7)c7cc(-c8ccc(C(C)(C)C)cc8)ccc7c7nc8ccc3c4c8c5c67)ccc2c1 ; CC(C)c1ccc2cc(-c3c4cc(-c5ccc(C(C)(C)C)cc5)ccc4c4nc5ccc6c(-c7ccc8cc(C(C)C)ccc8c7)c7cc(-c8ccc(C(C)(C)C)cc8)ccc7c7nc8ccc3c4c8c5c67)ccc2c1 ; CC(C)(C)c1ccc(-c2ccc3c(c2)c(-c2ccc4cc(C(C)(C)C)ccc4c2)c2ccc4nc5c6ccc(-c7ccc(C(C)(C)C)cc7)cc6c(-c6ccc7cc(C(C)(C)C)ccc7c6)c6ccc7nc3c2c4c7c65)cc1 ; Cc1ccc2cc(-c3c4ccccc4c4nc5ccc6c(-c7ccc8cc(C)ccc8c7)c7ccccc7c7nc8ccc3c4c8c5c67)ccc2c1]

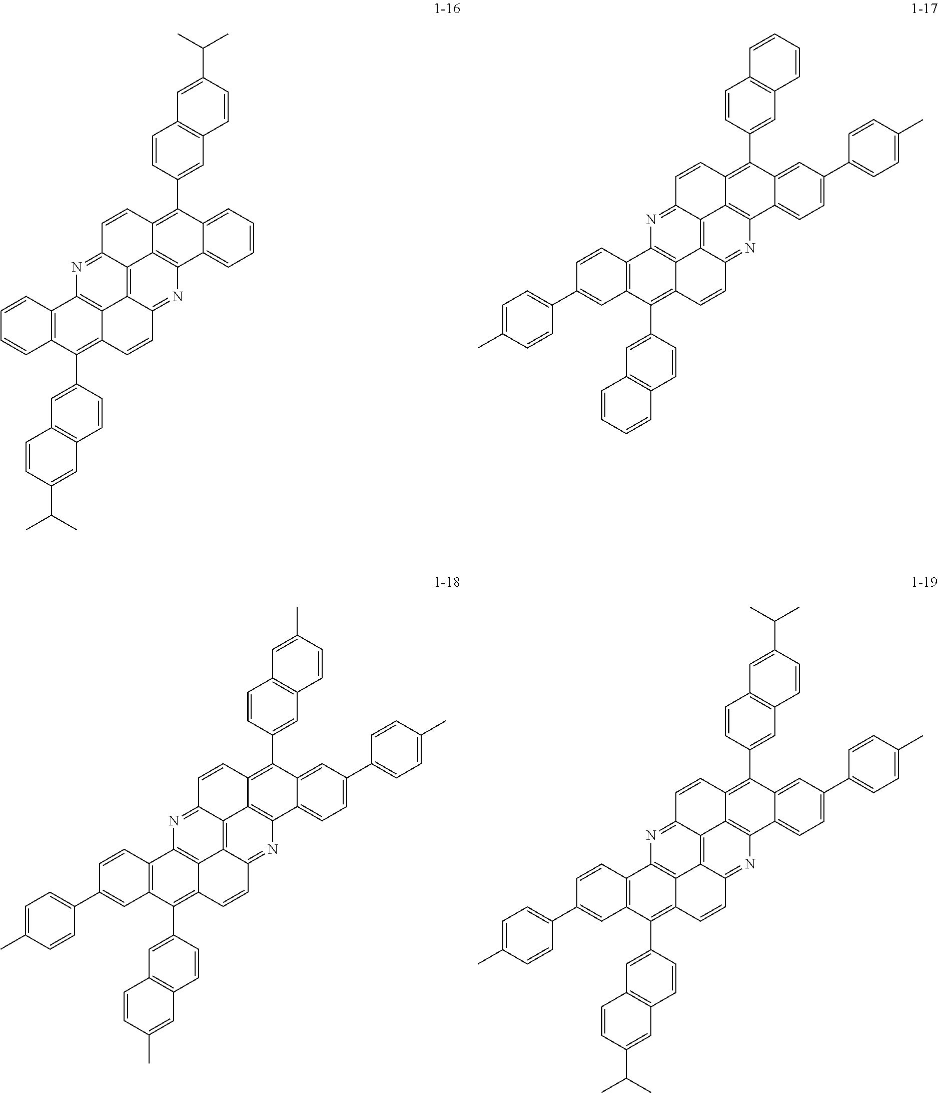

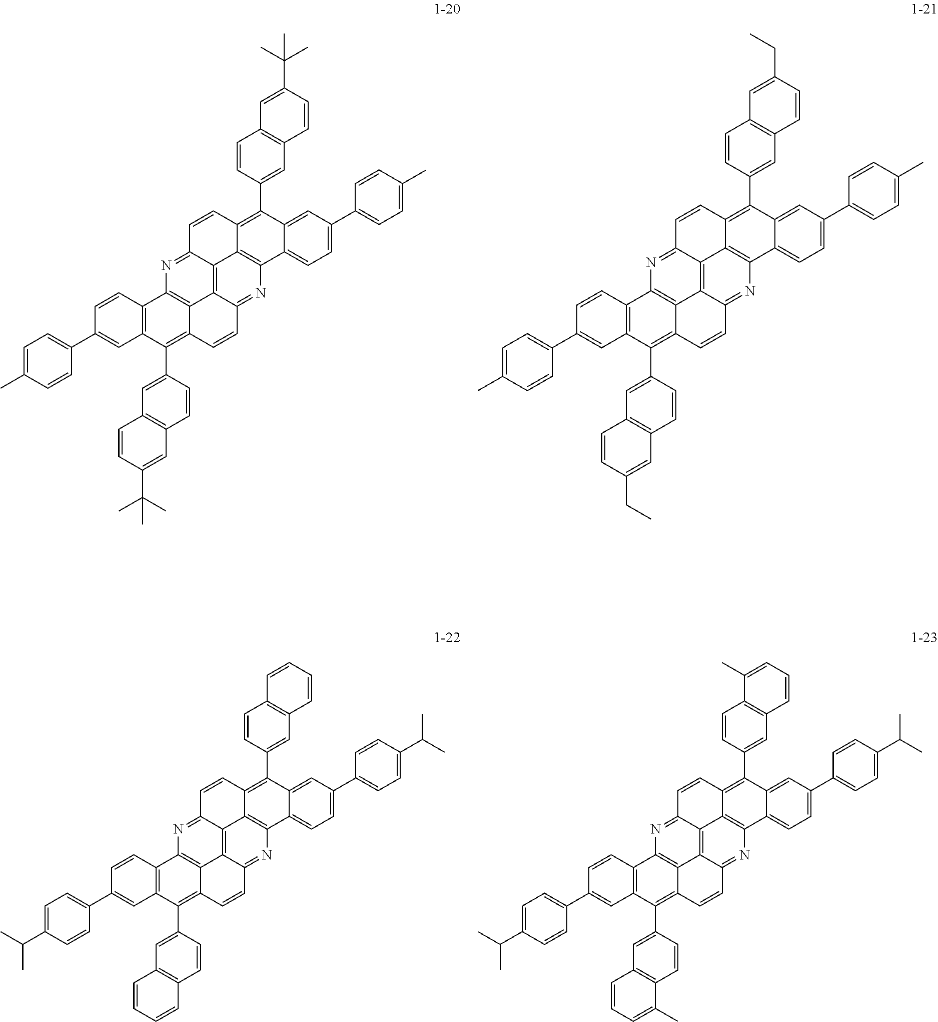

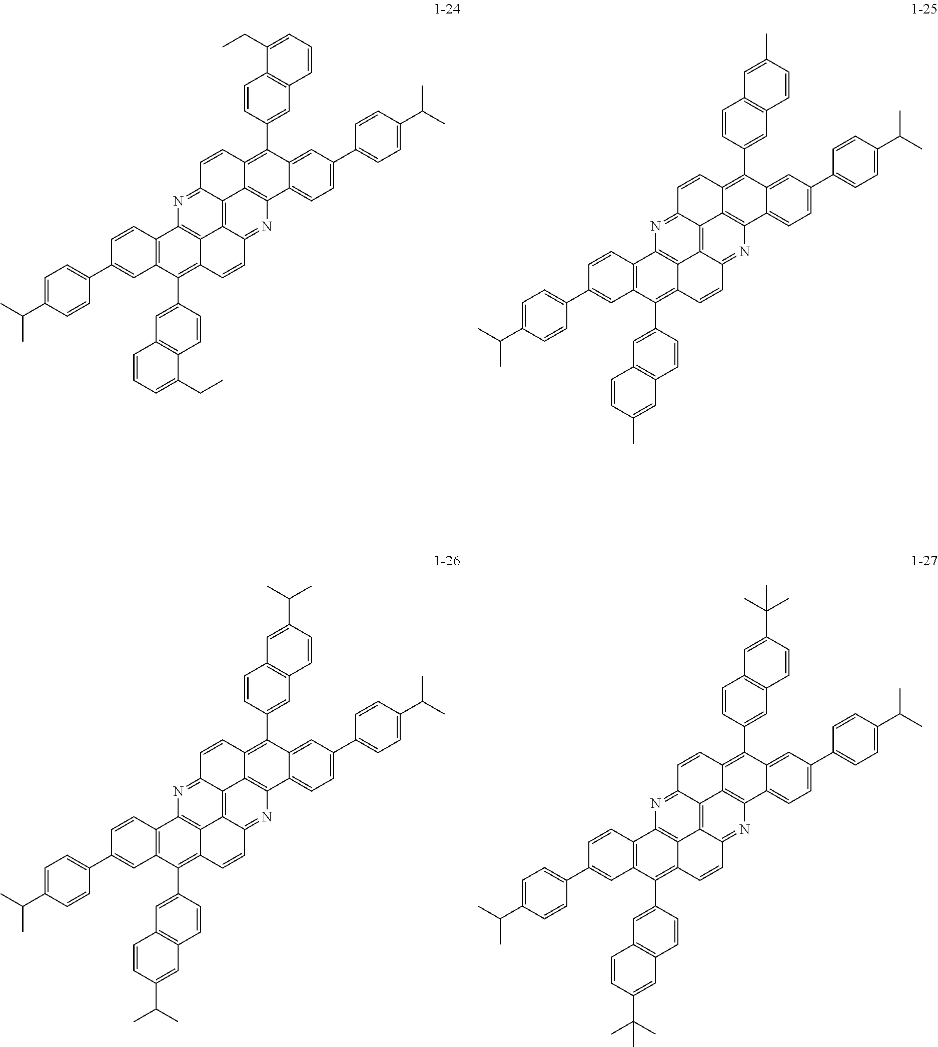

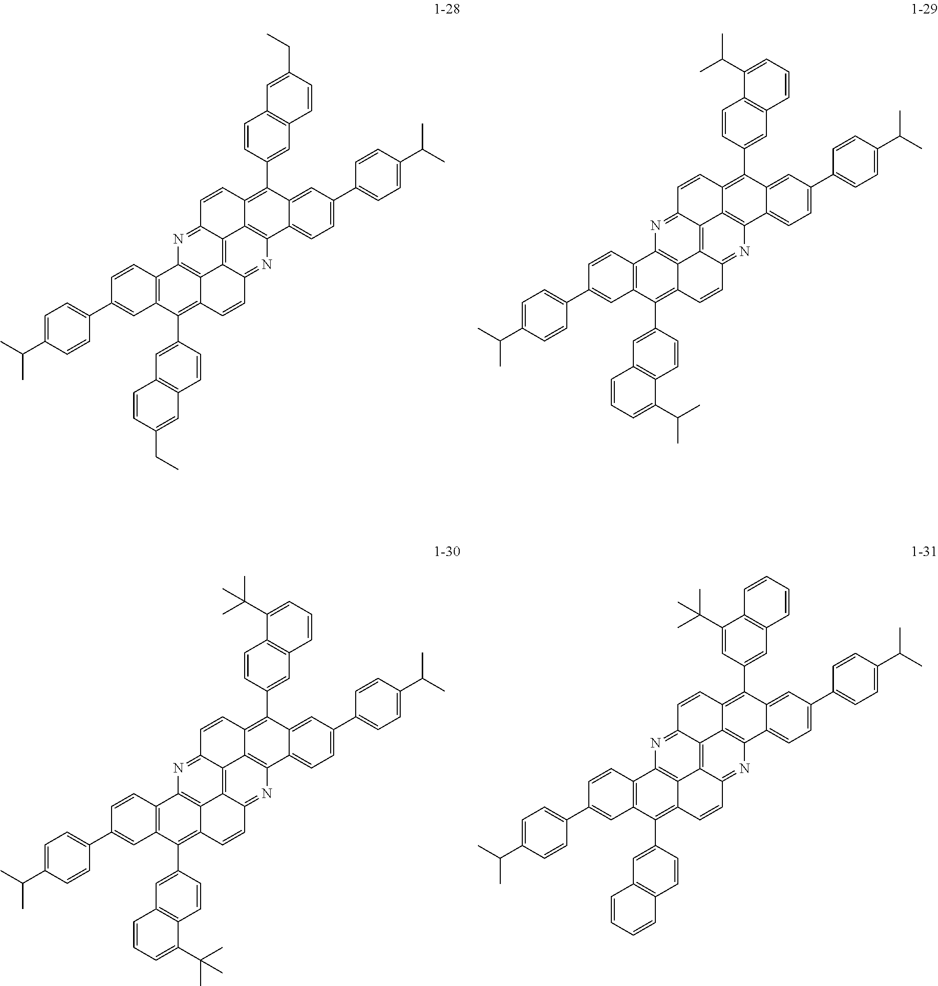

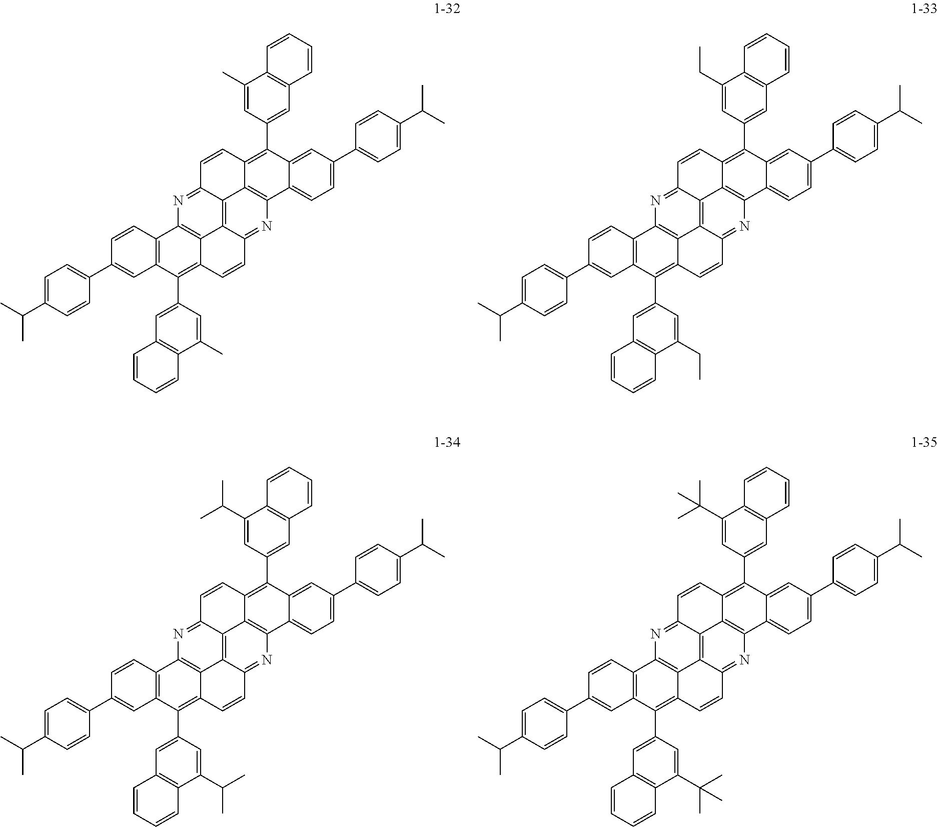

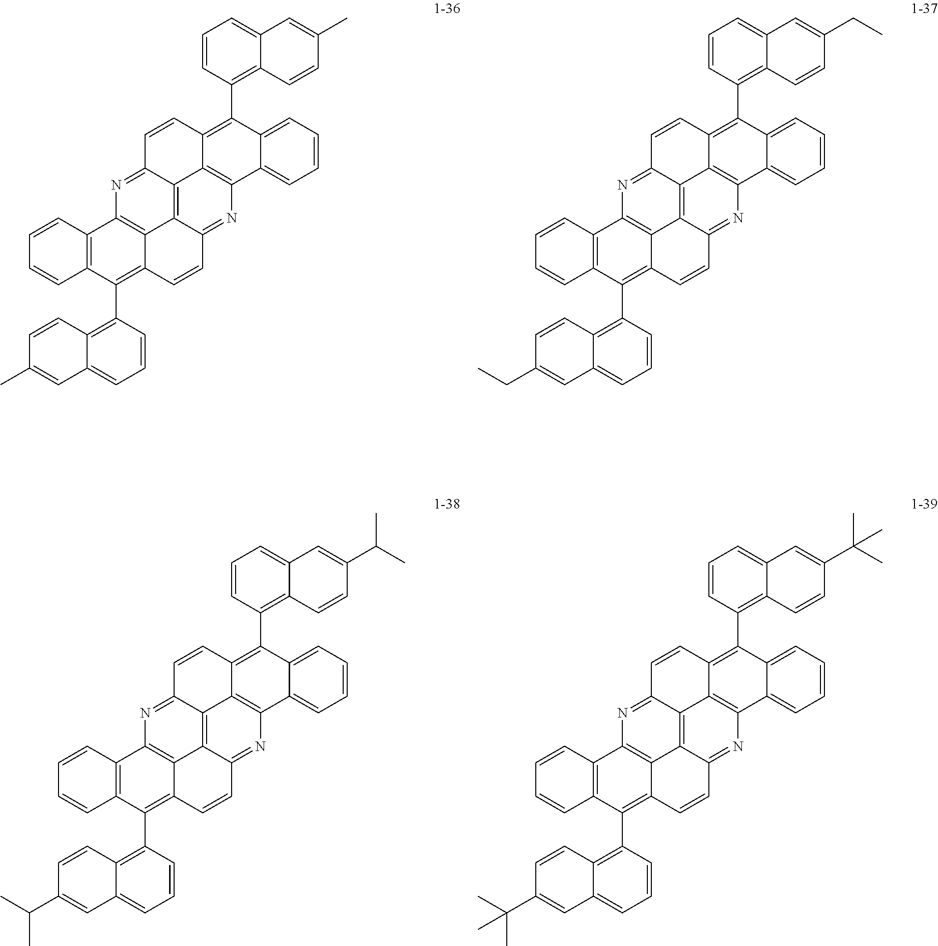

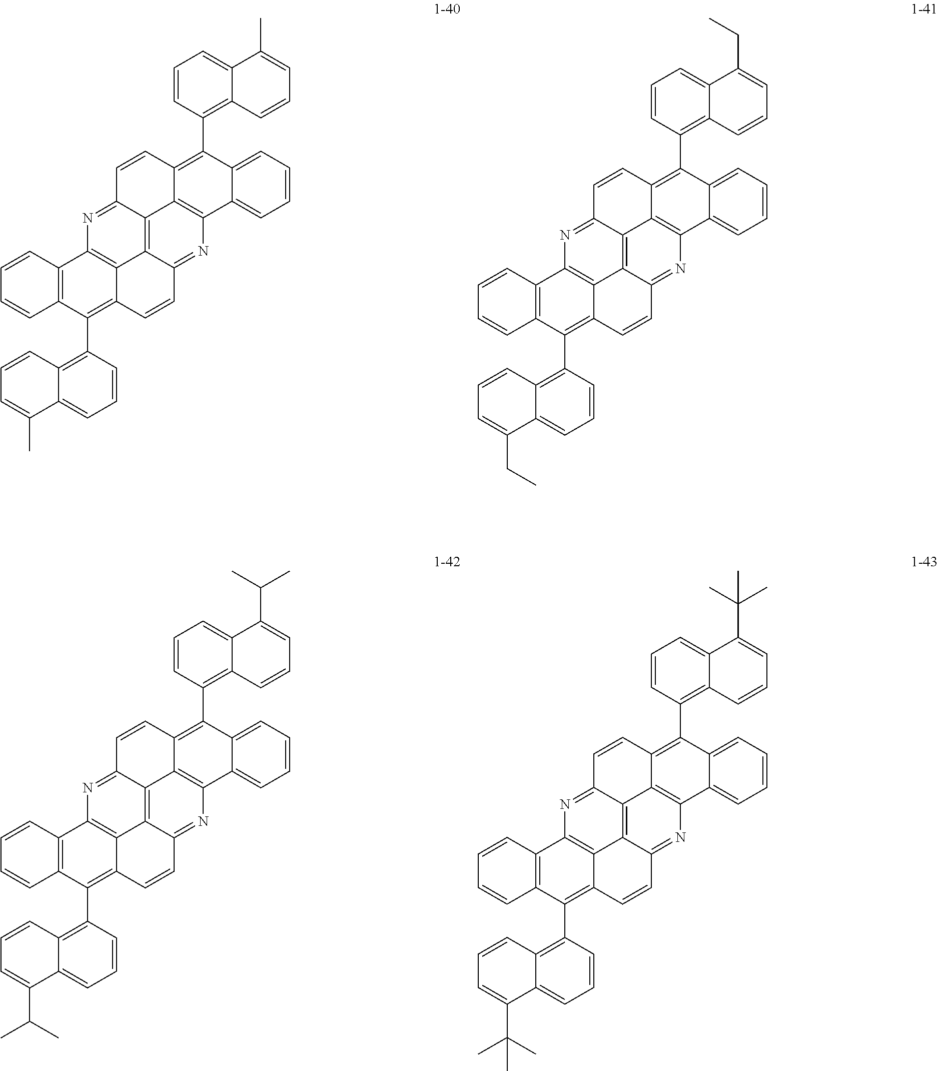 [SMILES: Cc1cccc2c(-c3c4ccccc4c4nc5ccc6c(-c7cccc8c(C)cccc78)c7ccccc7c7nc8ccc3c4c8c5c67)cccc12 ; CCc1cccc2c(-c3c4ccccc4c4nc5ccc6c(-c7cccc8c(CC)cccc78)c7ccccc7c7nc8ccc3c4c8c5c67)cccc12 ; CC(C)c1cccc2c(-c3c4ccccc4c4nc5ccc6c(-c7cccc8c(C(C)C)cccc78)c7ccccc7c7nc8ccc3c4c8c5c67)cccc12 ; CC(C)(C)c1cccc2c(-c3c4ccccc4c4nc5ccc6c(-c7cccc8c(C(C)(C)C)cccc78)c7ccccc7c7nc8ccc3c4c8c5c67)cccc12]

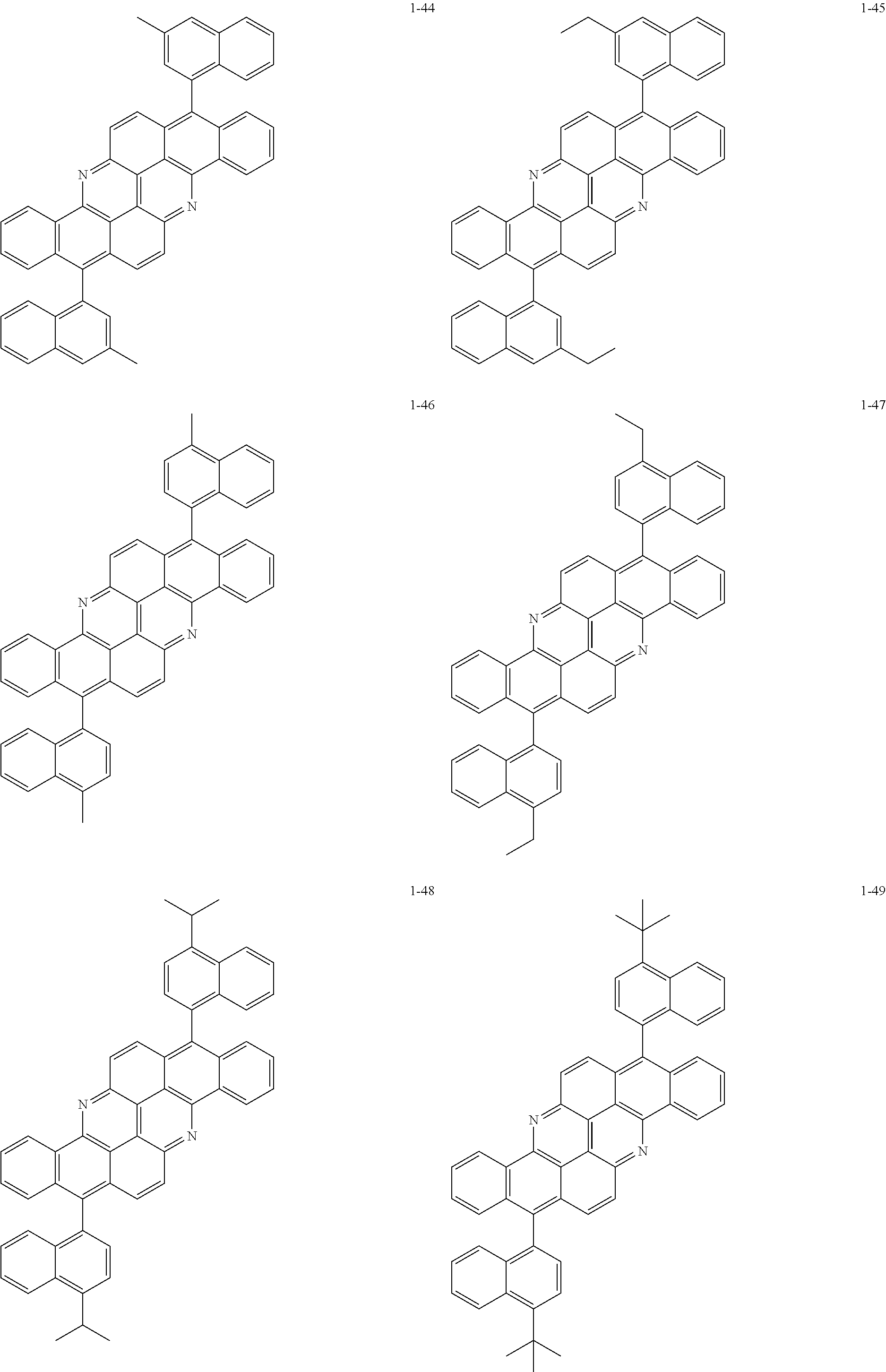

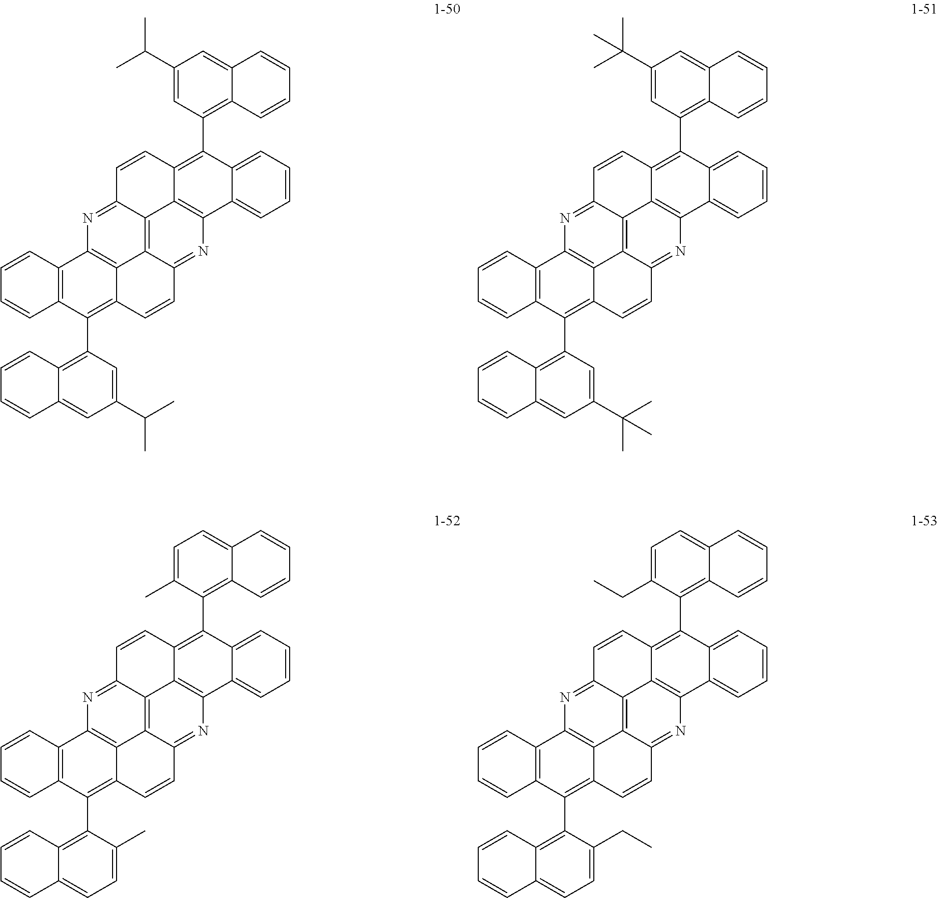 [SMILES: CC(C)c1cc(-c2c3ccccc3c3nc4ccc5c(-c6cc(C(C)C)cc7ccccc67)c6ccccc6c6nc7ccc2c3c7c4c56)c2ccccc2c1 ; CC(C)(C)c1cc(-c2c3ccccc3c3nc4ccc5c(-c6cc(C(C)(C)C)cc7ccccc67)c6ccccc6c6nc7ccc2c3c7c4c56)c2ccccc2c1 ; Cc1ccc2ccccc2c1-c1c2ccccc2c2nc3ccc4c(-c5c(C)ccc6ccccc56)c5ccccc5c5nc6ccc1c2c6c3c45 ; CCc1ccc2ccccc2c1-c1c2ccccc2c2nc3ccc4c(-c5c(CC)ccc6ccccc56)c5ccccc5c5nc6ccc1c2c6c3c45]

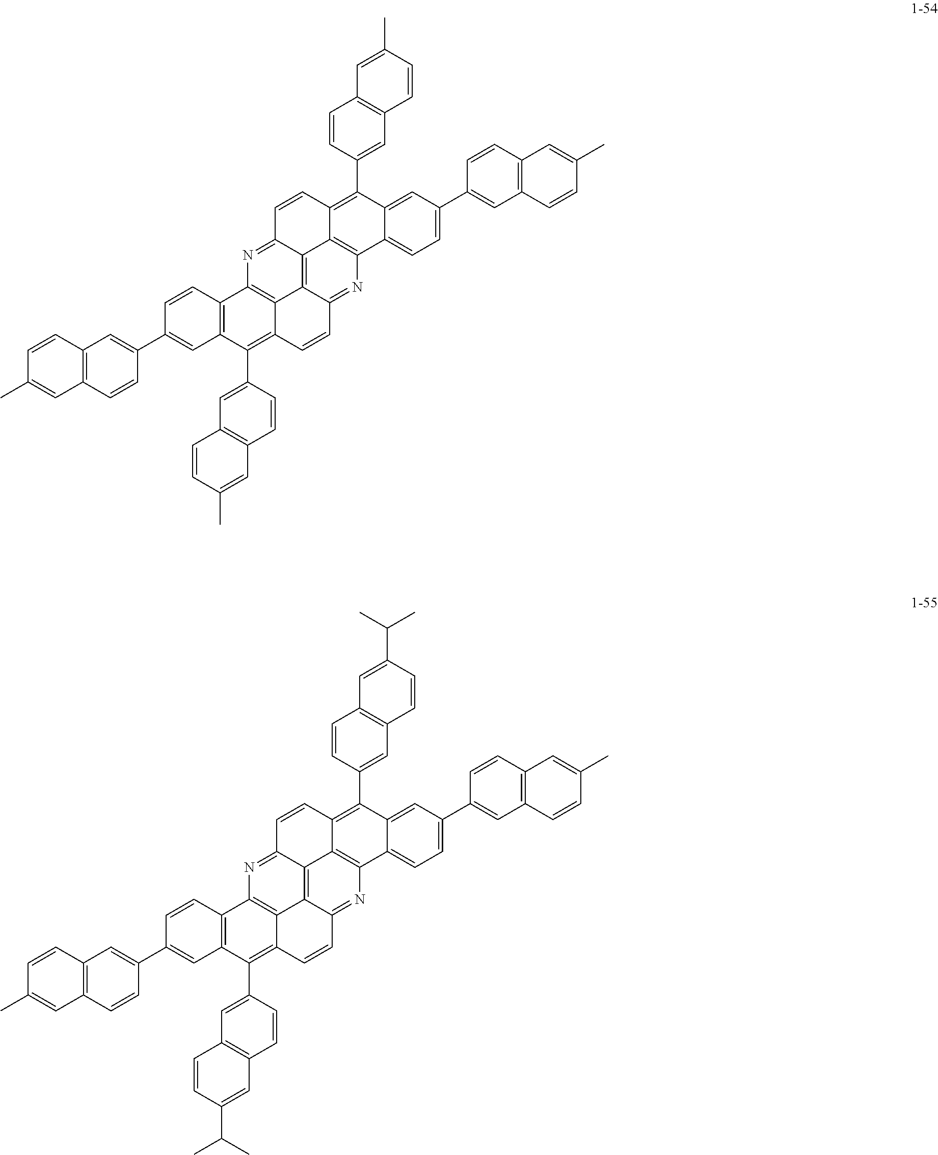

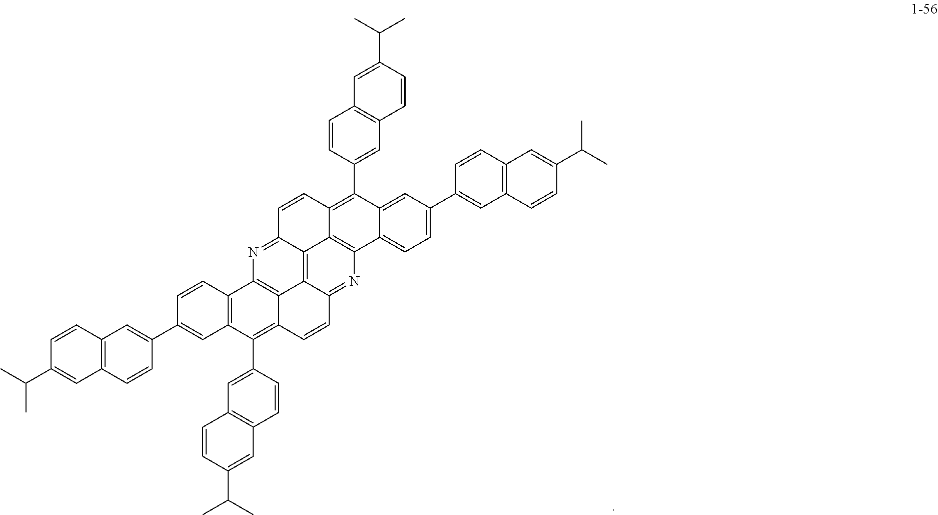 [SMILES: CC(C)c1ccc2cc(-c3ccc4c(c3)c(-c3ccc5cc(C(C)C)ccc5c3)c3ccc5nc6c7ccc(-c8ccc9cc(C(C)C)ccc9c8)cc7c(-c7ccc8cc(C(C)C)ccc8c7)c7ccc8nc4c3c5c8c76)ccc2c1]

The first compound 342 having the structure of Chemical Formulae 1, 2A, 2B and 3 includes fused ring system of multiple aromatic or heteroaromatic rings to have a wide plate-like structure. The singlet exciton energy of the second compound 344 may be transferred efficiently to the singlet exciton of the first compound 342 having the structure of Chemical Formulae 1, 2A, 2B and 3. The OLED D1 may realize beneficial luminous efficiency, luminous lifespan and color purity by introducing the first compound having the structure of Chemical Formulae 1, 2A, 2B and 3 into the EML 340.

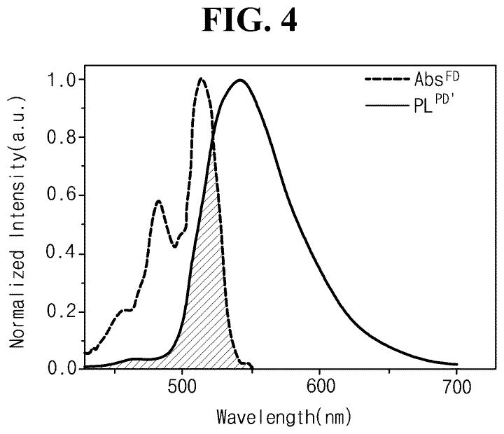

It may be necessary to increase overlap degree between: (i) the absorption wavelength or absorption spectrum of the first compound 342 and (ii) the luminescence wavelength or luminescence spectrum of the second compound 344 so as to transfer efficiently exciton energy generated at the second compound 344 to the first compound 342. FIG. 4 illustrates spectra of luminous materials of lower luminous efficiency with small overlap degree between: (i) the absorption wavelength or absorption spectrum of the first compound and (ii) the luminescence wavelength or luminescence spectrum of the second compound. As illustrated in FIG. 4, the first compound 342 of the fluorescent emitter has maximum absorption peak between about 510 nm and about 530 nm in the absorption spectrum Abs^{FD}.

When the second compound has a luminescence peak in the luminescence spectrum PL^{PD′} more than about 530 nm, the overlap degree between the absorption spectrum Abs^{FD} of the first compound and the luminescence spectrum PL^{PD′} of the second compound is less than 30%. As such, when the second compound having luminescence spectrum PL^{PD′} in the range of longer wavelength range is used together with the first compound, the exciton energy of the second compound may not be transferred efficiently to the first compound.

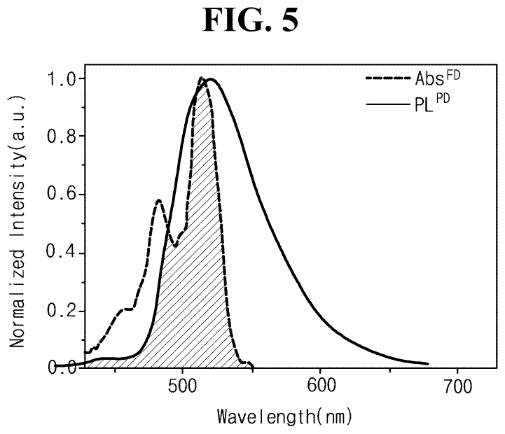

FIG. 5 illustrates spectra of luminous materials of beneficial luminous efficiency with large overlap degree between: (i) the absorption wavelength or absorption spectrum of the first compound and (ii) the luminescence wavelength or luminescence spectrum of the second compound. As illustrated in FIG. 5, the second compound 344 includes an electron-withdrawing group so that the luminescence spectrum PL^{PD} of the second compound 344 is shifted to a shorter wavelength. In this case, the overlap degree between the absorption spectrum Abs' of the first compound 342 and the luminescence spectrum PL^{PD} of the second compound 344 of the total area in the luminescence spectrum PL^{PD} of the second compound 344 may be, but is not limited to, 30% or more, for example, between about 30% and about 50%.

As illustrated in FIG. 5, when the second compound 344 having luminescence spectrum PL^{PD} in the shorter wavelength range is used together with the first compound 342, the exciton energy of the second compound 344 may be transferred efficiently to the first compound 342. In one example embodiment, the second compound 344 may have a maximum luminescence wavelength between about 520 nm and about 530 nm. The distance between the maximum absorption wavelength of the first compound 342 and the maximum luminescence wavelength of the second compound 344 may be, but is not limited to, about 30 nm or less, for example, between about 10 nm and about 30 nm or between about 10 nm and about 20 nm.

In an example embodiment illustrated in FIG. 3, the second compound 344 may include an organometallic compound of phosphorescent material substituted with at least one electron-withdrawing group. For example, the second compound 344 may be an iridium-based organometallic compound with the following structure of Chemical Formula 4:

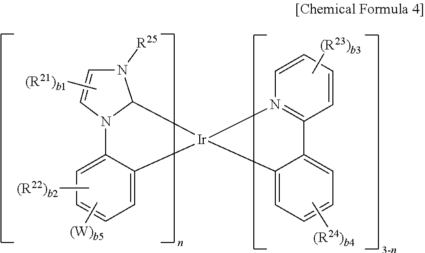

wherein, in the Chemical Formula 4,
each of R²¹, R²², R²³, and R²⁴ is independently an unsubstituted or substituted C₁-C₂₀ alkyl group, an unsubstituted or substituted C₁-C₂₀ alkyl amino group, an unsubstituted or substituted C₆-C₃₀ aryl group, an unsubstituted or substituted C₃-C₃₀ heteroaryl group, an unsubstituted or substituted C₆-C₃₀ aryl amino group or an unsubstituted or substituted C₃-C₃₀ heteroaryl amino group, where each R²¹ is identical to or different from each other when b1 is 2, each R²² is identical to or different from each other when b2 is 2 or 3, each R²³ is identical to or different from each other when b3 is 2, 3 or 4, and each R²⁴ is identical to or different from each other when b4 is 2, 3 or 4, or
optionally, two adjacent R²¹ when bi is 2, two adjacent R²² when b2 is 2 or 3, two adjacent R²³ when b3 is 2, 3 or 4, and/or two adjacent R²⁴ when b4 is 2, 3 or 4 are linked together to form an unsubstituted or substituted C₆-C₂₀ aromatic ring or an unsubstituted or substituted C₃-C₂₀ heteroaromatic ring;
R²⁵ is hydrogen or an unsubstituted or substituted C₁-C₂₀ alkyl group;
W is a cyano group, a nitro group, a halogen atom, a C1-C₂₀ alkyl group, a C₆-C₃₀ aryl group or a C₃-C₃₀ heteroaryl group, where each of the C₁-C₂₀ alkyl group, the C₆-C₃₀ aryl group, and the C₃-C₃₀ heteroaryl group is optionally substituted with at least one group selected from a cyano group, a nitro group, and a halogen atom;
b1 is 0, 1 or 2;
b2 is 0, 1, 2 or 3;
each of b3 and b4 is independently 0, 1, 2, 3 or 4;
b5 is 1 or 2, where b2+b5=1, 2, 3 or 4; and
n is 1, 2 or 3.

Since the second compound 344 having the structure of Chemical Formula 4 includes at least one electron-withdrawing group W in the ligand, its luminescence spectrum PL^{PD} (FIG. 5) may be shifted to the shorter wavelength range. The overlap degree between the luminescence spectrum PL^{PD} of the second compound 344 and the absorption spectrum Abs^{FD} (FIG. 5) of the first compound is increased. Accordingly, the exciton energy of the second compound 344 may be transferred efficiently to the singlet exciton of the first compound 342. The EML 340 may be a phosphor-sensitized fluorescence (PSF) emitting material layer in that the exciton energy of the second compound 344 of the phosphorescent material as the assistant emitter is transferred to the first compound 342 of fluorescent emitter.

For example, in Chemical Formula 4, b1 is 0, or two R²¹ may be further linked together to form a benzene ring when b1 may be 2, b2 may be 0, b3 may be 1, R²³ may be a C₆-C₃₀ aryl group (e.g., phenyl), b4 may be 0, R²⁵ may be a C₁-C₁₀ alkyl group (e.g., methyl or ethyl), n may be 1 or 2 (e.g., 1), and W may be at least one of halogen (e.g., F, Cl, Br or I) and/or a cyano group.

In some embodiments, the second compound 344 having at least one electron-withdrawing group may be, but is not limited to, at least one of the following organometallic compounds of Chemical Formula 5:

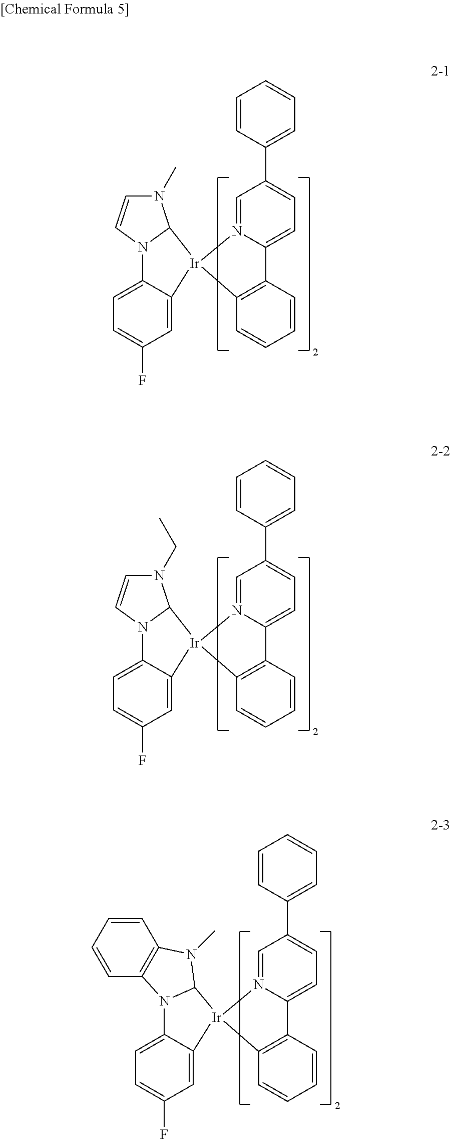

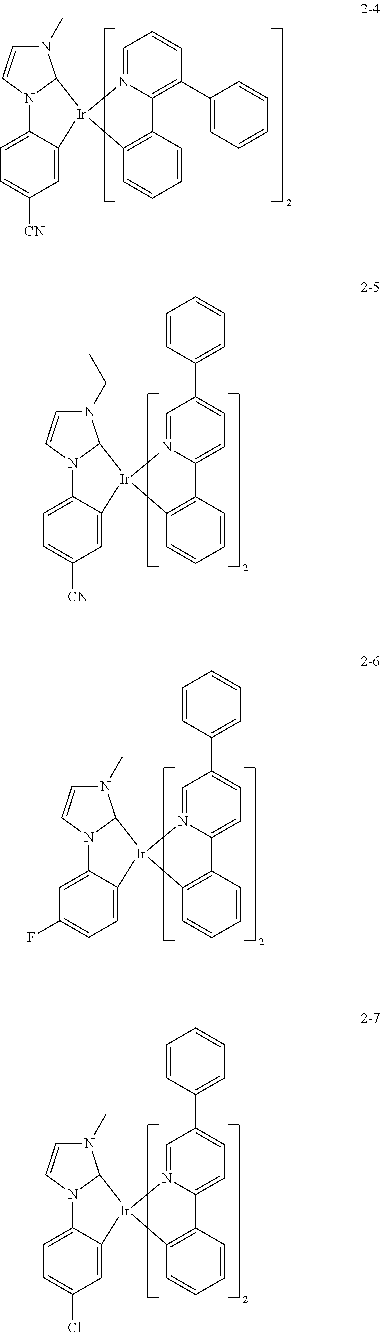

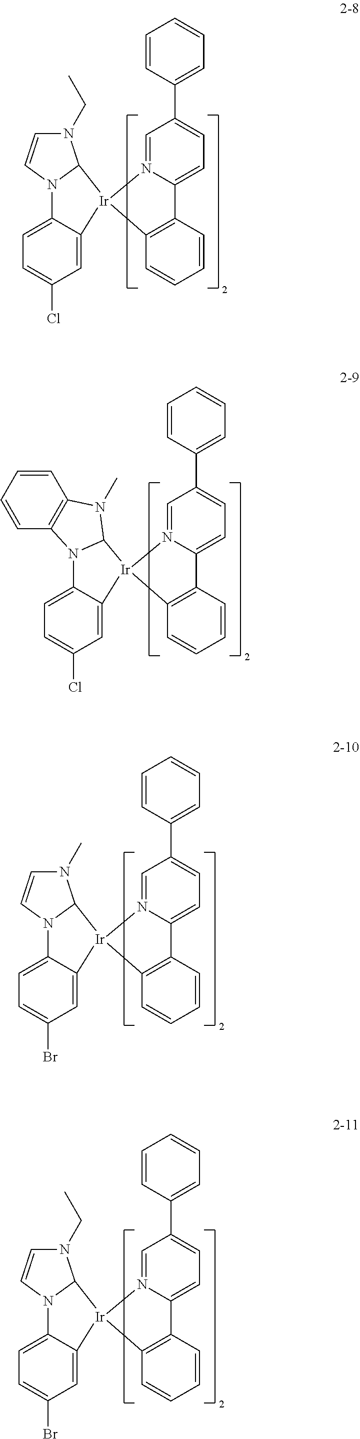

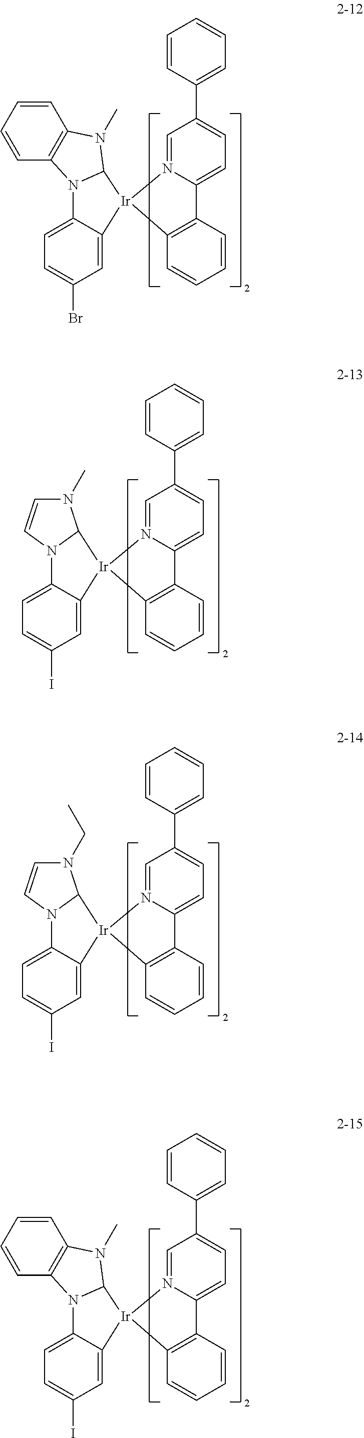

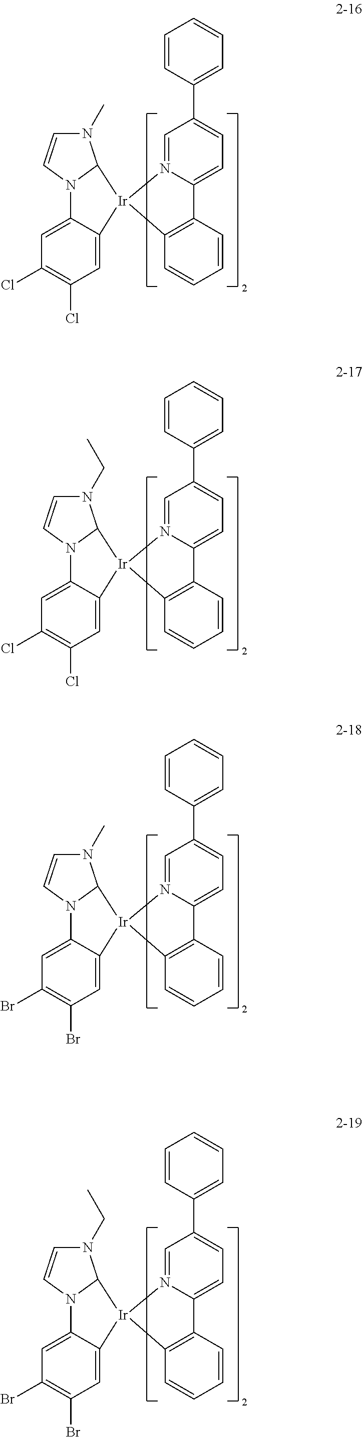

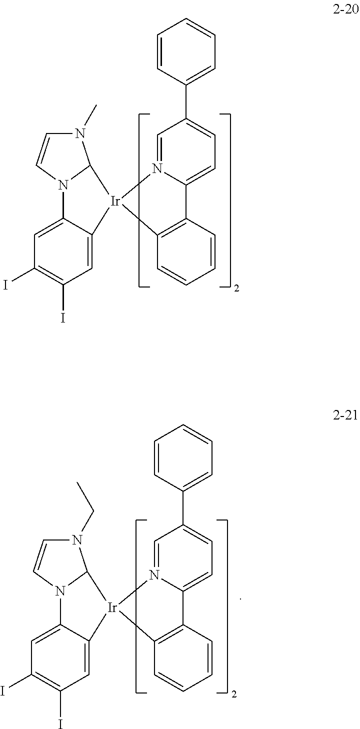

The third compound 346 may be a P-type host (hole-type host) with relatively advantageous hole affinity. For example, the third compound 346 may include, but is not limited to, a carbazole-based organic compound, an aryl amine-based or heteroaryl amine-based organic compound with at least one fused aromatic or fused heteroaromatic moiety, and/or an aryl amine-based or heteroaryl amine-based organic compound with a spirofluorene moiety.

In one example embodiment, the third compound 346 may be a carbazole-based organic compound with the following structure of Chemical Formula 6:

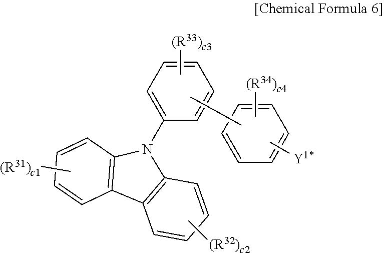

wherein, in the Chemical Formula 6,
each of R³¹ and R³² is independently an unsubstituted or substituted C₁-C₂₀ alkyl group or an unsubstituted or substituted C₆-C₃₀ aryl group, where each R³¹ is identical to or different from each other when c1 is 2, 3 or 4, and each R³² is identical to or different from each other when c2 is 2, 3 or 4;
each of R³³ and R³⁴ is independently an unsubstituted or substituted C₁-C₂₀ alkyl group or an unsubstituted or substituted C₆-C₃₀ aryl group, where each R³³ is identical to or different from each other when c3 is 2, 3 or 4, and each R³⁴ is identical to or different from each other when c4 is 2, 3 or 4, or R³³ and R³⁴ are further linked together to form a heteroring;
Y¹ is represented by following Chemical Formula 7A or Chemical Formula 7B;
each of c1, c2, c3 and c4 is independently 0, 1, 2, 3 or 4; and
asterisk indicates a link position to the Chemical Formula 7A or Chemical Formula 7B,

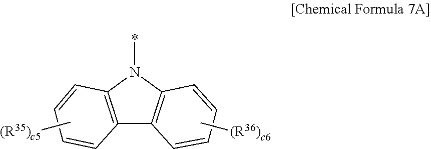

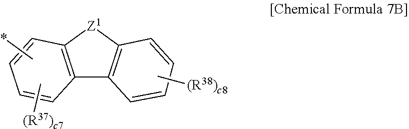

wherein, in the Chemical Formulae 7A and 7B,
each of R³⁵, R³⁶, R³⁷ and R³⁸ is independently an unsubstituted or substituted C₁-C₂₀ alkyl group or an unsubstituted or substituted C₆-C₃₀ aryl group, where each R³⁵ is identical to or different from each other when c5 is 2, 3 or 4, each R³⁶ is identical to or different from each other when c6 is 2, 3 or 4, each R³⁷ is identical to or different from each other when c7 is 2, or 3 and each R³⁸ is identical to or different from each other when c8 is 2, 3 or 4;
Z¹ is NR³⁹, O or S, where R³⁹ is hydrogen, an unsubstituted or substituted C₁-C₂₀ alkyl group or an unsubstituted or substituted C₆-C₃₀ aryl group; and
asterisk indicates a link position to the Chemical Formula 6.

For example, the carbazolyl moiety including R³¹ and R³² and the phenyl moiety including R³⁴ in Chemical Formula 6 may be linked to an ortho-, meta- or para-position to the benzene ring with R³³. In addition, R³³ and R³⁴ are further linked together to form a 5-membered heteroaromatic ring including a nitrogen atom, an oxygen atom and/or a sulfur atom. The nitrogen atom in the 5-membered heteroaromatic ring formed by R³³ and R³⁴ may be unsubstituted or substituted with a C₆-C₂₀ aryl group (e.g., phenyl). In some embodiments, R³³ or R³⁴ may be linked to the adjacent 6-membered aromatic ring to form a heteroring that includes a nitrogen atom, an oxygen atom and/or a sulfur atom and that is optionally substituted with an unsubstituted or substituted C₆-C₃₀ aryl group.

As an example, the third compound 346 having the structure of Chemical Formula 6 may be, but is not limited to, the following organic compounds of Chemical Formula 8:

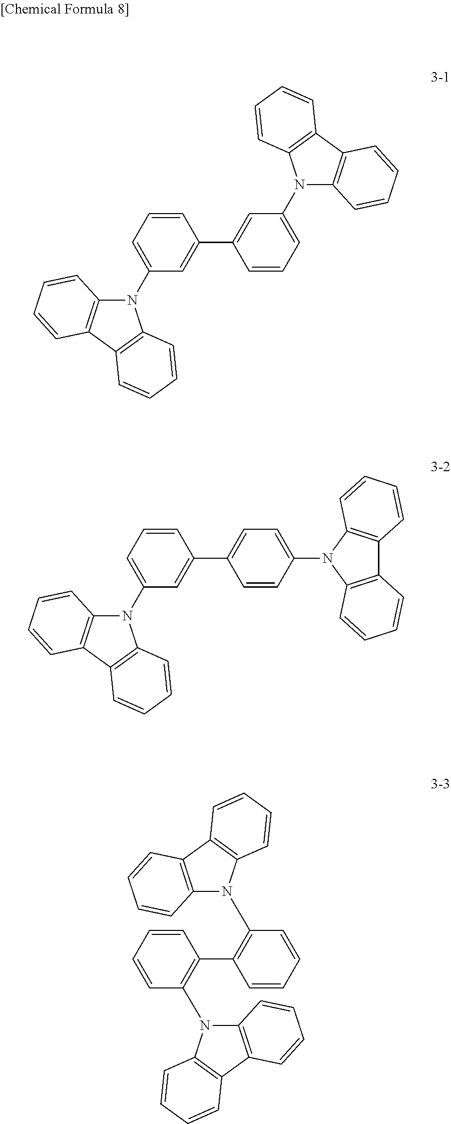 [SMILES: c1cc(-c2cccc(-n3c4ccccc4c4ccccc43)c2)cc(-n2c3ccccc3c3ccccc32)c1 ; c1cc(-c2ccc(-n3c4ccccc4c4ccccc43)cc2)cc(-n2c3ccccc3c3ccccc32)c1 ; c1ccc(-n2c3ccccc3c3ccccc32)c(-c2ccccc2-n2c3ccccc3c3ccccc32)c1]

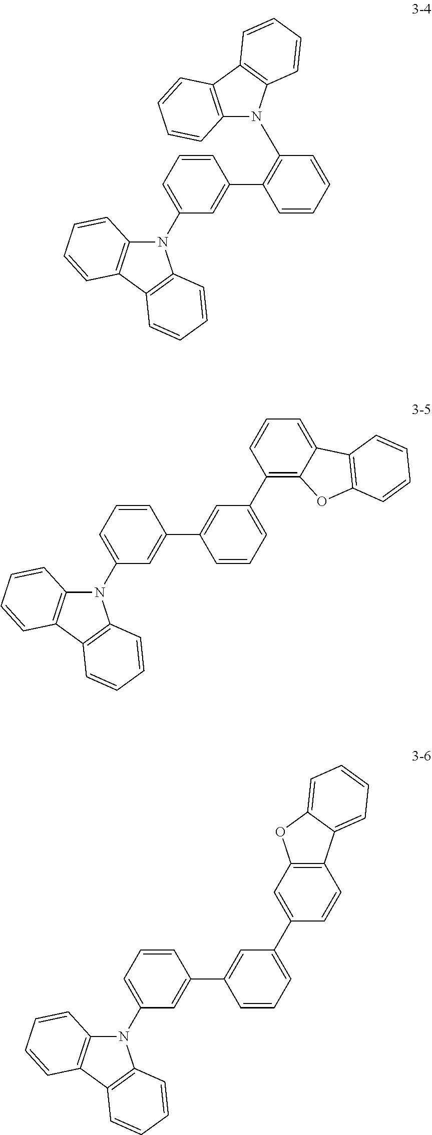 [SMILES: c1cc(-c2ccccc2-n2c3ccccc3c3ccccc32)cc(-n2c3ccccc3c3ccccc32)c1 ; c1cc(-c2cccc(-n3c4ccccc4c4ccccc43)c2)cc(-c2cccc3c2oc2ccccc23)c1 ; c1cc(-c2cccc(-n3c4ccccc4c4ccccc43)c2)cc(-c2ccc3c(c2)oc2ccccc23)c1]

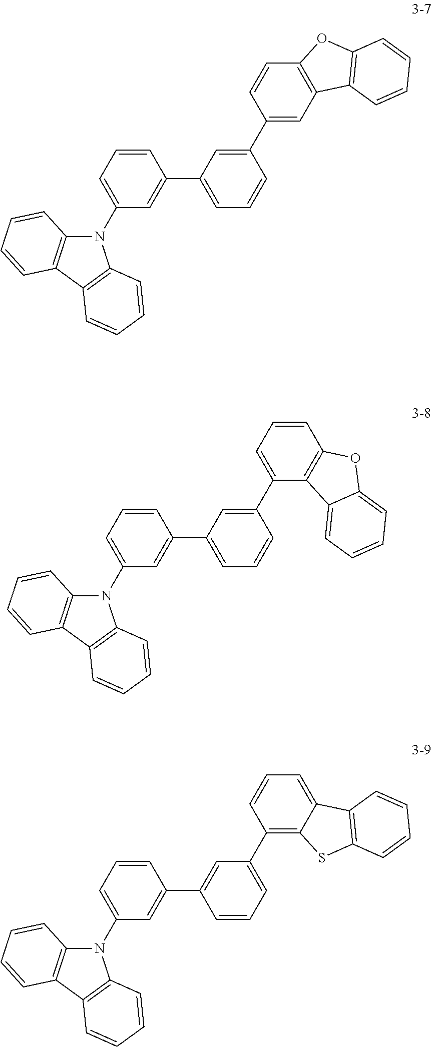 [SMILES: c1cc(-c2cccc(-n3c4ccccc4c4ccccc43)c2)cc(-c2ccc3oc4ccccc4c3c2)c1 ; c1cc(-c2cccc(-n3c4ccccc4c4ccccc43)c2)cc(-c2cccc3oc4ccccc4c23)c1 ; c1cc(-c2cccc(-n3c4ccccc4c4ccccc43)c2)cc(-c2cccc3c2sc2ccccc23)c1]

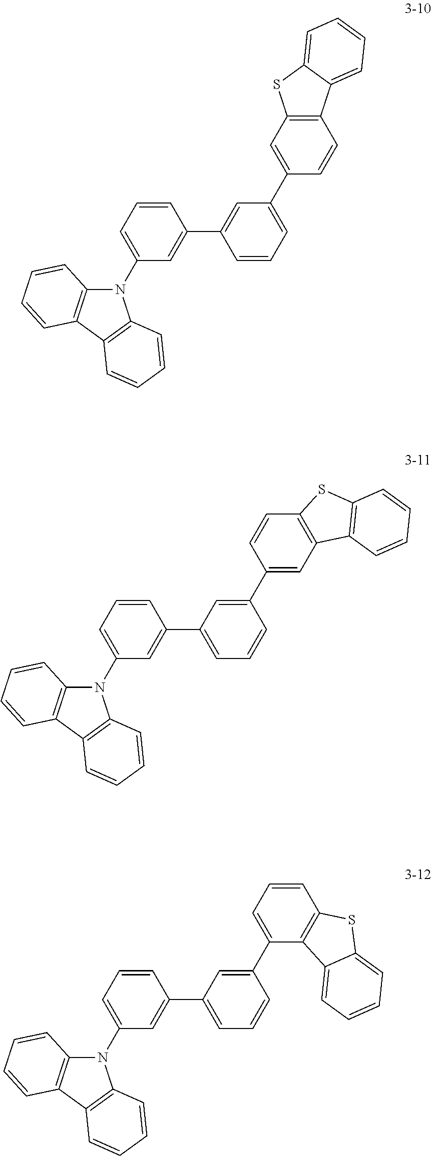 [SMILES: c1cc(-c2cccc(-n3c4ccccc4c4ccccc43)c2)cc(-c2ccc3c(c2)sc2ccccc23)c1 ; c1cc(-c2cccc(-n3c4ccccc4c4ccccc43)c2)cc(-c2ccc3sc4ccccc4c3c2)c1 ; c1cc(-c2cccc(-n3c4ccccc4c4ccccc43)c2)cc(-c2cccc3sc4ccccc4c23)c1]

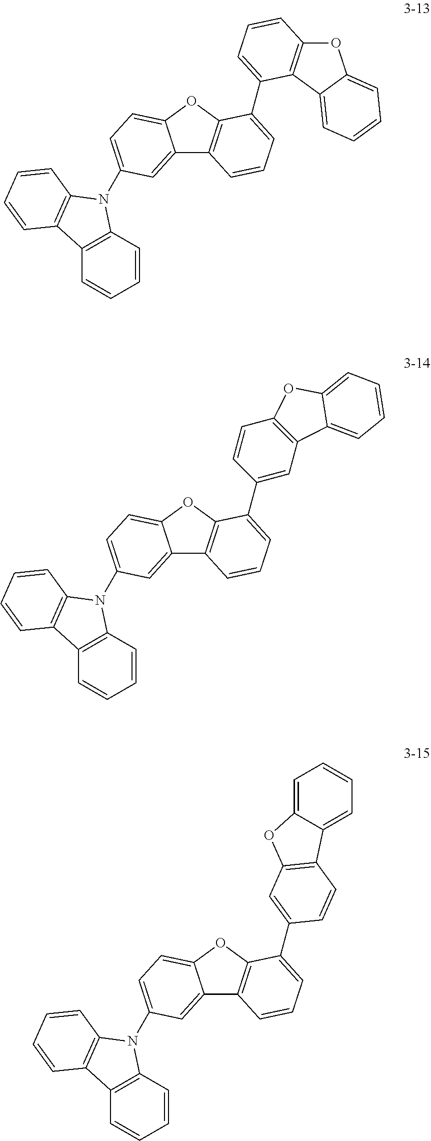 [SMILES: c1ccc2c(c1)oc1cccc(-c3cccc4c3oc3ccc(-n5c6ccccc6c6ccccc65)cc34)c12 ; c1ccc2c(c1)oc1ccc(-c3cccc4c3oc3ccc(-n5c6ccccc6c6ccccc65)cc34)cc12 ; c1ccc2c(c1)oc1cc(-c3cccc4c3oc3ccc(-n5c6ccccc6c6ccccc65)cc34)ccc12]

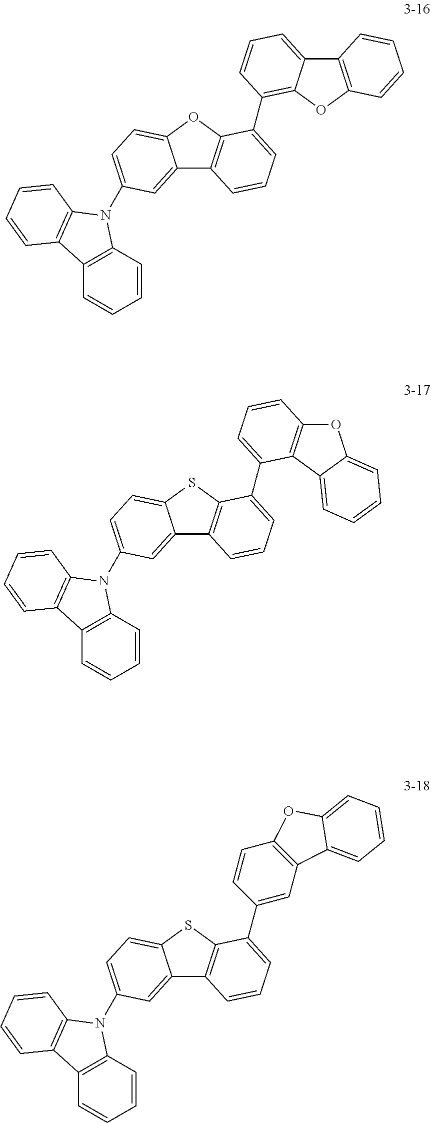 [SMILES: c1ccc2c(c1)oc1c(-c3cccc4c3oc3ccc(-n5c6ccccc6c6ccccc65)cc34)cccc12 ; c1ccc2c(c1)oc1cccc(-c3cccc4c3sc3ccc(-n5c6ccccc6c6ccccc65)cc34)c12 ; c1ccc2c(c1)oc1ccc(-c3cccc4c3sc3ccc(-n5c6ccccc6c6ccccc65)cc34)cc12]

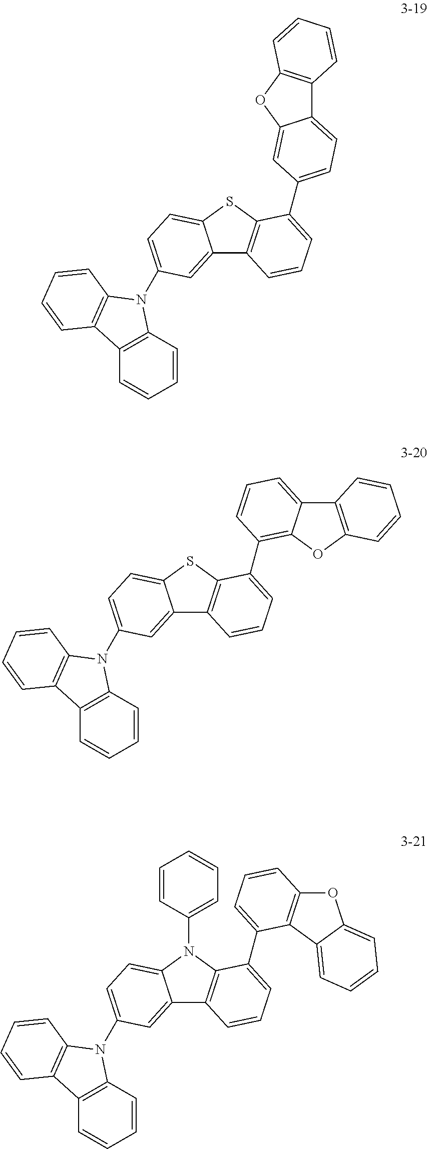 [SMILES: c1ccc2c(c1)oc1cc(-c3cccc4c3sc3ccc(-n5c6ccccc6c6ccccc65)cc34)ccc12 ; c1ccc2c(c1)oc1c(-c3cccc4c3sc3ccc(-n5c6ccccc6c6ccccc65)cc34)cccc12 ; c1ccc(-n2c3ccc(-n4c5ccccc5c5ccccc54)cc3c3cccc(-c4cccc5oc6ccccc6c45)c32)cc1]

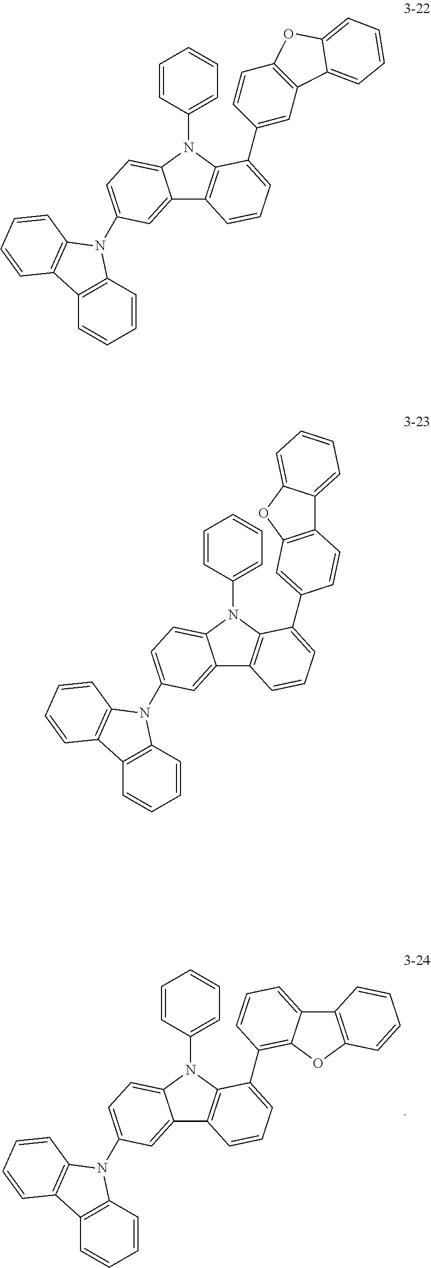 [SMILES: c1ccc(-n2c3ccc(-n4c5ccccc5c5ccccc54)cc3c3cccc(-c4ccc5oc6ccccc6c5c4)c32)cc1 ; c1ccc(-n2c3ccc(-n4c5ccccc5c5ccccc54)cc3c3cccc(-c4ccc5c(c4)oc4ccccc45)c32)cc1 ; c1ccc(-n2c3ccc(-n4c5ccccc5c5ccccc54)cc3c3cccc(-c4cccc5c4oc4ccccc45)c32)cc1]

The fourth compound 348 may be an N-type host (electron-type host) with relatively advantageous electron affinity. For example, the fourth compound 348 may include an azine-based (e.g., pyrimidine-based or triazine-based) organic compound. In some embodiments, the fourth compound 348 may include an organic compound having the following structure of Chemical Formula 9:

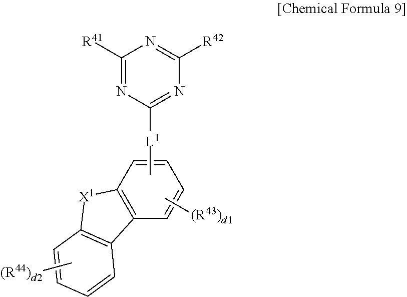

wherein, in the Chemical Formula 9,
X¹ is O or S;
each of R⁴¹, R⁴², R⁴³, and R⁴⁴ is independently an unsubstituted or substituted C₁-C₂₀ alkyl group, an unsubstituted or substituted C₁-C₂₀ alkyl amino group, an unsubstituted or substituted C₆-C₃₀ aryl group, an unsubstituted or substituted C₃-C₃₀ heteroaryl group, an unsubstituted or substituted C₆-C₃₀ aryl amino group or an unsubstituted or substituted C₃-C₃₀ heteroaryl amino group, where each R⁴³ is identical to or different from each other when d1 is 2 or 3, each R⁴⁴ is identical to or different from each other when d2 is 2, 3 or 4, or
optionally,
two adjacent R⁴³ when d1 is 2 or 3 and/or two adjacent R⁴⁴ when d2 is 2, 3 or 4 are linked together to form an unsubstituted or substituted C₆-C₂₀ aromatic ring or an unsubstituted or substituted C₃-C₂₀ heteroaromatic ring;
L¹ is a single bond or an unsubstitued or substituted C₆-C₃₀ arylene group;
d1 is 0, 1, 2 or 3; and
d2 is 0, 1, 2, 3 or 4.

For example, each of R⁴¹ and R⁴² in Chemical Formula 9 may be independently an unsubstituted or substituted C₆-C₃₀ aryl group (e.g., phenyl or naphthyl). Two adjacent R⁴³ and/or two adjacent R⁴⁴ in Chemical Formula 9 may be independently linked together to form an indene ring, an indole ring, a benzofuran ring and/or a benzothiophene ring each of which is independently unsubstituted or substituted with a C₆-C₃₀ aryl group (e.g., phenyl), and each of d1 and d2 in Chemical Formula 9 may be independently 0, 1 or 2. In addition, L¹ in Chemical Formula 9 may be a phenylene group or a naphthylene group.

As an example, in Chemical Formula 9, R⁴¹ may be phenyl and R⁴² may be naphthyl. The fourth compound 348 with such a structure may have the following structure of Chemical Formula 10:

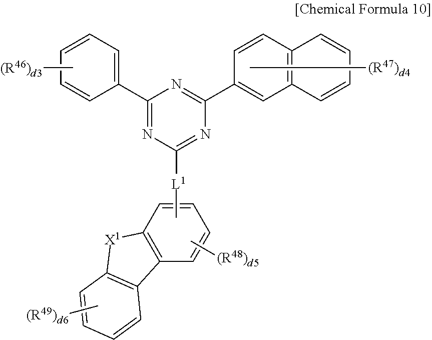

wherein, in the Chemical Formula 10,
each of X¹ and L¹ is as defined in Chemical Formula 9;
each of R⁴⁶, R⁴⁷, R⁴⁸ and R⁴⁹ is independently an unsubstituted or substituted C₁-C₂₀ alkyl group, an unsubstituted or substituted C₆-C₃₀ aryl group or an unsubstituted or substituted C₃-C₃₀ heteroaryl group, where each R⁴⁶ is identical to or different from each other when d3 is 2, 3, 4 or 5, each R⁴⁷ is identical to or different from each other when d4 is 2, 3, 4, 5, 6 or 7, each R⁴⁸ is identical to or different from each other when d5 is 2 or 3 and each R⁴⁹ is identical to or different from each other when d6 is 2, 3 or 4, or
optionally,
two adjacent R⁴⁶ when d3 is 2, 3, 4 or 5 and/or two adjacent R⁴⁷ when d4 is 2, 3, 4, 5, 6 or 7 are linked together to form an unsubstituted or substituted C₆-C₂₀ aromatic ring;
d3 is 0, 1, 2, 3, 4 or 5;
d4 is 0, 1, 2, 3, 4, 5, 6 or 7;
d5 is 0, 1, 2 or 3; and
d6 is 0, 1, 2, 3 or 4.

For example, each of d3 and d4 in Chemical Formula 10 may be 0. In Chemical Formula 10, one of d5 and d6 may be 0 and the other of d5 and d6 may be 2. In this case, two adjacent R⁴⁸ or two adjacent R⁴⁹ in Chemical Formula 10 may be further linked together to form a fused ring.

In some embodiments, the fourth compound 348 may be, but is not limited to, at least one of the following organic compounds of Chemical Formula 11.

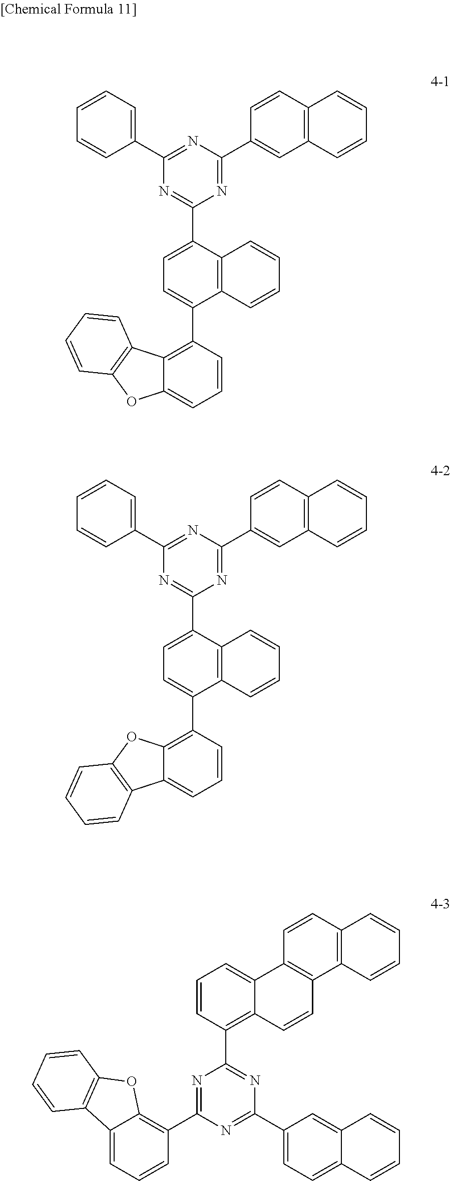 [SMILES: c1ccc(-c2nc(-c3ccc4ccccc4c3)nc(-c3ccc(-c4cccc5oc6ccccc6c45)c4ccccc34)n2)cc1 ; c1ccc(-c2nc(-c3ccc4ccccc4c3)nc(-c3ccc(-c4cccc5c4oc4ccccc45)c4ccccc34)n2)cc1 ; c1ccc2cc(-c3nc(-c4cccc5c4ccc4c6ccccc6ccc54)nc(-c4cccc5c4oc4ccccc45)n3)ccc2c1]

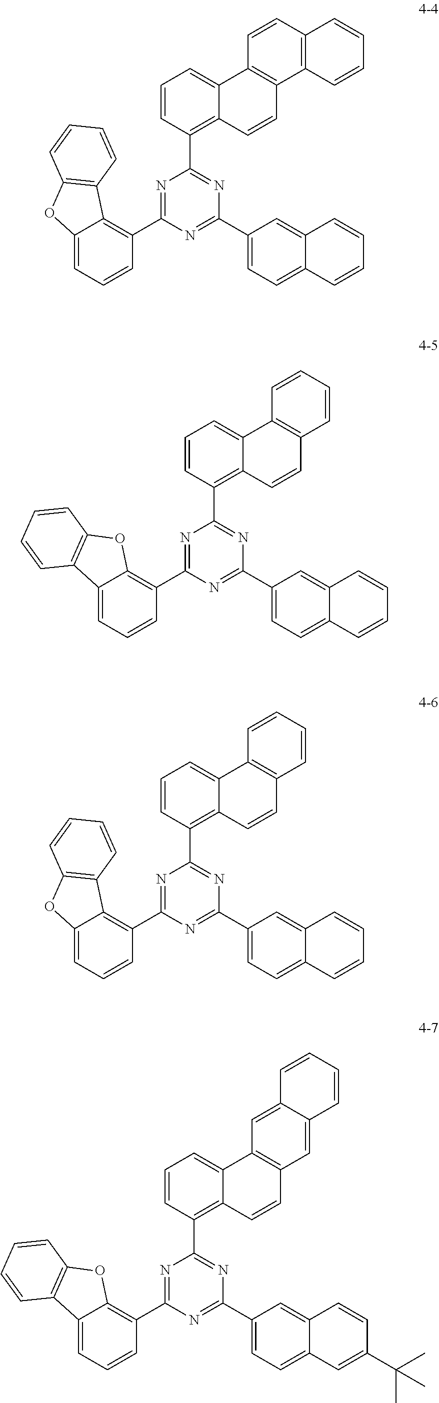 [SMILES: c1ccc2cc(-c3nc(-c4cccc5c4ccc4c6ccccc6ccc54)nc(-c4cccc5oc6ccccc6c45)n3)ccc2c1 ; c1ccc2cc(-c3nc(-c4cccc5c4ccc4ccccc45)nc(-c4cccc5c4oc4ccccc45)n3)ccc2c1 ; c1ccc2cc(-c3nc(-c4cccc5c4ccc4ccccc45)nc(-c4cccc5oc6ccccc6c45)n3)ccc2c1 ; CC(C)(C)c1ccc2cc(-c3nc(-c4cccc5c4ccc4cc6ccccc6cc45)nc(-c4cccc5c4oc4ccccc45)n3)ccc2c1]

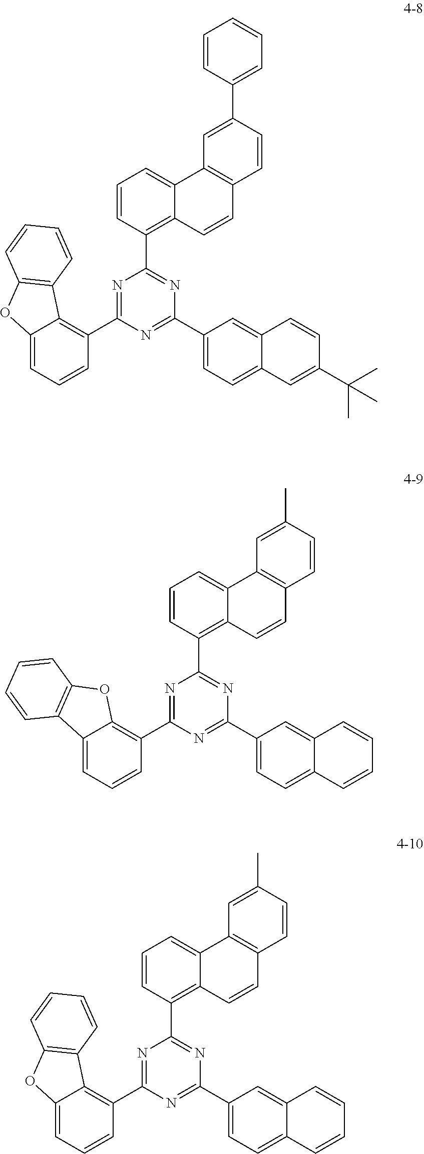 [SMILES: CC(C)(C)c1ccc2cc(-c3nc(-c4cccc5c4ccc4ccc(-c6ccccc6)cc45)nc(-c4cccc5oc6ccccc6c45)n3)ccc2c1 ; Cc1ccc2ccc3c(-c4nc(-c5ccc6ccccc6c5)nc(-c5cccc6c5oc5ccccc56)n4)cccc3c2c1 ; Cc1ccc2ccc3c(-c4nc(-c5ccc6ccccc6c5)nc(-c5cccc6oc7ccccc7c56)n4)cccc3c2c1]

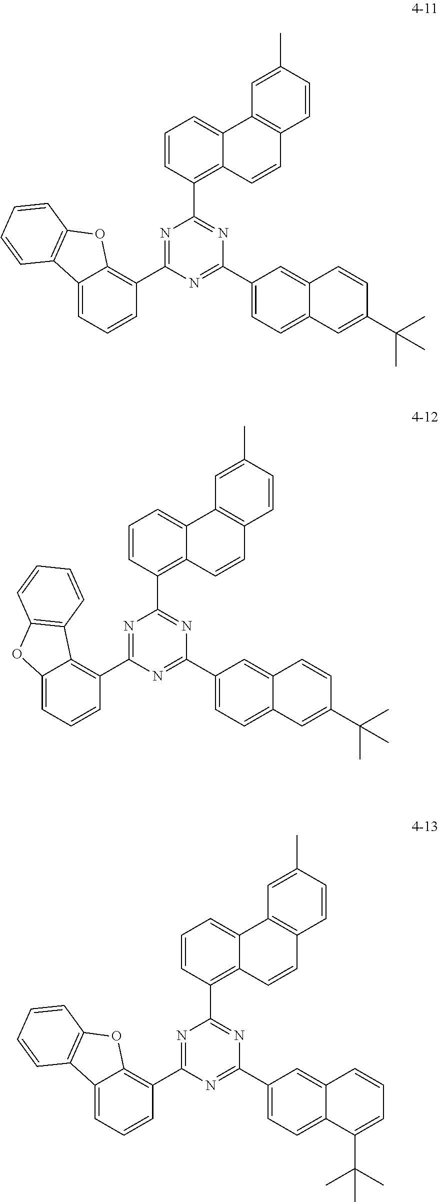 [SMILES: Cc1ccc2ccc3c(-c4nc(-c5ccc6cc(C(C)(C)C)ccc6c5)nc(-c5cccc6c5oc5ccccc56)n4)cccc3c2c1 ; Cc1ccc2ccc3c(-c4nc(-c5ccc6cc(C(C)(C)C)ccc6c5)nc(-c5cccc6oc7ccccc7c56)n4)cccc3c2c1 ; Cc1ccc2ccc3c(-c4nc(-c5ccc6c(C(C)(C)C)cccc6c5)nc(-c5cccc6c5oc5ccccc56)n4)cccc3c2c1]

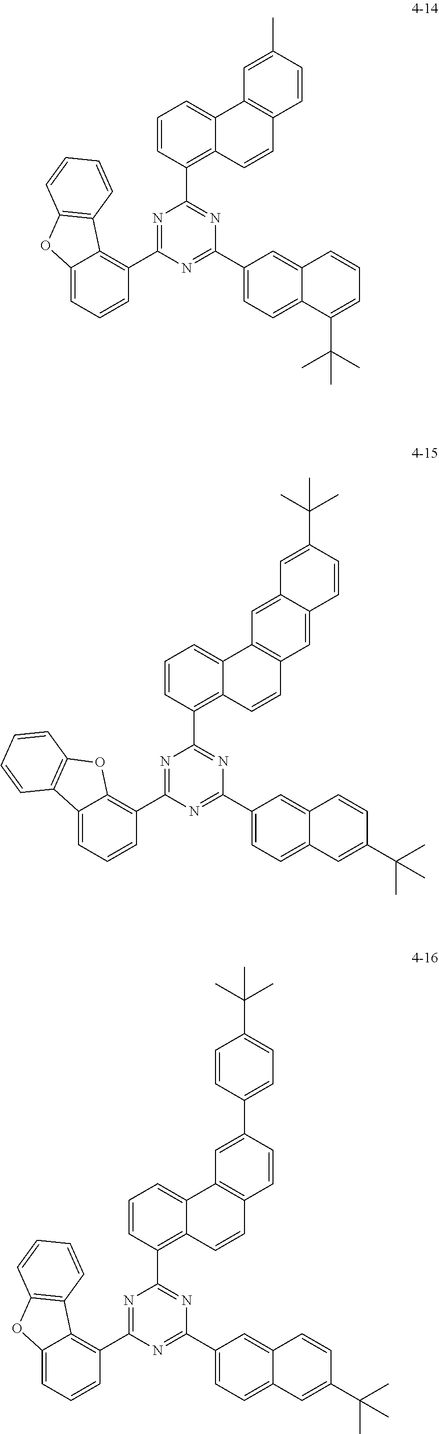 [SMILES: Cc1ccc2ccc3c(-c4nc(-c5ccc6c(C(C)(C)C)cccc6c5)nc(-c5cccc6oc7ccccc7c56)n4)cccc3c2c1 ; CC(C)(C)c1ccc2cc(-c3nc(-c4cccc5c4ccc4cc6ccc(C(C)(C)C)cc6cc45)nc(-c4cccc5c4oc4ccccc45)n3)ccc2c1 ; CC(C)(C)c1ccc(-c2ccc3ccc4c(-c5nc(-c6ccc7cc(C(C)(C)C)ccc7c6)nc(-c6cccc7oc8ccccc8c67)n5)cccc4c3c2)cc1]

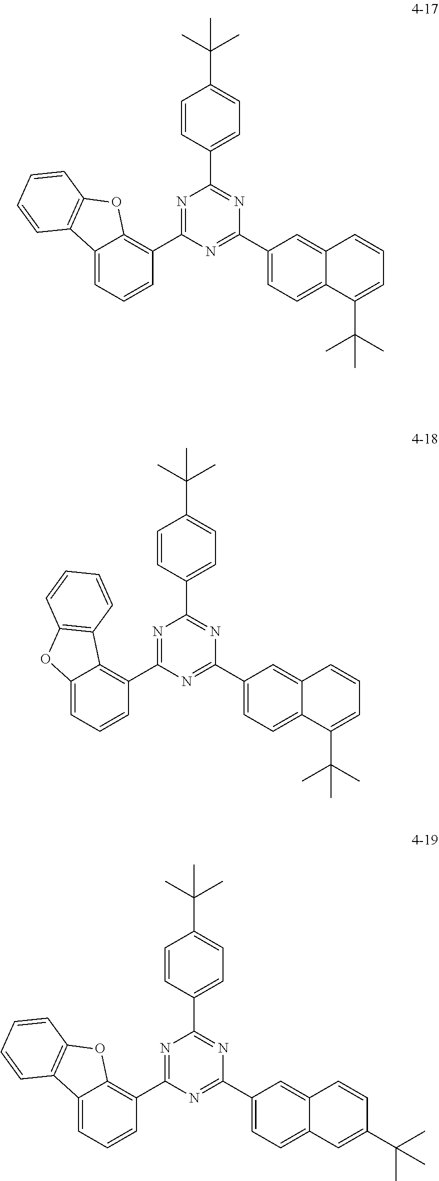 [SMILES: CC(C)(C)c1ccc(-c2nc(-c3ccc4c(C(C)(C)C)cccc4c3)nc(-c3cccc4c3oc3ccccc34)n2)cc1 ; CC(C)(C)c1ccc(-c2nc(-c3ccc4c(C(C)(C)C)cccc4c3)nc(-c3cccc4oc5ccccc5c34)n2)cc1 ; CC(C)(C)c1ccc(-c2nc(-c3ccc4cc(C(C)(C)C)ccc4c3)nc(-c3cccc4c3oc3ccccc34)n2)cc1]

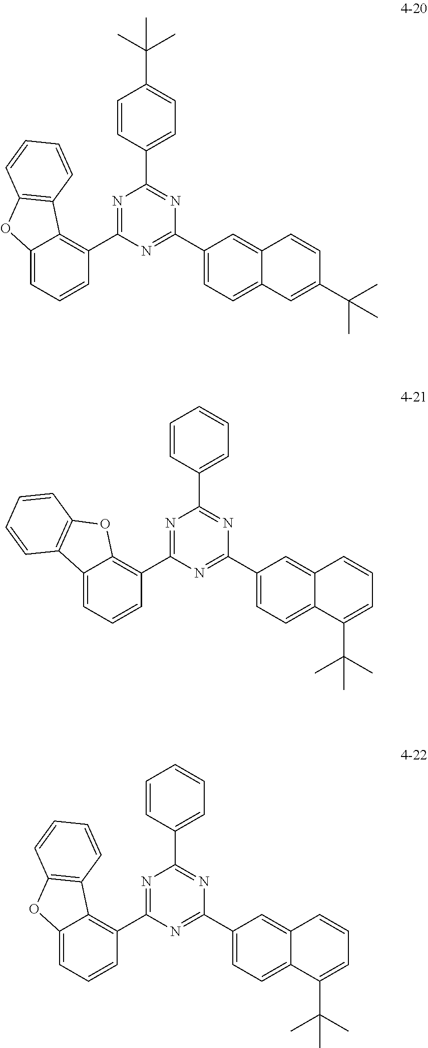 [SMILES: CC(C)(C)c1ccc(-c2nc(-c3ccc4cc(C(C)(C)C)ccc4c3)nc(-c3cccc4oc5ccccc5c34)n2)cc1 ; CC(C)(C)c1cccc2cc(-c3nc(-c4ccccc4)nc(-c4cccc5c4oc4ccccc45)n3)ccc12 ; CC(C)(C)c1cccc2cc(-c3nc(-c4ccccc4)nc(-c4cccc5oc6ccccc6c45)n3)ccc12]

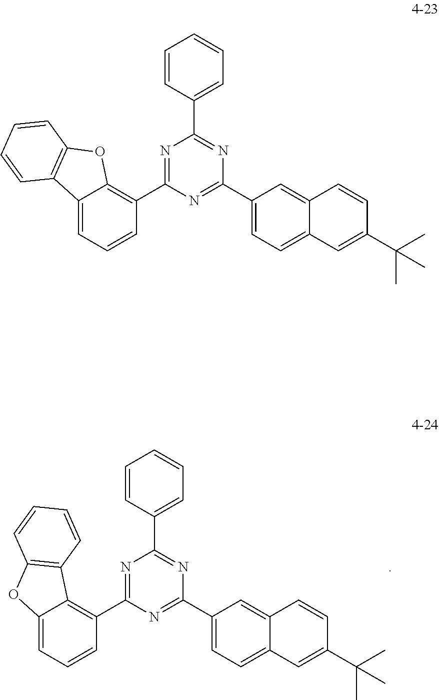 [SMILES: CC(C)(C)c1ccc2cc(-c3nc(-c4ccccc4)nc(-c4cccc5c4oc4ccccc45)n3)ccc2c1 ; CC(C)(C)c1ccc2cc(-c3nc(-c4ccccc4)nc(-c4cccc5oc6ccccc6c45)n3)ccc2c1]

The first compound 342 acting as final emitting material has low HOMO (highest occupied molecular orbital) energy level and low LUMO (lowest unoccupied molecular orbital) energy level. Compared to a LUMO energy level of the third compound 346 of the P-type host with relatively strong hole affinity, a LUMO energy level of the fourth compound 348 of the N-type host with relatively strong electron affinity is lower. Compared to an energy bandgap between the LUMO energy level of the third compound 346 and the LUMO energy level of the first compound 342, the energy bandgap between the LUMO energy level of the fourth compound 348 and the LUMO energy level of the first compound 342 is very narrow. The fourth compound 348 in the EML 340 enables electrons to be transported and injected to the first compound 342 from the fourth compound 348. In addition, as exciton recombination zone in the OLED D1 may be limited into the EML 340, it is possible to minimize amount of quenching excitons without emission. The quenching exciton without emission interacts with luminous materials and charge transporting materials, which results in the deteriorations of those materials, and thereby, reducing the luminous lifespan of those materials. On the contrary, minimizing the amount of the quenching excitons without emission may further improve the luminous lifespan of the OLED D1.

The contents of the host including the third compound 346 and the fourth compound 348 in the EML 340 may be about 50 wt % to about 99 wt %, for example, about 80 wt % to about 95 wt %, and the contents of the first compound 342 and the second compound 344 in the EML 340 may be about 1 wt % to about 50 wt %, for example, about 5 wt % to about 20 wt %, but is not limited thereto. The contents of the second compound 344 in the EML 340 may be larger than the contents of the first compound 342. In this case, the singlet exciton energy of the second compound 344 may be transferred efficiently to the first compound 342. For example, the contents of the second compound 344 in the EML 340 may be about 3 wt % to about 19.5 wt %, for example, about 5 wt % to about 19.5 wt %, and the contents of the first compound 342 in the EML 340 may be about 0.5 wt % to about 5 wt %, for example, about 0.5 wt % to about 1 wt %, but is not limited thereto.

When the EML 340 includes both the third compound 346 and the fourth compound 348, the third compound 346 and the fourth compound 348 may be admixed, but is not limited to, with a weight ratio of about 4:1 to about 1:4, for example about 3:1 to about 1:3. As an example, the EML 340 may have a thickness of, but is not limited to, about 100 Å to about 500 Å.

The ETL 360 and the EIL 370 may be laminated sequentially between the EML 340 and the second electrode 220. An electron transporting material included in the ETL 360 has high electron mobility so as to provide electrons stably to the EML 340 by fast electron transportation.

In one example embodiment, the ETL 360 may include at least one of an oxadiazole-based compound, a triazole-based compound, a phenanthroline-based compound, a benzoxazole-based compound, a benzothiazole-based compound, a benzimidazole-baed compound and a traizine-based compound.

In some embodiments, the ETL 360 may include, but is not limited to, tris-(8-hydroxyquinoline aluminum) (Alq₃), 2-biphenyl-4-yl-5-(4-t-butylphenyl)-1,3,4-oxadiazole (PBD), spiro-PBD, lithium quinolate (Liq), 1,3,5-Tris(N-phenylbenzimidazol-2-yl)benzene (TPBi), Bis(2-methyl-8-quinolinolato-N1,08)-(1,1′-biphenyl-4-olato)aluminum (BAlq), 4,7-diphenyl-1,10-phenanthroline (Bphen), 2,9-Bis(naphthalene-2-yl)4,7-diphenyl-1,10-phenanthroline (NBphen), 2,9-Dimethyl-4,7-diphenyl-1,10-phenathroline (BCP), 3-(4-Biphenyl)-4-phenyl-5-tert-butylphenyl-1,2,4-triazole (TAZ), 4-(Naphthalen-1-yl)-3,5-diphenyl-4H-1,2,4-triazole (NTAZ), 1,3,5-Tri(p-pyrid-3-yl-phenyl)benzene (TpPyPB), 2,4,6-Tris(3′-(pyridin-3-yl)biphenyl-3-yl)1,3,5-triazine (TmPPPyTz), Poly[9,9-bis(3′-((N,N-dimethyl)-N-ethylammonium)-propyl)-2,7-fluorene]-alt-2,7-(9,9-dioctylfluorene)] (PFNBr), tris(phenylquinoxaline (TPQ), TSPO1, 2-[4-(9,10-Di-2-naphthalen2-yl-2-anthracen-2-yl)phenyl]-1-phenyl-1H-benzimidazole (ZADN), and/or combinations thereof.

The EIL 370 is disposed between the second electrode 220 and the ETL 360, and may improve physical properties of the second electrode 220 and therefore, may enhance the lifespan of the OLED D1. In one example embodiment, the EIL 370 may include, but is not limited to, an alkali metal halide or an alkaline earth metal halide such as LiF, CsF, NaF, BaF₂ and the like, and/or an organometallic compound such as Liq, lithium benzoate, sodium stearate, and the like. Alternatively, the EIL 370 may be omitted.

When holes are transferred to the second electrode 220 via the EML 340 and/or electrons are transferred to the first electrode 210 via the EML 340, the OLED D1 may have short lifespan and reduced luminous efficiency. In order to prevent or reduce those phenomena, the OLED D1 in accordance with this aspect of the present disclosure may have at least one exciton blocking layer adjacent to the EML 340.

As an example, the OLED D1 may include the EBL 330 disposed between the HTL 320 and the EML 340 so as to control and prevent or reduce electron transfers. In one example embodiment, the EBL 330 may include, but is not limited to, TCTA, Tris[4-(diethylamino)phenyl]amine, N-(biphenyl-4-yl)-9,9-dimethyl-N-(4-(9-phenyl-9H-carbazol-3-yl)phenyl)-9H-fluorene-2-amine, TAPC, MTDATA, 1,3-Bis(carbazol-9-yl)benzene (mCP), 3,3′-Di(9H-carbazol-0-yl)biphenyl (mCBP), CuPc, DNTPD, TDAPB, DCDPA, 2,8-bis(9-phenyl-9H-carbazol-3-yl)dibenzo[b,d]thiophene and/or combinations thereof.

In addition, the OLED D1 may further include the HBL 350 as a second exciton blocking layer between the EML 340 and the ETL 360 so that holes may not be transferred from the EML 340 to the ETL 360. In one example embodiment, the HBL 350 may include, but is not limited to, at least one of an oxadiazole-based compound, a triazole-based compound, a phenanthroline-based compound, a benzoxazole-based compound, a benzothiazole-based compound, a benzimidazole-based compound, and a triazine-based compound.

For example, the HBL 350 may include material having a relatively low HOMO energy level compared to the luminescent materials in EML 340. The HBL 350 may include, but is not limited to, BCP, BAlq, Alq₃, PBD, spiro-PBD, Liq, Bis-4,5-(3,5-di-3-pyridylphenyl)-2-methylpyrimidine (B3PYMPM), DPEPO, 9-(6-(9H-carbazol-9-yl)pyridine-3-yl)-9H-3,9′-bicarbazole, TSPO1 and/or combinations thereof.

As described above, the EML 340 includes the first compound 342, the second compound 344, and optionally, the third compound 346 and/or the fourth compound 348. The first compound 342 may include the organic compound having the structure of Chemical Formulae 1, 2A, 2B and 3, the second compound 344 may include the organometallic compound having the structure of Chemical Formulae 4 to 5, the third compound 346 may include the organic compound having the structure of Chemical Formulae 6 and 8, and/or the fourth compound 348 may include the organic compound having the structure of Chemical Formula 9 to 11.

The first compound 342 having the structure of Chemical Formulae 1, 2A, 2B and 3 is fluorescent emitter with a wide plate-like structure. The singlet exciton energy of the second compound 344 may be transferred efficiently to the first compound 342 through FRET mechanism. Accordingly, the luminous efficiency and the luminous lifespan of the OLED D1 may be improved.

The organic light emitting device and the OLED D1 with a single emitting part are shown in FIGS. 2 and 3. In another example embodiment, an organic light emitting display device may implement full-color including white color.

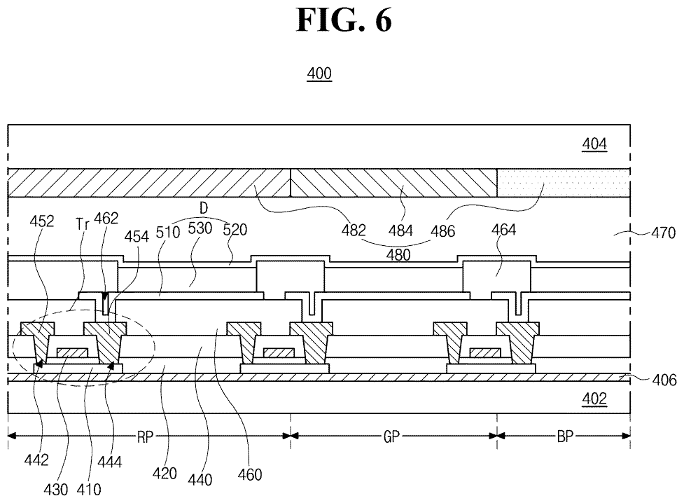

FIG. 6 illustrates a schematic cross-sectional view of an organic light emitting display device in accordance with another example embodiment of the present disclosure. As illustrated in FIG. 6, the organic light emitting display device 400 includes a first substrate 402 that defines each of a red pixel region RP, a green pixel region GP and a blue pixel region BP, a second substrate 404 facing the first substrate 402, a thin film transistor Tr on the first substrate 402, an OLED D disposed between the first and second substrates 402 and 404 and emitting white (W) light and a color filter layer 480 disposed between the OLED D and the second substrate 404.

Each of the first and second substrates 402 and 404 may include, but is not limited to, glass, flexible material and/or polymer plastics. For example, each of the first and second substrates 402 and 404 may be made of PI, PES, PEN, PET, PC and/or combinations thereof. The second substrate 404 may be omitted. The first substrate 402, on which a thin film transistor Tr and the OLED D are arranged, forms an array substrate.

A buffer layer 406 may be disposed on the first substrate 402. The thin film transistor Tr is disposed on the buffer layer 406 correspondingly to each of the red pixel region RP, the green pixel region GP and the blue pixel region BP. The buffer layer 406 may be omitted.

A semiconductor layer 410 is disposed on the buffer layer 406. The semiconductor layer 410 may be made of or include oxide semiconductor material or polycrystalline silicon.

A gate insulating layer 420 including an insulating material, for example, inorganic insulating material such as silicon oxide (SiOₓ, wherein 0<x≤2) or silicon nitride (SiNₓ, wherein 0<x≤2) is disposed on the semiconductor layer 410.

A gate electrode 430 made of a conductive material such as a metal is disposed over the gate insulating layer 420 so as to correspond to a center of the semiconductor layer 410. An interlayer insulating layer 440 including an insulating material, for example, inorganic insulating material such as SiOₓ or SiNₓ (wherein 0<x≤2), or an organic insulating material such as benzocyclobutene or photo-acryl, is disposed on the gate electrode 430.

The interlayer insulating layer 440 has first and second semiconductor layer contact holes 442 and 444 that expose or do not cover a portion of the surface nearer to the opposing ends than to a center of the semiconductor layer 410. The first and second semiconductor layer contact holes 442 and 444 are disposed on opposite sides of the gate electrode 430 with spacing apart from the gate electrode 430.

A source electrode 452 and a drain electrode 454, which are made of or include a conductive material such as a metal, are disposed on the interlayer insulating layer 440. The source electrode 452 and the drain electrode 454 are spaced apart from each other with respect to the gate electrode 430. The source electrode 452 and the drain electrode 454 contact both sides of the semiconductor layer 410 through the first and second semiconductor layer contact holes 442 and 444, respectively.

The semiconductor layer 410, the gate electrode 430, the source electrode 452 and the drain electrode 454 constitute the thin film transistor Tr, which acts as a driving element.

Although not shown in FIG. 6, the gate line GL and the data line DL, which cross each other to define the pixel region P, and a switching element Ts, which is connected to the gate line GL and the data line DL, may be further formed in the pixel region P. The switching element Ts is connected to the thin film transistor Tr, which is a driving element. In addition, the power line PL is spaced apart in parallel from the gate line GL or the data line DL, and the thin film transistor Tr may further include the storage capacitor Cst configured to constantly keep a voltage of the gate electrode 430 for one frame.

A passivation layer 460 is disposed on the source electrode 452 and the drain electrode 454 and covers the thin film transistor Tr over the whole first substrate 402. The passivation layer 460 has a drain contact hole 462 that exposes or does not cover the drain electrode 454 of the thin film transistor Tr.

The OLED D is located on the passivation layer 460. The OLED D includes a first electrode 510 that is connected to the drain electrode 454 of the thin film transistor Tr, a second electrode 520 facing the first electrode 510 and an emissive layer 530 disposed between the first and second electrodes 510 and 520.

The first electrode 510 formed for each pixel region RP, GP or BP may be an anode and may include a conductive material having relatively high work function value. For example, the first electrode 510 may include, but is not limited to, ITO, IZO, ITZO, SnO, ZnO, ICO, AZO, and/or combinations thereof. Alternatively, a reflective electrode or a reflective layer may be disposed under the first electrode 510. For example, the reflective electrode or the reflective layer may include, but is not limited to, Ag or APC alloy.

A bank layer 464 is disposed on the passivation layer 460 in order to cover edges of the first electrode 510. The bank layer 464 exposes or does not cover a center of the first electrode 510 corresponding to each of the red pixel RP, the green pixel GP and the blue pixel BP. The bank layer 464 may be omitted.

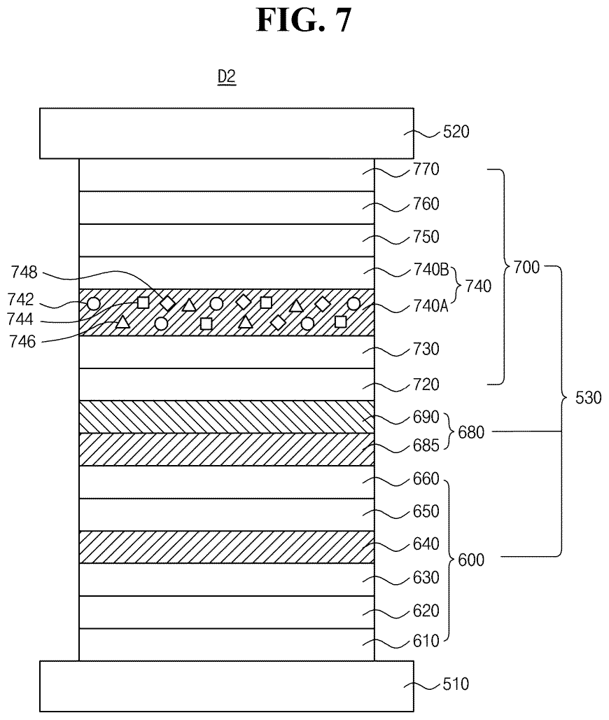

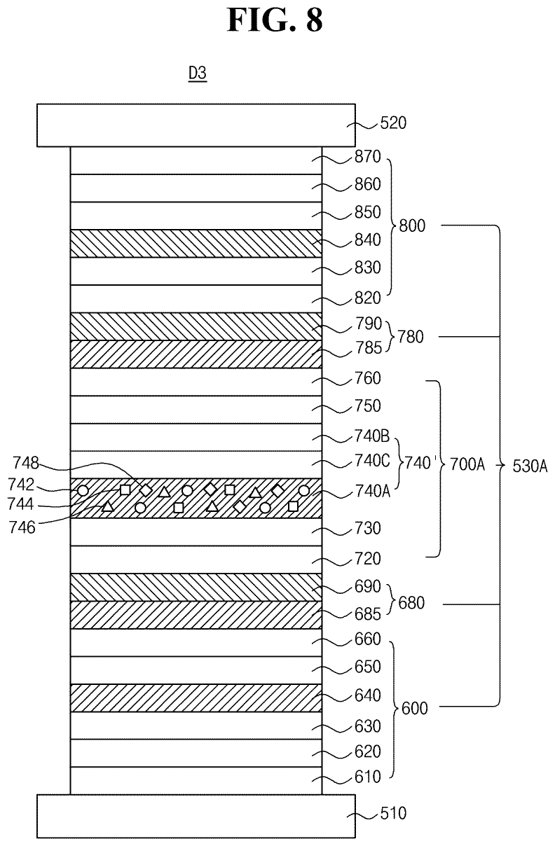

An emissive layer 530 that may include multiple emitting parts is disposed on the first electrode 510. As illustrated in FIGS. 7 and 8, the emissive layer 530 may include multiple emitting parts 600, 700, 700A, and 800 and at least one charge generation layer 680 and 780. Each of the emitting parts 600, 700, 700A and 800 includes at least one emitting material layer and may further include an HIL, an HTL, an EBL, an HBL, an ETL and/or an EIL.

The second electrode 520 may be disposed on the first substrate 402 above which the emissive layer 530 may be disposed. The second electrode 520 may be disposed over a whole display area, may include a conductive material with a relatively low work function value compared to the first electrode 510, and may be a cathode. For example, the second electrode 520 may include, but is not limited to, Al, Mg, Ca, Ag, alloy thereof, and/or combinations thereof such as Al—Mg.

Since the light emitted from the emissive layer 530 is incident to the color filter layer 480 through the second electrode 520 in the organic light emitting display device 400 in accordance with the second embodiment of the present disclosure, the second electrode 520 has a thin thickness so that the light may be transmitted.

The color filter layer 480 is disposed on the OLED D and includes a red color filter pattern 482, a green color filter pattern 484 and a blue color filter pattern 486 each of which is disposed correspondingly to the red pixel region RP, the green pixel region GP and the blue pixel region BP, respectively. Although not shown in FIG. 6, the color filter layer 480 may be attached to the OLED D through an adhesive layer. Alternatively, the color filter layer 480 may be disposed directly on the OLED D.

In addition, an encapsulation film 470 may be disposed on the second electrode 520 in order to prevent or reduce outer moisture from penetrating into the OLED D. The encapsulation film 470 may have, but is not limited to, a laminated structure including a first inorganic insulating film, an organic insulating film and a second inorganic insulating film (176 in FIG. 2). In addition, a polarizing plate may be attached onto the second substrate 404 to reduce reflection of external light. For example, the polarizing plate may be a circular polarizing plate.

In FIG. 6, the light emitted from the OLED D is transmitted through the second electrode 520 and the color filter layer 480 is disposed on the OLED D. In this case, the organic light emitting display device 400 may be a top-emission type. Alternatively, when the organic light emitting display device 400 is a bottom-emission type, the light emitted from the OLED D is transmitted through the first electrode 510 and the color filter layer 480 may be disposed between the OLED D and the first substrate 402.

In addition, a color conversion layer may be formed or disposed between the OLED D and the color filter layer 480. The color conversion layer may include a red color conversion layer, a green color conversion layer and a blue color conversion layer each of which is disposed correspondingly to each pixel (RP, GP and BP), respectively, so as to convert the white (W) color light to each of a red, green and blue color lights, respectively. Alternatively, the organic light emitting display device 400 may comprise the color conversion layer instead of the color filter layer 480.

As described above, the white (W) color light emitted from the OLED D is transmitted through the red color filter pattern 482, the green color filter pattern 484 and the blue color filter pattern 486 each of which is disposed correspondingly to the red pixel region RP, the green pixel region GP and the blue pixel region BP, respectively, so that red, green and blue color lights are displayed in the red pixel region RP, the green pixel region GP and the blue pixel region BP.

An OLED that may be applied into the organic light emitting display device will be described in more detail. FIG. 7 illustrates a schematic cross-sectional view of an organic light emitting diode having a tandem structure of two emitting parts.

As illustrated in FIG. 7, the OLED D2 in accordance with the example embodiment of the present disclosure includes first and second electrodes 510 and 520 facing each other and an emissive layer 530 disposed between the first and second electrodes 510 and 520. The emissive layer 530 includes a first emitting part 600 disposed between the first and second electrodes 510 and 520, a second emitting part 700 disposed between the first emitting part 600 and the second electrode 520 and a charge generation layer (CGL) 680 disposed between the first and second emitting parts 600 and 700.

The first electrode 510 may be an anode and may include a conductive material having relatively high work function value such as TCO. For example, the first electrode 510 may include, but is not limited to, ITO, IZO, ITZO, SnO, ZnO, ICO, AZO, and/or combinations thereof. The second electrode 520 may be a cathode and may include a conductive material with a relatively low work function value. For example, the second electrode 520 may include, but is not limited to, highly reflective material such as Al, Mg, Ca, Ag, alloy thereof and/or combinations thereof such as Al—Mg.

The first emitting part 600 includes a first EML (EML1) 640. The first emitting part 600 may further include at least one of an HIL 610 disposed between the first electrode 510 and the EML1 640, a first HTL (HTL1) 620 disposed between the HIL 610 and the EML1 640, and a first ETL (ETL1) 660 disposed between the EML1 640 and the CGL 680. Alternatively, the first emitting part 600 may further include a first EBL (EBL1) 630 disposed between the HTL1 620 and the EML1 640 and/or a first HBL (HBL1) 650 disposed between the EML1 640 and the ETL1 660.

The second emitting part 700 includes a second EML (EML2) 740. The second emitting part 700 may further include at least one of a second HTL (HTL2) 720 disposed between the CGL 680 and the EML2 740, a second ETL (ETL2) 760 disposed between the second electrode 520 and the EML2 740 and an EIL 770 disposed between the second electrode 520 and the ETL2 760. Alternatively, the second emitting part 700 may further include a second EBL (EBL2) 730 disposed between the HTL2 720 and the EML2 740 and/or a second HBL (HBL2) 750 disposed between the EML2 740 and the ETL2 760.

One of the EML1 640 and the EML2 740 may include a first compound having the structure of Chemical Formulae 1, 2A, 2B and 3 so that it may emit red to green color light, and the other of the EML1 640 and the EML2 740 may emit blue color light, so that the OLED D2 may realize white (W) emission. Hereinafter, the OLED D2 where the EML2 740 includes the first compound having the structure of Chemical Formulae 1, 2A, 2B and 3 to emit red to green color light will be described in detail.

The HIL 610 is disposed between the first electrode 510 and the HTL1 620 and improves an interface property between the inorganic first electrode 510 and the organic HTL1 620. In one embodiment, the HIL 610 may include, but is not limited to, MTDATA, NATA, 1T-NATA, 2T-NATA, CuPc, TCTA, NPB (NPD), DNTPD, HAT-CN, F4-TCNQ, F6-TCNNQ, TDAPB, PEDOT/PSS, N-(biphenyl-4-yl)-9,9-dimethyl-N-(4-(9-phenyl-9H-carbazol-3-yl)phenyl)-9H-fluoren-2-amine, NPNPB and/or combinations thereof. Alternatively, the HIL 610 may include hole transporting material doped with hole injecting material. The HIL 610 may be omitted in compliance of the OLED D2 property.

In one example embodiment, each of the HTL1 620 and the HTL2 720 may independently include, but is not limited to, TPD, NPB (NPD), DNTPD, CBP, poly-TPD, TFB, TAPC, DCDPA, N-(biphenyl-4-yl)-9,9-dimethyl-N-(4-(9-phenyl-9H-carbazol-3-yl)phenyl)-9H-fluoren-2-amine, N-(biphenyl-4-yl)-N-(4-(9-phenyl-9H-carbazol-3-yl)phenyl)biphenyl-4-amine, N-([1,1′-Biphenyl]-4-yl)-9,9-dimethyl-N-(4-(9-phenl-9H-carbazol-3-yl)phenyl)-9H-fluoren-2-amine and/or combinations thereof.

Each of the ETL1 660 and the ETL2 760 facilitates electron transportation in each of the first emitting part 600 and the second emitting part 700, respectively. As an example, each of the ETL1 660 and the ETL2 760 may include at least one of an oxadiazole-based compound, a triazole-based compound, a phenanthroline-based compound, a benzoxazole-based compound, a benzothiazole-based compound, a benzimidazole-based compound and a triazine-based compound. For example, each of the ETL1 660 and the ETL2 760 may include, but is not limited to, Alq₃, PBD, spiro-PBD, Liq, TPBi, BAlq, Bphen, NBphen, BCP, TAZ, NTAZ, TpPyPB, TmPPPyTz, PFNBr, TPQ, TSPO1, ZADN and/or combinations thereof.

The EIL 770 is disposed between the second electrode 520 and the ETL2 760, and may improve physical properties of the second electrode 520 and therefore, may enhance the lifespan of the OLED D2. In one example embodiment, the EIL 770 may include, but is not limited to, an alkali metal halide or an alkaline earth metal halide such as LiF, CsF, NaF, BaF₂ and the like, and/or an organometallic compound such as Liq, lithium benzoate, sodium stearate, and the like.

Each of the EBL1 630 and the EBL2 730 may independently include, but is not limited to, TCTA, Tris[4-(diethylamino)phenyl]amine, N-(biphenyl-4-yl)-9,9-dimethyl-N-(4-(9-phenyl-9H-carbazol-3-yl)phenyl)-9H-fluorene-2-amine, TAPC, MTDATA, mCP, mCBP, CuPc, DNTPD, TDAPB, DCDPA, 2,8-bis(9-phenyl-9H-carbazol-3-yl)dibenzo[b,d]thiophene and/or combinations thereof, respectively.

Each of the HBL1 650 and the HBL2 750 may include, but is not limited to, at least one of an oxadiazole-based compound, a triazole-based compound, a phenanthroline-based compound, a benzoxazole-based compound, a benzothiazole-based compound, a benzimidazole-based compound, and a triazine-based compound. For example, each of the HBL1 650 and the HBL2 750 may independently include, but is not limited to, BCP, BAlq, Alq₃, PBD, spiro-PBD, Liq, B3PYMPM, DPEPO, 9-(6-(9H-carbazol-9-yl)pyridine-3-yl)-9H-3,9′-bicarbazole, TSPO1 and/or combinations thereof, respectively.

The CGL 680 is disposed between the first emitting part 600 and the second emitting part 700. The CGL 680 includes an N-type CGL (N-CGL) 685 disposed adjacent to the first emitting part 600 and a P-type CGL (P-CGL) 690 disposed adjacent to the second emitting part 700. The N-CGL 685 injects electrons to the EML1 640 of the first emitting part 600 and the P-CGL 690 injects holes to the EML2 740 of the second emitting part 700.

The N-CGL 685 may be an organic layer including electron transporting material doped with an alkali metal such as Li, Na, K and Cs and/or an alkaline earth metal such as Mg, Sr, Ba and Ra. For example, the contents of the alkali metal or the alkaline earth metal in the N-CGL 685 may be, but is not limited to, between about 0.01 wt % and about 30 wt %.

The P-CGL 690 may include, but is not limited to, inorganic material selected from the group consisting of tungsten oxide (WOₓ), molybdenum oxide (MoOₓ), beryllium oxide (Be₂O₃), vanadium oxide (V₂O₅) and/or combinations thereof. In another example embodiment, the P-CGL 690 may include hole transporting material doped with hole injecting material (e.g., HAT-CN, F4-TCNQ and/or F6-TCNNQ). The contents of the hole injecting material in the P-CGL 690 may be, but is not limited to, between about 2 wt % and about 15 wt %.

The EML1 640 may be a blue EML. In this case, the EML1 640 may be a blue EML, a sky-blue EML or a deep-blue EML. The EML1 640 may include a blue host and a blue dopant. The EML1 640 may include a blue host and blue emitter (dopant).

The blue host may include at least one of a P-type blue host and an N-type blue host. For example, the blue host may include, but is not limited to, mCP, 9-(3-(9H-carbazol-9-yl)phenyl)-9H-carbazole-3-carbonitrile (mCP-CN), mCBP, CBP-CN, 9-(3-(9H-carbazol-9-yl)phenyl)-3-(diphenylphosphoryl)-9H-carbazole (mCPPO1) 3,5-Di(9H-carbazol-9-yl)biphenyl (Ph-mCP), TSPO1, 9-(3′-(9H-carbazol-9-yl)-[1,1′-biphenyl]-3-yl)-9H-pyrido[2,3-b]indole (CzBPCb), Bis(2-methylphenyl)diphenylsilane (UGH-1), 1,4-Bis(triphenylsilyl)benzene (UGH-2), 1,3-Bis(triphenylsilyl)benzene (UGH-3), 9,9-Spirobifluoren-2-yl-diphenyl-phosphine oxide (SPPO1), 9,9′-(5-(Triphenylsilyl)-1,3-phenylene)bis(9H-carbazole) (SimCP) and/or combinations thereof.

The blue emitter may include at least one of blue phosphorescent material, blue fluorescent material and blue delayed fluorescent material. As an example, the blue emitter may include, but is not limited to, perylene, 4,4′-Bis[4-(di-p-tolylamino)styryl]biphenyl (DPAVBi), 4-(Di-p-tolylamino)-4-4′-[(di-p-tolylamino)styryl]stilbene (DPAVB), 4,4′-Bis[4-(diphenylamino)styryl]biphenyl (BDAVBi), 2,7-Bis(4-diphenylamino)styryl)-9,9-spirofluorene (spiro-DPVBi), [1,4-bis[2-[4-[N,N-di(p-tolyl)amino]phenyl]vinyl]benzene (DSB), 1-4-di-[4-(N,N-diphenyl)amino]styryl-benzene (DSA), 2,5,8,11-Tetra-tert-butylperylene (TBPe), Bis(2-hydroxylphenyl)-pyridine)beryllium (Bepp₂), 9-(9-Phenylcarbazole-3-yl)-10-(naphthalene-1-yl)anthracene (PCAN), mer-Tris(1-phenyl-3-methylimidazolin-2-ylidene-C,C(2)′iridium(III) (mer-Ir(pmi)₃), fac-Tris(1,3-diphenyl-benzimidazolin-2-ylidene-C,C(2)′iridium(III) (fac-Ir(dpbic)₃), Bis(3,4,5-trifluoro-2-(2-pyridyl)phenyl-(2-carboxypyridyl)iridium(III) (Ir(tfpd)₂pic), tris(2-(4,6-difluorophenyl)pyridine))iridium(III) (Ir(Fppy)₃), Bis[2-(4,6-difluorophenyl)pyridinato-C²,N](picolinato)iridium(III) (FIrpic) and/or combinations thereof.

The contents of the blue host in the EML1 640 may be about 50 wt % to about 99 wt %, for example, about 80 wt % to about 95 wt %, and the contents of the blue emitter in the EML1 640 may be about 1 wt % to about 50 wt %, for example, about 5 wt % to about 20 wt %, but is not limited thereto. When the EML1 640 includes both the P-type blue host and the N-type blue host, the P-type blue host and the N-type blue host may be admixed, but is not limited to, with a weight ratio of about 4:1 to about 1:4, for example about 3:1 to about 1:3.

The EML2 740 may include a first layer (lower EML) 740A disposed between the EBL2 730 and the HBL2 750 and a second layer (upper EML) 740B disposed between the first layer 740A and the HBL2 750. One of the first layer 740A and the second layer 740B may emit red to yellow color light and the other of the first layer 740A and the second layer 740B may emit green color light. Hereinafter, the EML2 740 where the first layer 740A emits a red to yellow color light and the second layer 740B emits a green color light will be described in detail.

The first layer 740A includes a first compound 742, a second compound 744, and optionally, a third compound 746 and/or a fourth compound 748. The first compound 742 is fluorescent emitter (fluorescent dopant) having the structure of Chemical Formulae 1, 2A, 2B and 3, and may emit red to yellow color light.

The second compound 744 may be phosphorescent material (assistant emitter) substituted with at least one electron-withdrawing group, and may include the organometallic compound having the structure of Chemical Formulae 4 to 5. The third compound 746 may be a P-type host of a carbazole-based organic compound. The third compound 746 may include the organic compound having the structure of Chemical Formulae 6 and 8. The fourth compound 748 may be an N-type host of an azine-based organic compound. The fourth compound 748 may include the organic compound having the structure of Chemical Formulae 9 to 11. The contents of the first compound 742, the second compound 744, the third compound 746 and the fourth compound 748 may be identical as the corresponding materials described in an example embodiment illustrated in connection with FIG. 3.

The second layer 740B may include a green host and a green emitter (green dopant). The green host may include at least one of a P-type green host and an N-type green host. In one example embodiment, the green host may be identical to the third compound 746 and/or the fourth compound 748. In another example embodiment, the green host may include, but is not limited to, mCP-CN, CBP, mCBP, mCP, DPEPO, PPT, TmPyPB, PYD-2Cz, DCzDBT, DCzTPA, pCzB-2CN, mCzB-2CN, TSPO1, CCP, 4-(3-(triphenylen-2-yl)phenyl)dibenzo[b,d]thiophene, 9-(4-(9H-carbazol-9-yl)phenyl)-9H-3,9′-bicarbazole, 9-(3-(9H-carbazol-9-yl)phenyl)-9H-3,9′-bicarbazole, 9-(6-(9H-carbazol-9-yl)pyridin-3-yl)-9H-3,9′-bicarbazole, BCzPh, BCZ, TCP, TCTA, CDBP, DMFL-CBP, Spiro-CBP, TCzl and/or combinations thereof.

The green emitter may include at least one of green phosphorescnet material, green fluorescent material and green delayed fluorescent material. As an example, the green emitter may include, but is not limited to, [Bis(2-phenylpyridine)](pyridyl-2-benzofuro[2,3-b]pyridine)iridium, Tris[2-phenylpyridine]iridiun(III) (Ir(ppy)₃), fac-Tris(2-phenylpyridine)iridium(III) (fac-Ir(ppy)₃), Bis(2-phenylpyridine)(acetylacetonate)iridium(III) (Ir(ppy)₂(acac)), Tris[2-(p-tolyl)pyridine]iridium(III) (Ir(mppy)₃), Bis(2-(naphthalen-2-yl)pyridine)(acetylacetonate)iridium(III) (Ir(npy)₂acac), Tris(2-phenyl-3-methyl-pyridine)iridium (Ir(3mppy)₃), fac-Tris(2-(3-p-xylyl)phenyl)pyridine iridium(III) (TEG) and/or combinations thereof.

The contents of the green host in the second layer 740B may be about 50 wt % to about 99 wt %, for example, about 80 wt % to about 95 wt %, and the contents of the green emitter in the second layer 740B may be about 1 wt % to about 50 wt %, for example, about 5 wt % to about 20 wt %, but is not limited thereto. When the second layer 740B includes both the P-type green host and the N-type green host, the P-type green host and the N-type green host may be admixed, but is not limited to, with a weight ratio of about 4:1 to about 1:4, for example about 3:1 to about 1:3.

Alternatively, the EML2 740 may further include a third layer (740C in FIG. 8) that may emit yellow-green color light and may be disposed between the first layer 740A of the red EML and the second layer 740B of the green EML.

The OLED D2 with a tandem structure in accordance with this embodiment includes the first compound 742 of the organic compound having the structure of Chemical Formulae 1, 2A, 2B and 3, the second compound 744 of the organometallic compound having the structure of Chemical Formulae 4 to 5, and optionally, the third compound 746 of the organic compound having the structure of Chemical Formulae 6 and 8 and/or the fourth compound 748 of the organic compound having the structure of Chemical Formulae 9 to 11. The first compound 742 having the structure of Chemical Formulae 1, 2A, 2B and 3 has a wide plate-like structure and may receive singlet exciton energy from the second compound 744, the third compound 746 and/or the fourth compound 748. The luminous efficiency and the luminous lifespan of the OLED D2 may be improved.

An OLED may have three or more emitting parts to form a tandem structure. FIG. 8 is a schematic cross-sectional view illustrating an organic light emitting diode in accordance with yet another example embodiment of the present disclosure.

As illustrated in FIG. 8, the OLED D3 includes first and second electrodes 510 and 520 facing each other and an emissive layer 530A disposed between the first and second electrodes 510 and 520. The emissive layer 530A includes a first emitting part 600 disposed between the first and second electrodes 510 and 520, a second emitting part 700A disposed between the first emitting part 600 and the second electrode 520, a third emitting part 800 disposed between the second emitting part 700A and the second electrode 520, a first charge generation layer (CGL1) 680 disposed between the first and second emitting parts 600 and 700A, and a second charge generation layer (CGL2) 780 disposed between the second and third emitting parts 700A and 800.

The first emitting part 600 includes a first EML (EML1) 640. The first emitting part 600 may further include at least one of an HIL 610 disposed between the first electrode 510 and the EML1 640, a first HTL (HTL1) 620 disposed between the HIL 610 and the EML1 640, a first ETL (ETL1) 660 disposed between the EML1 640 and the CGL1 680. Alternatively, the first emitting part 600 may further comprise a first EBL (EBL1) 630 disposed between the HTL1 620 and the EML1 640 and/or a first HBL (HBL1) 650 disposed between the EML1 640 and the ETL1 660.

The second emitting part 700A includes a second EML (EML2) 740′. The second emitting part 700A may further include at least one of a second HTL (HTL2) 720 disposed between the CGL1 680 and the EML2 740′ and a second ETL (ETL2) 760 disposed between the EML2 740′ and the CGL2 780. Alternatively, the second emitting part 700A may further include a second EBL (EBL2) 730 disposed between the HTL2 720 and the EML2 740′ and/or a second HBL (HBL2) 750 disposed between the EML2 740′ and the ETL2 760.

The third emitting part 800 includes a third EML (EML3) 840. The third emitting part 800 may further include at least one of a third HTL (HTL3) 820 disposed between the CGL2 780 and the EML3 840, a third ETL (ETL3) 860 disposed between the second electrode 520 and the EML3 840 and an EIL 870 disposed between the second electrode 520 and the ETL3 860. Alternatively, the third emitting part 800 may further comprise a third EBL (EBL3) 830 disposed between the HTL3 820 and the EML3 840 and/or a third HBL (HBL3) 850 disposed between the EML3 840 and the ETL3 860.

The CGL1 680 is disposed between the first emitting part 600 and the second emitting part 700A and the CGL2 780 is disposed between the second emitting part 700A and the third emitting part 800. The CGL1 680 includes a first N-type CGL (N-CGL1) 685 disposed adjacent to the first emitting part 600 and a first P-type CGL (P-CGL1) 690 disposed adjacent to the second emitting part 700A. The CGL2 780 includes a second N-type CGL (N-CGL2) 785 disposed adjacent to the second emitting part 700A and a second P-type CGL (P-CGL2) 790 disposed adjacent to the third emitting part 800. Each of the N-CGL1 685 and the N-CGL2 785 injects electrons to the EML1 640 of the first emitting part 600 and the EML2 740′ of the second emitting part 700A, respectively, and each of the P-CGL1 690 and the P-CGL2 790 injects holes to the EML2 740′ of the second emitting part 700A and the EML3 840 of the third emitting part 800, respectively.

The materials included in the HIL 610, the HTL1 to the HTL3 620, 720 and 820, the EBL1 to the EBL3 630, 730 and 830, the HBL1 to the HBL3 650, 750 and 850, the ETL1 to the ETL3 660, 760 and 860, the EIL 870, the CGL1 680, and the CGL2 780 may be identical to the materials disclosed in an example embodiment described in connection with to FIGS. 3 and 7.

At least one of the EML1 640, the EML2 740′ and the EML3 840 may include a first compound having the structure of Chemical Formulae 1, 2A, 2B and 3. For example, one of the EML1 640, the EML2 740′ and the EML3 840 may emit red to green color light, and the other of the EML1 640, the EML2 740′ and the EML3 840 may emit blue color light so that the OLED D3 may realize white (W) emission. Hereinafter, the OLED where the EML2 740′ includes the first compound having the structure of Chemical Formulae 1, 2A, 2B and 3 and emits red to green color light, and each of the EML1 640 and the EML3 840 emits blue color light will be described in detail.

Each of the EML1 640 and the EML3 840 may be independently a blue EML. In this case, each of the EML1 640 and the EML3 840 may be independently a blue EML, a sky-blue EML or a deep-blue EML. Each of the EML1 640 and the EML3 840 may independently include a blue host and a blue emitter (dopant). Each of the blue host and the blue emitter may be identical to corresponding materials disclosed in an example embodiment described in connection with FIG. 7. For example, the blue emitter may include at least one of blue phosphorescent material, blue fluorescent material and blue delayed fluorescent material. Alternatively, the blue emitter in the EML1 640 may be identical to or different from the blue emitter in the EML3 840 in terms of color and/or luminous efficiency.

The EML2 740′ may include a first layer (lower EML) 740A disposed between the EBL2 730 and the HBL2 750, a second layer (upper EML) 740B disposed between the first layer 740A and the HBL2 750, and a third layer (middle EML) 740C disposed between the first layer 740A and the second layer 740B. One of the first layer 740A and the second layer 740B may emit red to yellow color light and the other of the first layer 740A and the second layer 740B may emit green color light. Hereinafter, the EML2 740′ where the first layer 740A emits a red to yellow color light and the second layer 740B emits a green color light will be described in detail.

The first layer 740A may include a first compound 742, a second compound 744, and optionally, a third compound 746 and/or a fourth compound 748. The first compound 742 may include the organic compound having the structure of Chemical Formulae 1, 2A, 2B and 3 and may be fluorescent emitter (fluorescent dopant). The second compound 744 may include the organometallic compound having the structure of Chemical Formulae 4 to 5 and may be phosphorescent material (assistant emitter). The third compound 746 may be the carbazole-based organic compound having the structure of Chemical Formulae 6 and 8 and may be the P-type host. The fourth compound 748 may be the azine-based organic compound having the structure of Chemical Formulae 9 to 11 and may be the N-type host. The contents of the first compound 742, the second compound 744, the third compound 746 and the fourth compound 748 may be identical as the corresponding materials described in an example embodiment described in connection with FIG. 3.

The second layer 740B may include a green host and green emitter (green dopant). The kinds and the contents of the green host and the green emitter may be identical as the corresponding materials described in an example embodiment described in connection with FIG. 7. For example, the green emitter may include at least one of green phosphorescent material, green fluorescent material and green delayed fluorescent material.

The third layer 740C may be a yellow-green emitting material layer. The third layer 740C may include a yellow-green host and a yellow-green emitter (dopant). The yellow-green host may include at least one of a P-type yellow-green host and an N-type yellow-green host. As an example, the yellow-green host may be identical to the third compound 746, the fourth compound 748 and/or the green host.

The yellow-green emitter may include at least one of yellow-green fluorescent material, yellow-green phosphorescent material and yellow-green delayed fluorescent material. For example, the yellow-green emitter may include, but is not limited to, 5,6,11,12-Tetraphenylnaphthalene (Rubrene), 2,8-Di-tert-butyl-5,11-bis(4-tert-butylphenyl)-6,12-diphenyltetracene (TBRb), Bis(2-phenylbenzothiazolato)(acetylacetonate)iridium(III) (Ir(BT)₂(acac)), Bis(2-(9,9-diethytl-fluoren-2-yl)-1-phenyl-1H-benzo[d]imdiazolato)(acetylacetonate)iridium(III) (Ir(fbi)₂(acac)), Bis(2-phenylpyridine)(3-(pyridine-2-yl)-2H-chromen-2-onate)iridium(III) (fac-Ir(ppy)₂Pc), Bis(2-(2,4-difluorophenyl)quinoline)(picolinate)iridium(III) (FPQIrpic), Bis(4-phenylthieno[3,2-c]pyridinato-N,C2′) (acetylacetonate) iridium(III) (PO-01) and/or combinations thereof.

The contents of the yellow-green host in the third layer 740C may be about 50 wt % to about 99 wt %, for example, about 80 wt % to about 95 wt %, and the contents of the yellow-green emitter in the third layer 740C may be about 1 wt % to about 50 wt %, for example, about 5 wt % to about 20 wt %, but is not limited thereto. When the third layer 740C includes both the P-type yellow-green host and the N-type yellow-green host, the P-type yellow-green host and the N-type yellow-green host may be admixed, but is not limited to, with a weight ratio of about 4:1 to about 1:4, for example about 3:1 to about 1:3.

The OLED D3 with a tandem structure in accordance with this embodiment includes the first compound 742 of the organic compound having the structure of Chemical Formulae 1, 2A, 2B and 3 in the at least one emitting material layer. Since the first compound 742 has a wide plate-like structure, the first compound may receive efficiently singlet exciton energy from the second compound 744, the third compound 746 and/or the fourth compound 748. OLED D3 with three emitting parts including the first compound 742 and the second compound 744 may implement white emission with improved luminous efficiency and the luminous lifespan. In addition, the organic light emitting diode may include four or more emitting parts.

### Synthesis Example 1: Synthesis of Compound 1-1

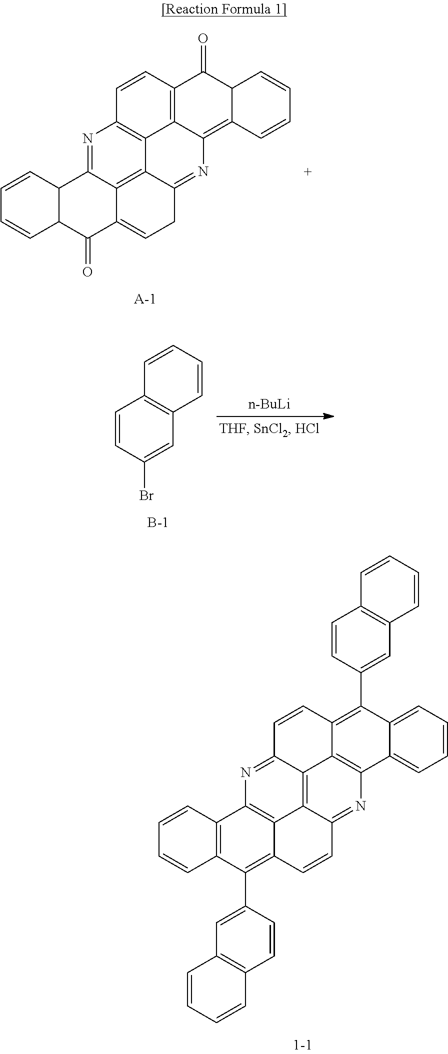

Compound A-1 (3.0 g, 7.3 mmol) and compound B-1 (4.55 g, 22.1 mmol) dissolved in anhydrous tetrahydrofuran (THF, 50 ml) were added into a 100 ml round bottom flask under nitrogen atmosphere, and then the solution was stirred at −78° C. n-BuLi (8.8 ml, 2.5 M) was added dropwise into the round bottom flask and then the solution was stirred again for 3 hours. After the reaction was complete, the temperature was raised to room temperature, and then the mixture was stirred for 12 hours. 3M HCl solution (50 ml) and SnCl₂ (2.08 g, 11 mmol) were added into the round bottom flask under nitrogen atmosphere, and the solution was stirred for 3 hours. Triethylamine was added into the solution to adjust pH of the solution to be neutral, the solution was stirred for 3 hours. Organic phase was extracted with water and dichloromethane and treated with anhydrous MgSO₄. The organic phase was filtered and subjected to reduced pressure to obtain a crude product. The crude product was purified with column chromatography (eluent: dichloromethane) and recrystallized to give a solid Compound 1-1 (0.55 g, 12%).

### Synthesis Example 2: Synthesis of Compound 1-2

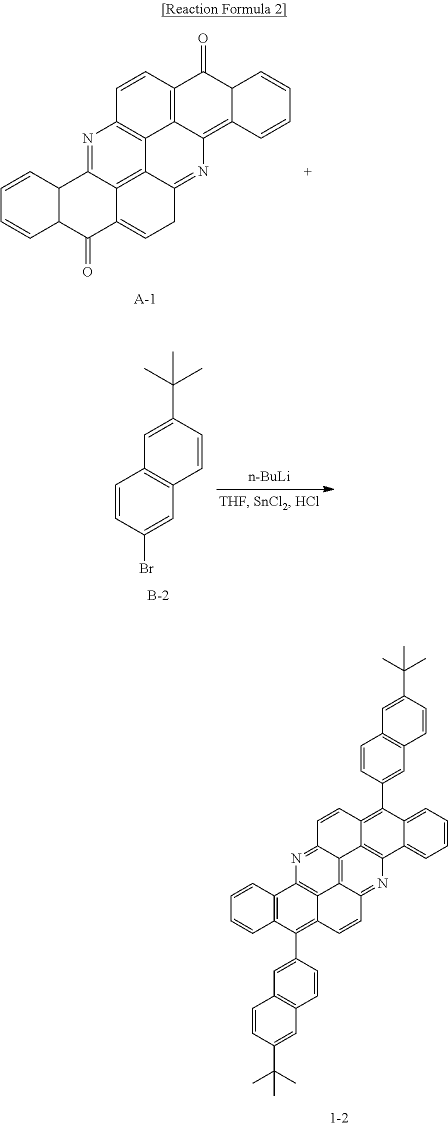

Compound A-1 (3.0 g, 7.3 mmol) and compound B-2 (5.79 g, 22.1 mmol) dissolved in anhydrous tetrahydrofuran (THF, 50 ml) were added into a 100 ml round bottom flask under nitrogen atmosphere, and then the solution was stirred at −78° C. n-BuLi (8.8 ml, 2.5 M) was added dropwise into the round bottom flask and then the solution was stirred again for 3 hours. After the reaction was complete, the temperature was raised to room temperature, and then the mixture was stirred for 12 hours. 3M HCl solution (50 ml) and SnCl₂ (2.08 g, 11 mmol) were added into the round bottom flask under nitrogen atmosphere, and the solution was stirred for 3 hours. Triethylamine was added into the solution to adjust pH of the solution to be neutral, the solution was stirred for 3 hours. Organic phase was extracted with water and dichloromethane and treated with anhydrous MgSO₄. The organic phase was filtered and subjected to reduced pressure to obtain a crude product. The crude product was purified with column chromatography (eluent: dichloromethane) and recrystallized to give a solid Compound 1-2 (0.71 g, 13%).

### Synthesis Example 3: Synthesis of Compound 1-3

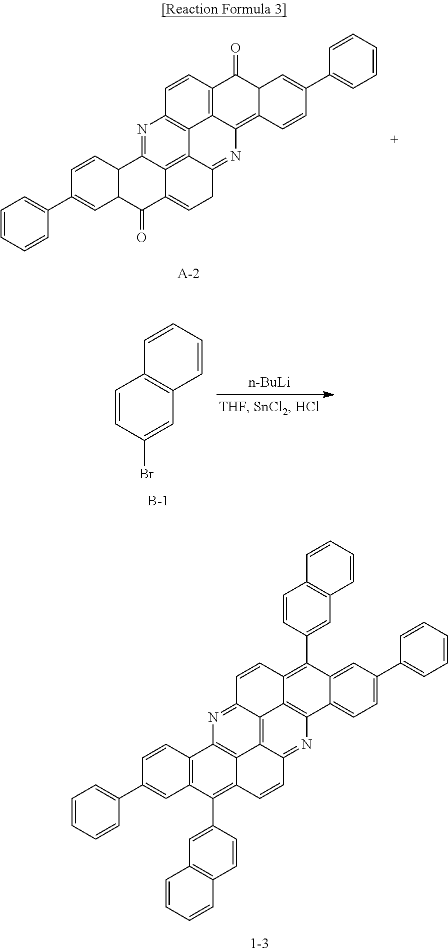

Compound A-2 (4.1 g, 7.3 mmol) and compound B-1 (4.55 g, 22.1 mmol) dissolved in anhydrous tetrahydrofuran (THF, 50 ml) were added into a 100 ml round bottom flask under nitrogen atmosphere, and then the solution was stirred at −78° C. n-BuLi (8.8 ml, 2.5 M) was added dropwise into the round bottom flask and then the solution was stirred again for 3 hours. After the reaction was complete, the temperature was raised to room temperature, and then the mixture was stirred for 12 hours. 3M HCl solution (50 ml) and SnCl₂ (2.08 g, 11 mmol) were added into the round bottom flask under nitrogen atmosphere, and the solution was stirred for 3 hours. Triethylamine was added into the solution to adjust pH of the solution to be neutral, the solution was stirred for 3 hours. Organic phase was extracted with water and dichloromethane and treated with anhydrous MgSO₄. The organic phase was filtered and subjected to reduced pressure to obtain a crude product. The crude product was purified with column chromatography (eluent: dichloromethane) and recrystallized to give a solid Compound 1-3 (0.42 g, 10%).

### Synthesis Example 4: Synthesis of Compound 1-4

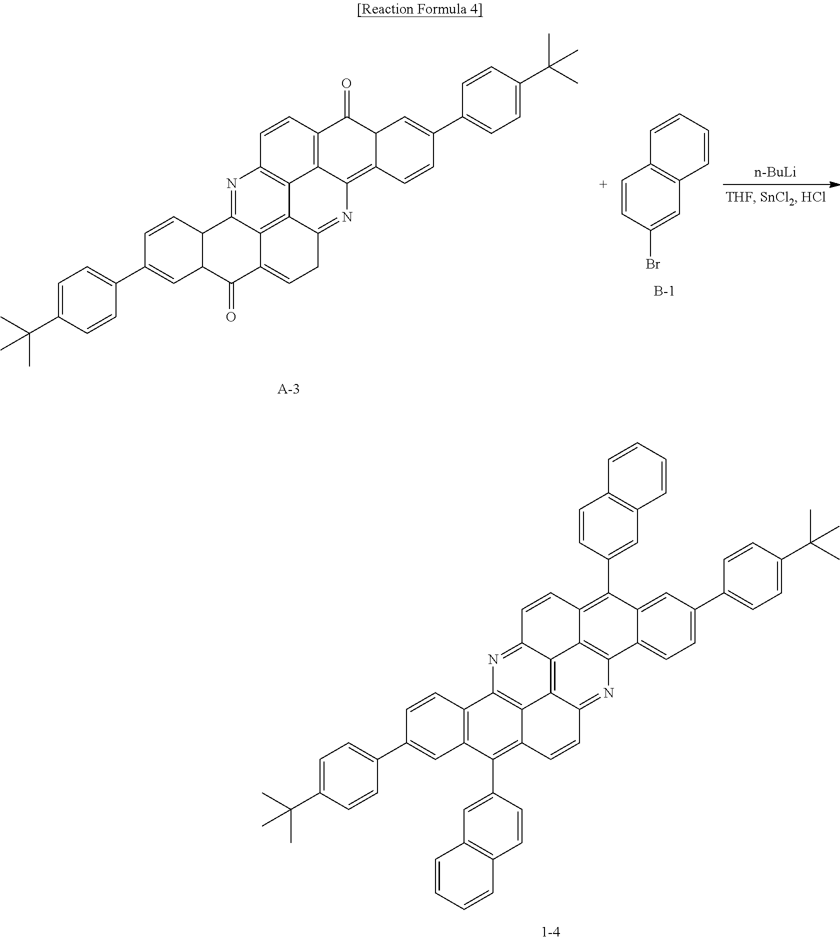

Compound A-3 (4.93 g, 7.3 mmol) and compound B-1 (4.55 g, 221 mmol) dissolved in anhydrous tetrahydrofuran (TTIF, 50 ml) were added into a 100 ml round bottom flask under nitrogen atmosphere, and then the solution was stirred at −78° C. n-BuLi (8.8 ml, 2.5 M) was added dropwise into the round bottom flask and then the solution was stirred again for 3 hours. After the reaction was complete, the temperature was raised to room temperature, and then the mixture was stirred for 12 hours. 3M HCl solution (50 ml) and SnCl₂ (2.08 g, 11 mmol) were added into the round bottom flask under nitrogen atmosphere, and the solution was stirred for 3 hours. Triethylamine was added into the solution to adjust pH of the solution to be neutral, the solution was stirred for 3 hours. Organic phase was extracted with water and dichloromethane and treated with anhydrous MgSO₄. The organic phase was filtered and subjected to reduced pressure to obtain a crude product. The crude product was purified with column chromatography (eluent: dichloromethane) and recrystallized to give a solid Compound 1-4 (0.44 g, 11%).

### Synthesis Example 5: Synthesis of Compound 1-5

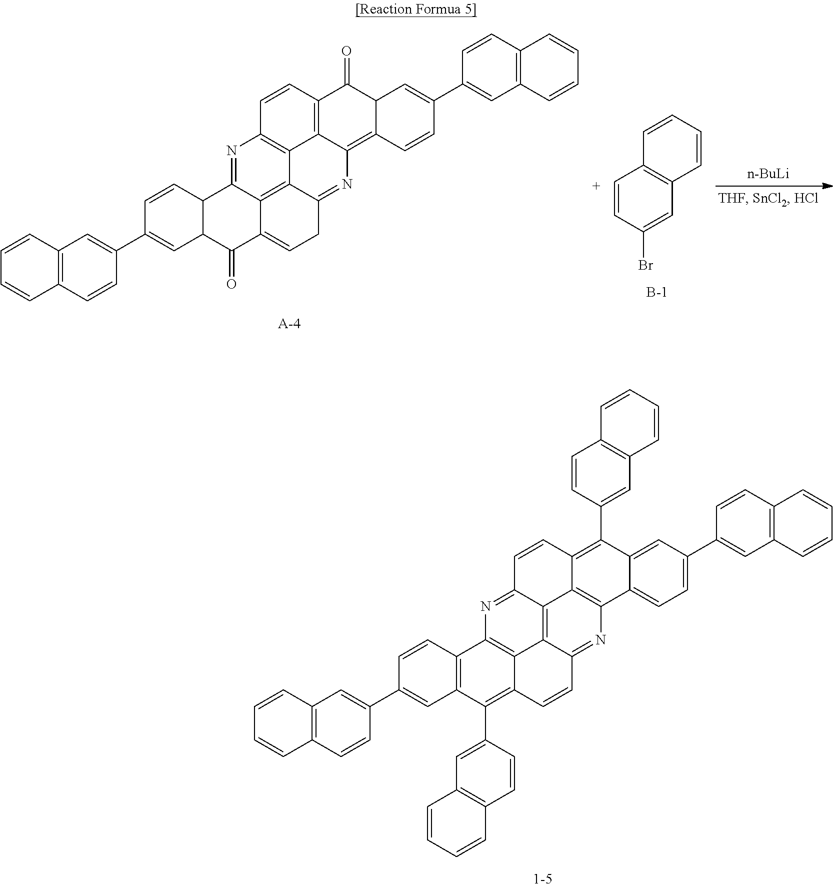

Compound A-4 (4.9 g, 7.3 mmol) and compound B-1 (4.55 g, 22.1 mmol) dissolved in anhydrous tetrahydrofuran (THF, 50 ml) were added into a 100 ml round bottom flask under nitrogen atmosphere, and then the solution was stirred at −78° C. n-BuLi (8.8 ml, 2.5 M) was added dropwise into the round bottom flask and then the solution was stirred again for 3 hours. After the reaction was complete, the temperature was raised to room temperature, and then the mixture was stirred for 12 hours. 3M HCl solution (50 ml) and SnCl₂ (2.08 g, 11 mmol) were added into the round bottom flask under nitrogen atmosphere, and the solution was stirred for 3 hours. Triethylamine was added into the solution to adjust pH of the solution to be neutral, the solution was stirred for 3 hours. Organic phase was extracted with water and dichloromethane and treated with anhydrous MgSO₄. The organic phase was filtered and subjected to reduced pressure to obtain a crude product. The crude product was purified with column chromatography (eluent: dichloromethane) and recrystallized to give a solid Compound 1-5 (0.16 g, 11%).

### Synthesis Example 6: Synthesis of Compound 1-6

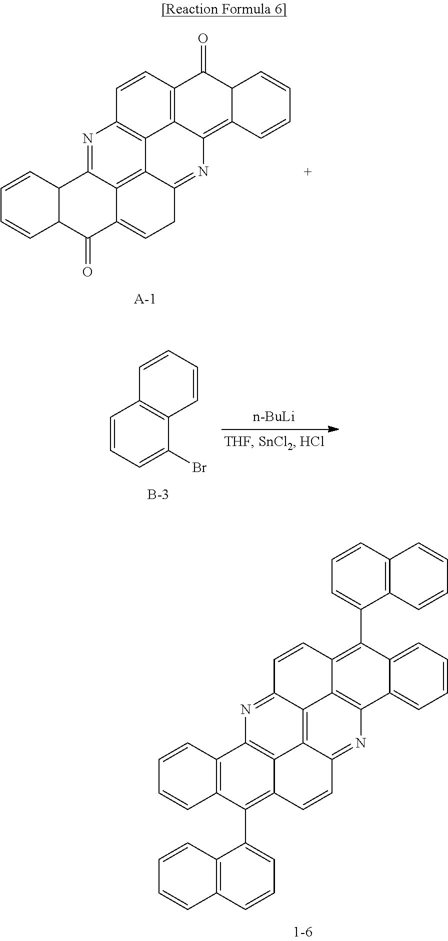

Compound A-1 (3.0 g, 7.3 mmol) and compound B-3 (4.55 g, 22.1 mmol) dissolved in anhydrous tetrahydrofuran (THF, 50 ml) were added into a 100 ml round bottom flask under nitrogen atmosphere, and then the solution was stirred at −78° C. n-BuLi (8.8 ml, 2.5 M) was added dropwise into the round bottom flask and then the solution was stirred again for 3 hours. After the reaction was complete, the temperature was raised to room temperature, and then the mixture was stirred for 12 hours. 3M HCl solution (50 ml) and SnCl₂ (2.08 g, 11 mmol) were added into the round bottom flask under nitrogen atmosphere, and the solution was stirred for 3 hours. Triethylamine was added into the solution to adjust pH of the solution to be neutral, the solution was stirred for 3 hours. Organic phase was extracted with water and dichloromethane and treated with anhydrous MgSO₄. The organic phase was filtered and subjected to reduced pressure to obtain a crude product. The crude product was purified with column chromatography (eluent: dichloromethane) and recrystallized to give a solid Compound 1-6 (0.69 g, 15%).

### Synthesis Example 7: Synthesis of Compound 1-7

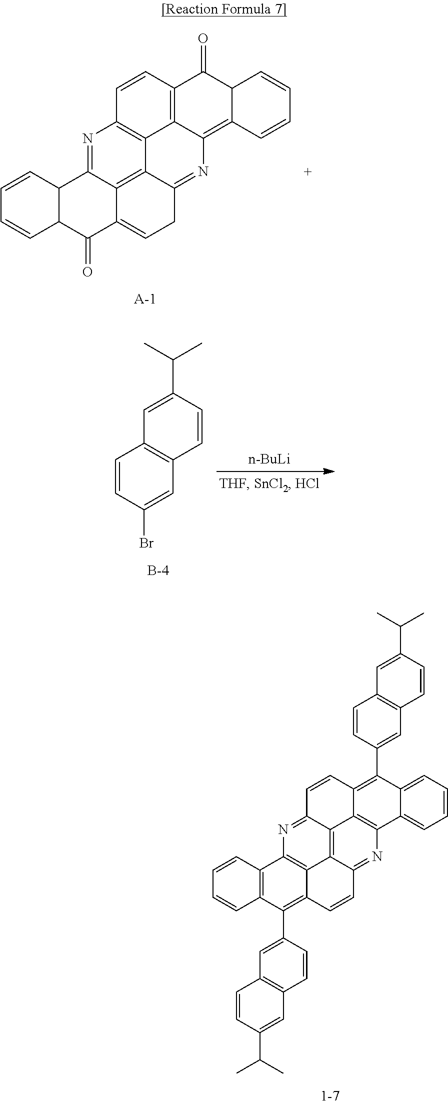

Compound A-1 (3.01 g, 7.3 mmol) and compound B-4 (5.48 g, 22.1 mmol) dissolved in anhydrous tetrahydrofuran (THF, 50 ml) were added into a 100 ml round bottom flask under nitrogen atmosphere, and then the solution was stirred at −78° C. n-BuLi (8.8 ml, 2.5 M) was added dropwise into the round bottom flask and then the solution was stirred again for 3 hours. After the reaction was complete, the temperature was raised to room temperature, and then the mixture was stirred for 12 hours. 3M HCl solution (50 ml) and SnCl₂ (2.08 g, 11 mmol) were added into the round bottom flask under nitrogen atmosphere, and the solution was stirred for 3 hours. Triethylamine was added into the solution to adjust pH of the solution to be neutral, the solution was stirred for 3 hours. Organic phase was extracted with water and dichloromethane and treated with anhydrous MgSO₄. The organic phase was filtered and subjected to reduced pressure to obtain a crude product. The crude product was purified with column chromatography (eluent: dichloromethane) and recrystallized to give a solid Compound 1-7 (0.53 g, 10%).

### Synthesis Example 8: Synthesis of Compound 1-17

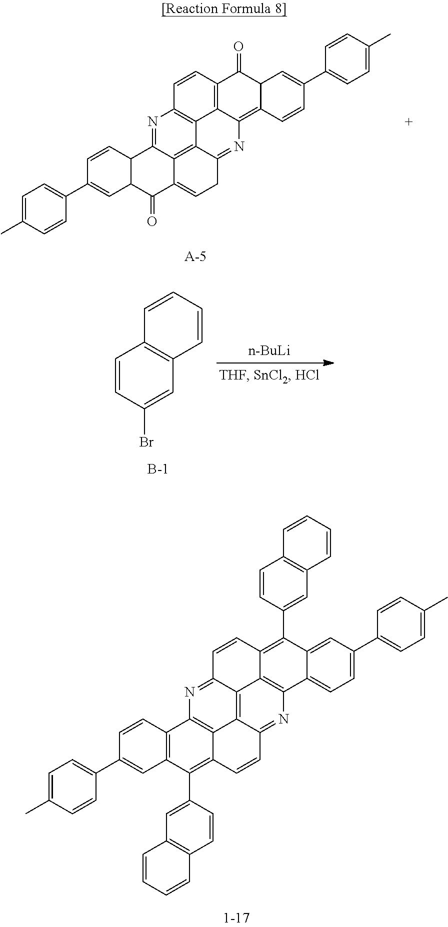

Compound A-5 (4.3 g, 7.3 mmol) and compound B-1 (4.55 g, 22.1 mmol) dissolved in anhydrous tetrahydrofuran (THF, 50 ml) were added into a 100 ml round bottom flask under nitrogen atmosphere, and then the solution was stirred at −78° C. n-BuLi (8.8 ml, 2.5 M) was added dropwise into the round bottom flask and then the solution was stirred again for 3 hours. After the reaction was complete, the temperature was raised to room temperature, and then the mixture was stirred for 12 hours. 3M HCl solution (50 ml) and SnCl₂ (2.08 g, 11 mmol) were added into the round bottom flask under nitrogen atmosphere, and the solution was stirred for 3 hours. Triethylamine was added into the solution to adjust pH of the solution to be neutral, the solution was stirred for 3 hours. Organic phase was extracted with water and dichloromethane and treated with anhydrous MgSO₄. The organic phase was filtered and subjected to reduced pressure to obtain a crude product. The crude product was purified with column chromatography (eluent: dichloromethane) and recrystallized to give a solid Compound 1-17 (0.45 g, 12%).

### Example 1 (Ex. 1): Fabrication of OLED

An organic light emitting diode where Compound 1-1 of Synthesis Example 1 as a first compound (fluorescent dopant) and Compound 3-1 in Chemical Formula 8 as a third compound (P-type host) were included in an emitting material layer was fabricated. A glass substrate onto which ITO (50 nm) was coated as a thin film was washed and ultrasonically cleaned by solvent such as isopropyl alcohol, acetone and dried at 100° C. oven. The substrate was transferred to a vacuum chamber for depositing emissive layer. Subsequently, an emissive layer and a cathode were deposited by evaporation from a heating boat under about 5×10⁻⁷ Torr to 7×10⁻⁷ Torr with setting a deposition rate 1 Å/sas the following order:

A hole injection layer (HAT-CN, 7 nm); a hole transport layer (NPB, 78 nm); an electron blocking layer (TAPC, 10 nm); an emitting material layer (Compound 3-1 in Chemical Formula 8 (mCBP, 64 wt %), NH below (35 wt %), Compound 1-1 (1 wt %, emitter), 38 nm); a hole blocking layer (B3PYMPM, 10 nm); an electron transport layer (TPBi, 25 nm); an electron injection layer (LiF, 1 nm): and a cathode (Al, 100 nm).

The structures of hole injection material, hole transporting material, electron blocking material, hole blocking material and electron transporting material are illustrated in the following:

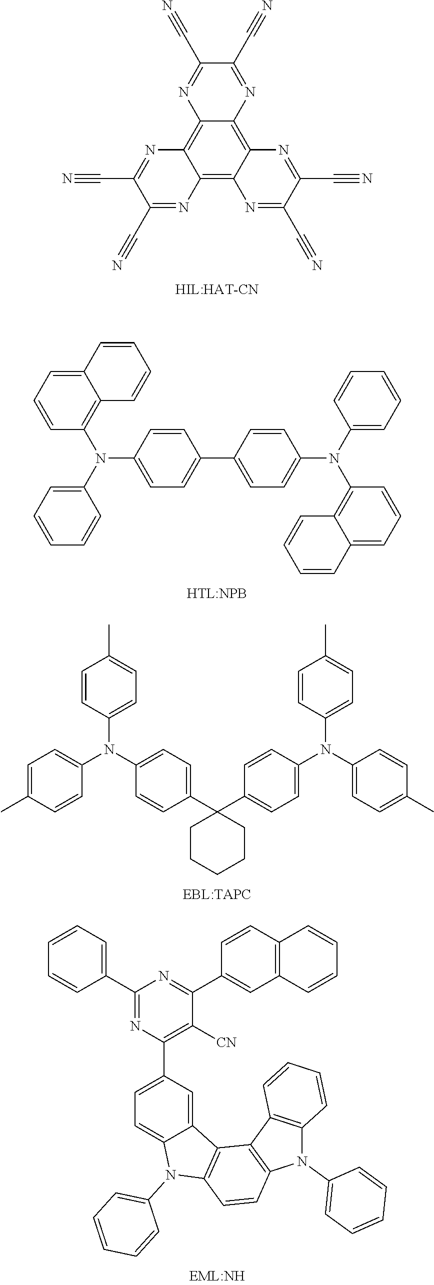

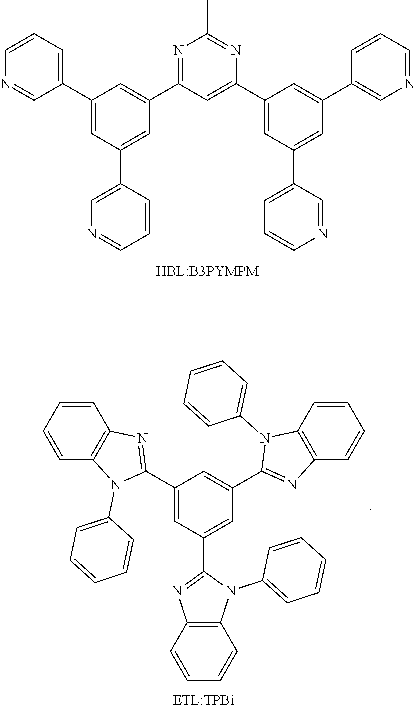 [SMILES: Cc1nc(-c2cc(-c3cccnc3)cc(-c3cccnc3)c2)cc(-c2cc(-c3cccnc3)cc(-c3cccnc3)c2)n1 ; c1ccc(-n2c(-c3cc(-c4nc5ccccc5n4-c4ccccc4)cc(-c4nc5ccccc5n4-c4ccccc4)c3)nc3ccccc32)cc1]

### Examples 2-6 (Ex. 2-6): Fabrication of OLEDs

An OLED was fabricated using the same procedure and the same materials as Example 1, except that instead of Compound 1-1, each of Compound 1-2 (Ex. 2), Compound 1-3 (Ex. 3), Compound 1-4 (Ex. 4), Compound 1-5 (Ex. 5), and Compound 1-6 (Ex. 6) was used as the emitter in the emitting material layer in Examples 2-6, respectively.

### Comparative Examples 1-8 (Refs. 1-8): Fabrication of OLED

An OLED was fabricated using the same procedure and the same materials as Example 1, except that instead of Compound 1-1, each of the following Compound Ref. 1-1 (Ref. 1), Compound Ref 1-2 (Ref. 2), Compound Ref 1-3 (Ref. 3), Compound Ref 1-4 (Ref. 4), Compound Ref 1-5 (Ref. 5), Compound Ref 1-6 (Ref. 6), Compound Ref 1-7 (Ref. 7) and Compound Ref 1-8 (Ref 8) was used as the emitter in the emitting material layer in Refs. 1-8, respectively.

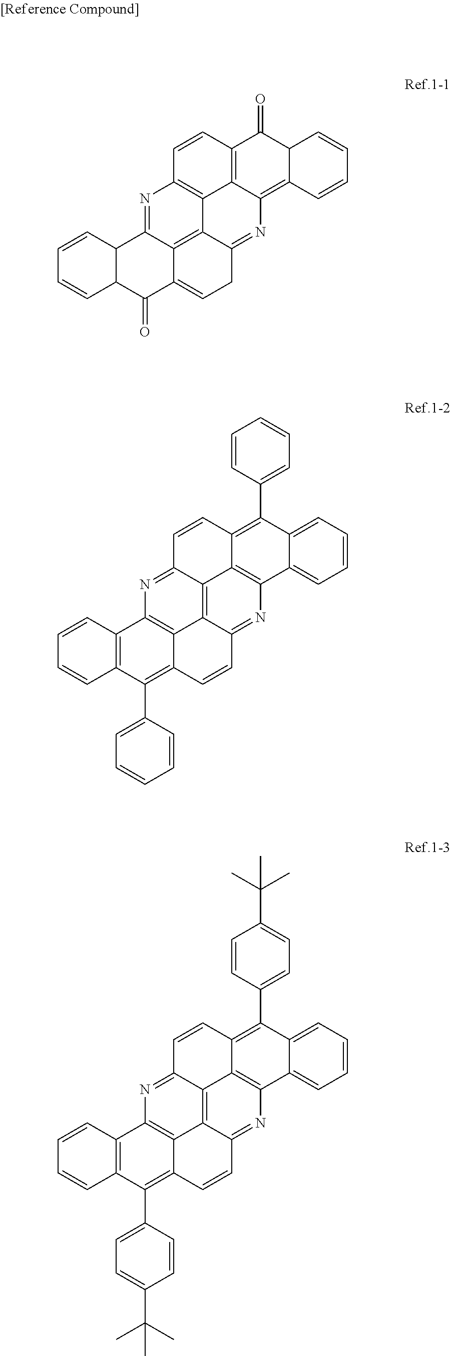 [SMILES: O=C1c2ccc3nc4c5c6c(nc(c2c36)=C2C=CC=CC12)CC=C5C(=O)C1C=CC=CC41 ; c1ccc(-c2c3ccccc3c3nc4ccc5c(-c6ccccc6)c6ccccc6c6nc7ccc2c3c7c4c56)cc1 ; CC(C)(C)c1ccc(-c2c3ccccc3c3nc4ccc5c(-c6ccc(C(C)(C)C)cc6)c6ccccc6c6nc7ccc2c3c7c4c56)cc1]

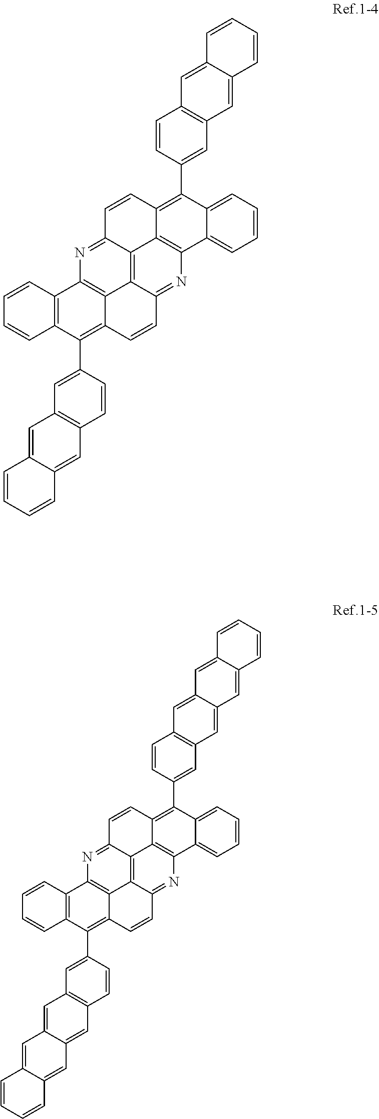 [SMILES: c1ccc2cc3cc(-c4c5ccccc5c5nc6ccc7c(-c8ccc9cc%10ccccc%10cc9c8)c8ccccc8c8nc9ccc4c5c9c6c78)ccc3cc2c1 ; c1ccc2cc3cc4cc(-c5c6ccccc6c6nc7ccc8c(-c9ccc%10cc%11cc%12ccccc%12cc%11cc%10c9)c9ccccc9c9nc%10ccc5c6c%10c7c89)ccc4cc3cc2c1]

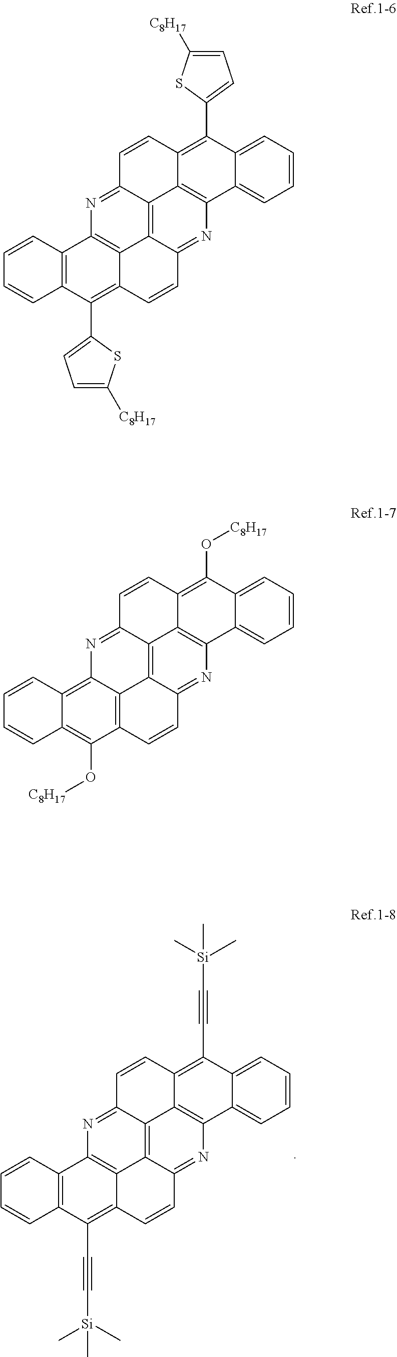

### Experimental Example 1: Measurement of Energy Level and Dipole Moment of Compounds

Luminous property for the OLEDs fabricated in Examples 1 to 6 and Comparative Examples 1 to 8 was measured. Each of the OLEDs having luminous area of 9 mm² was connected to external power source and the luminous property was measured using a current source (KEITHLEY) and a photometer (PR650) at a room temperature. In particular, driving voltage (V), external quantum efficiency (EQE, relative value) and lifespan (LT₉₅, relative value) at which the luminance was reduced to 95% from initial luminance was measured at a current density 6 mA/cm². The measurement results are indicated in the following Table 1.

TABLE 1
Luminous Properties of OLED

| Sample | Emitter | V | EQE (%) | LT₉₅ (%) |
|---|---|---|---|---|
| Ref. 1 | Ref. 1-1 | 3.7 | 96% | 38% |
| Ref. 2 | Ref. 1-2 | 3.7 | 100% | 100% |
| Ref. 3 | Ref. 1-3 | 3.7 | 98% | 100% |
| Ref. 4 | Ref. 1-4 | 3.7 | 99% | 92% |
| Ref. 5 | Ref. 1-5 | 3.7 | 97% | 88% |
| Ref. 6 | Ref. 1-6 | 3.6 | 85% | 40% |
| Ref. 7 | Ref. 1-7 | 3.6 | 88% | 37% |
| Ref. 8 | Ref. 1-8 | 3.5 | 67% | 31% |
| Ex. 1 | 1-1 | 3.7 | 107% | 127% |
| Ex. 2 | 1-2 | 3.7 | 110% | 134% |
| Ex. 3 | 1-3 | 3.7 | 106% | 129% |
| Ex. 4 | 1-4 | 3.7 | 108% | 133% |
| Ex. 5 | 1-5 | 3.7 | 107% | 131% |
| Ex. 6 | 1-6 | 3.7 | 104% | 124% |

As indicated in Table 1, compared to the OLED fabricated in Ref. 2 in which Compound Ref. 1-2 having a phenyl group attached to the core was used as the emitter, in the OLED fabricated in Ref. 1 in which Ref. 1-1 having an oxygen atom linked to the core by an exocyclic bond was used as the emitter, and in Ref. 4 to Ref. 8 in which Compounds Ref. 1-4 to Ref. 1-8, an anthracenyl group with three fused aromatic rings, a tetracenyl group with four fused aromatic rings, a heteroaryl group, an alkoxy group or a silyl group is attached to the core, were used as the emitter, EQE and the luminous lifespan were reduced. On the other hand, compared to the OLED fabricated in Ref. 2, in the OLED fabricated in Ex. 1 to Ex. 6 in which compounds having a naphthyl group attached to the core were used, driving voltage was similar, but EQE and luminous lifespan was improved significantly.

### Example 7 (Ex. 7): Fabrication of OLED

An OLED was fabricated using the same procedure and the same materials as Example 1, except that composition of the emitting material layer was changed to Compound 3-1 (89 wt %) in Chemical Formula 8 as a third compound (P-type host), Compound 2-1 (10 wt %) in Chemical Formula 5 as a second compound (phosphorescent material) and Compound 1-3 (1 wt %) in Chemical Formula 3 as a first compound (fluorescent emitter).

### Examples 8-12 (Ex. 8-12): Fabrication of OLEDs

An OLED was fabricated using the same procedure and the same materials as Example 7, except that instead of Compound 2-1, each of Compound 2-2 (Ex. 8), Compound 2-3 (Ex. 9), Compound 2-4 (Ex. 10), Compound 2-5 (Ex. 11) and Compound 2-6 (Ex. 12) in Chemical Formula 5 was used as the second compound (phosphorescent material) in the emitting material layer in Ex. 8-12, respectively.

### Comparative Examples 9-13 (Ref. 9-13): Fabrication of OLEDs

An OLED was fabricated using the same procedure and the same materials as Example 7, except that instead of Compound 2-1, each of the following Compound Ref. 2-1 (Ref. 9), Compound Ref. 2-2 (Ref. 10), Compound Ref. 2-3 (Ref. 11), Compound Ref. 2-4 (Ref. 12) and Compound Ref. 2-5 (Ref. 13) was used as the second compound (phosphorescent material) in the emitting material layer in Refs. 9-13, respectively.

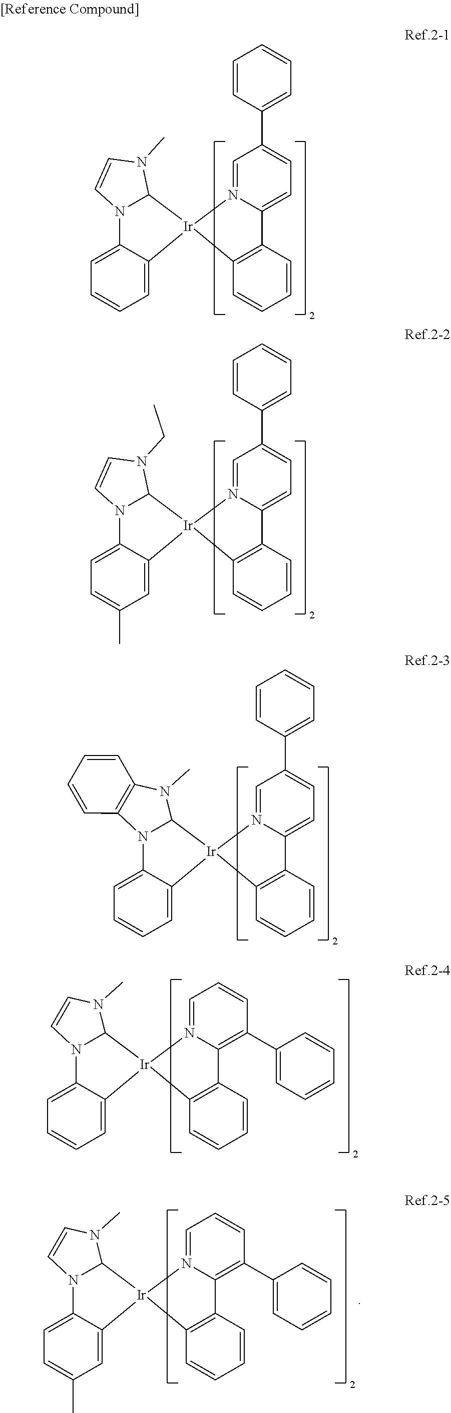

### Example 13 (Ex. 13): Fabrication of OLED

An OLED was fabricated using the same procedure and the same materials as Example 7, except that Compound 1-17 in Chemical Formula 3 instead of Compound 1-3 was used as the first compound (fluorescent emitter) in the emitting material layer.

### Comparative Example 14 (Ref 14): Fabrication of OLED

An OLED was fabricated using the same procedure and the same materials as Example 13, except that the Compound Ref. 2-1 instead of Compound 2-1 was used as the second compound (phosphorescent material) in the emitting material layer.

### Example 14 (Ex. 14): Fabrication of OLED

An OLED was fabricated using the same procedure and the same materials as Example 7, except that Compound 1-4 in Chemical Formula 3 instead of Compound 1-3 was used as the first compound (fluorescent emitter) in the emitting material layer.

### Comparative Example 15 (Ref. 15): Fabrication of OLED

An OLED was fabricated using the same procedure and the same materials as Example 14, except that Compound Ref. 2-1 instead of Compound 2-1 was used as the second compound (phosphorescent material) in the emitting material layer.

### Comparative Examples 16-31 (Ref. 16-31): Fabrication of OLEDs

An OLED was fabricated using the same procedure and the same materials as Example 7, except that the first compound and the second compound in the emitting material layer was used as indicated in the following Table 3.

### Experimental Example 2: Measurement of Luminous Properties of OLEDs

Luminous properties for each of the OLEDs fabricated in Examples 7 to 14 and Comparative Examples 9 to 31 were measured. In particular, driving voltage (V), current efficiency (cd/A), maximum absorption wavelength of the first compound (λₘₐₓ of Abs^{FD}) maximum luminescence wavelength of the first compound (λₘₐₓ of PL^{FD}), maximum luminescence wavelength of the second compound (λₘₐₓ of PL^{PD}), and overlap degree between absorption spectrum of the first compound (Abs^{FD}) and luminescence spectrum of the second compound (PL^{PD}) were measured. The measurement results for the OLEDs fabricated in Ex. 7-14 and Ref. 9-15 are indicated in the following Table 2 and the measurement results for the OLEDs fabricated in Ref. 16-31 are indicated in the following Table 3.

TABLE 2
Luminous Properties of OLED

| | | | | | | | | Overlap |
|---|---|---|---|---|---|---|---|---|
| | 1^{st} | 2^{nd} | 3^{rd} | | | λmax | | degree |
| Sample | Compound | Compound | Compound | V | cd/A | PL^{PD} | Abs^{FD} | (%) |
| Ref. 9 | 1-3 | Ref. 2-1 | 3-1 | 3.4 | 74 | 537 | 513 | 25 |
| Ref. 10 | | Ref. 2-2 | | 3.4 | 70 | 540 | | 22 |
| Ref. 11 | | Ref. 2-3 | | 3.4 | 80 | 533 | | 29 |
| Ref. 12 | | Ref. 2-4 | | 3.5 | 32 | 563 | | 7 |
| Ref. 13 | | Ref. 2-5 | | 3.5 | 28 | 565 | | 6 |
| Ex. 7 | | 2-1 | | 3.4 | 138 | 526 | | 36 |
| Ex. 8 | | 2-2 | | 3.4 | 134 | 529 | | 33 |
| Ex. 9 | | 2-3 | | 3.4 | 142 | 520 | | 40 |
| Ex. 10 | | 2-4 | | 3.5 | 128 | 530 | | 32 |
| Ex. 11 | | 2-5 | | 3.5 | 120 | 532 | | 31 |
| Ex. 12 | | 2-6 | | 3.4 | 136 | 527 | | 35 |
| Ref. 14 | 1-17 | Ref. 2-1 | | 3.4 | 76 | 537 | 515 | 27 |
| Ex. 13 | | 2-1 | | 3.4 | 140 | 526 | | 37 |
| Ref. 15 | 1-4 | Ref. 2-1 | | 3.5 | 78 | 537 | 515 | 27 |
| Ex. 14 | | 2-1 | | 3.4 | 142 | 526 | | 37 |

TABLE 3
Luminous Properties of OLED

| | | | | | | Overlap |
|---|---|---|---|---|---|---|
| | 1^{st} | 2^{nd} | 3^{rd} | | | degree |
| Sample | Compound | Compound | Compound | V | cd/A | (%) |
| Ref. 16 | Ref. 1-1 | Ref. 2-1 | 3-1 | 3.5 | 22 | 3 |
| Ref. 17 | | 2-1 | | 3.5 | 28 | 6 |
| Ref. 18 | Ref. 1-2 | Ref. 2-1 | | 3.4 | 56 | 14 |
| Ref. 19 | | 2-1 | | 3.4 | 74 | 22 |
| Ref. 20 | Ref. 1-3 | Ref. 2-1 | | 3.4 | 58 | 14 |
| Ref. 21 | | 2-1 | | 3.4 | 76 | 22 |
| Ref. 22 | Ref. 1-4 | Ref. 2-1 | | 3.6 | 69 | 20 |
| Ref. 23 | | 2-1 | | 3.6 | 77 | 24 |
| Ref. 24 | Ref. 1-5 | Ref. 2-1 | | 3.6 | 68 | 19 |
| Ref. 25 | | 2-1 | | 3.6 | 69 | 20 |
| Ref. 26 | Ref. 1-6 | Ref. 2-1 | | 3.5 | 54 | 14 |
| Ref. 27 | | 2-1 | | 3.5 | 62 | 17 |
| Ref. 28 | Ref. 1-7 | Ref. 2-1 | | 3.4 | 44 | 12 |
| Ref. 29 | | 2-1 | | 3.4 | 67 | 19 |
| Ref. 30 | Ref. 1-8 | Ref. 2-1 | | 3.4 | 31 | 9 |
| Ref. 31 | | 2-1 | | 3.4 | 49 | 14 |

As indicated in Tables 2 and 3, compared to the OLEDs fabricated in Ref 9-31 where the overlap degree between the luminescence spectrum of the second compound and the absorption spectrum of the first compound is small, in the OLEDs fabricated in Ex. 7-14 where the overlap degree between the luminescence spectrum of the second compound and the absorption spectrum of the first compound is relatively large, the driving voltage was maintained at similar levels and current density was improved by up to 545.5%.

### Example 15 (Ex. 15): Fabrication of OLED

An OLED was fabricated using the same procedure and the same materials as Example 1, except that composition of the emitting material layer was changed to Compound 3-1 (44.5 wt %) in Chemical Formula 8 as a third compound (P-type host), Compound 4-1 (44.5 wt %) in Chemical Formula 11 as a fourth compound (N-type host), Compound 2-1 in Chemical Formula 5 (10 wt %) as a second compound (phosphorescent material) and Compound 1-3 (1 wt %) in Chemical Formula 3 as a first compound (fluorescent emitter).

### Examples 16-18 (Ex. 16-18): Fabrication of OLEDs

An OLED was fabricated using the same procedure and the same materials as Example 15, except that instead of Compound 4-1, each of Compound 4-2 (Ex. 16), Compound 4-3 (Ex. 17) and Compound 4-4 (Ex. 18) in Chemical Formula 11 was used as the fourth compound (N-type host) in the emitting material layer in Ex. 16-18, respectively.

### Example 19 (Ex. 19): Fabrication of OLED

An OLED was fabricated using the same procedure and the same materials as Example 15, except that Compound 1-17 in Chemical Formula 3 instead of Compound 1-3 was used as the first compound (fluorescent emitter).

### Examples 20-22 (Ex. 20-22): Fabrication of OLEDs

An OLED was fabricated using the same procedure and the same materials as Example 19, except that instead of Compound 4-1, each of Compound 4-2 (Ex. 20), Compound 4-3 (Ex. 21) and Compound 4-4 (Ex. 22) in Chemical Formula 11 was used as the fourth compound (N-type host) in the emitting material layer in Ex. 20-22, respectively.

### Example 23 (Ex. 23): Fabrication of OLED

An OLED was fabricated using the same procedure and the same materials as Example 15, except that Compound 1-4 in Chemical Formula 3 instead of Compound 1-3 was used as the first compound (fluorescent emitter).

### Examples 24-26 (Ex. 24-26): Fabrication of OLEDs

An OLED was fabricated using the same procedure and the same materials as Example 23, except that each of Compound 4-2 (Ex. 24), Compound 4-3 (Ex. 25) and Compound 4-4 (Ex. 26) in Chemical Formula 11 instead of Compound 4-1 was used as the fourth compound (N-type host) in the emitting material layer, respectively.

### Experimental Example 3: Measurement of Luminous Properties of OLEDs

Luminous properties of the driving voltage (V), current efficiency (cd/A, relative value) and LT₉₅ (relative value) for each of the OLEDs fabricated in Examples 7, 13, 14 and 15-26 were measured as Experimental Example 1. The measurement results are indicated in the following Table 4.

TABLE 4
Luminous Properties of OLED

| | 1^{st} | 2^{nd} | 3^{rd} | 4^{th} | | cd/A | LT₉₅ |
|---|---|---|---|---|---|---|---|
| Sample | Compound | Compound | Compound | Compound | V | (%) | (%) |
| Ex. 7 | 1-1 | 2-1 | 3-1 | — | 3.4 | 100 | 100 |
| Ex. 13 | 1-17 | 2-1 | | — | 3.4 | 102 | 102 |
| Ex. 14 | 1-4 | 2-1 | | — | 3.4 | 102 | 105 |
| Ex. 15 | 1-3 | 2-1 | 3-1 | 4-1 | 3.3 | 106 | 130 |
| Ex. 16 | | | | 4-2 | 3.3 | 105 | 124 |
| Ex. 17 | | | | 4-3 | 3.3 | 107 | 131 |
| Ex. 18 | | | | 4-4 | 3.2 | 103 | 126 |
| Ex. 19 | 1-17 | | 3-1 | 4-1 | 3.3 | 109 | 132 |
| Ex. 20 | | | | 4-2 | 3.3 | 107 | 125 |
| Ex. 21 | | | | 4-3 | 3.3 | 109 | 133 |
| Ex. 22 | | | | 4-4 | 3.2 | 105 | 127 |
| Ex. 23 | 1-4 | | 3-1 | 4-1 | 3.3 | 109 | 134 |
| Ex. 24 | | | | 4-2 | 3.3 | 108 | 128 |
| Ex. 25 | | | | 4-3 | 3.3 | 109 | 135 |
| Ex. 26 | | | | 4-4 | 3.2 | 106 | 128 |

As indicated in Table 4, compared to the OLEDs fabricated in Ex. 7, 13 and 14 where the emitting material layer includes only the third compound of the P-type host as the host, in the OLEDs fabricated in Ex. 15-26 wherein the emitting material layer includes the third compound of the P-type host and the fourth compound of the N-type host, the driving voltage was slightly reduced, and current density and luminous lifespan were greatly improved.

Summing up the results of Tables 1 to 4, it may be possible to realize an organic light emitting diode having improved luminous properties by using the fluorescent emitter having a naphthalene moiety at the terminal of the core as the first compound and the phosphorescent material having luminescence spectrum of great overlap degree to the absorption wavelength or absorption spectrum of the first compound.

It will be apparent to those skilled in the art that various modifications and variations may be made in the present disclosure without departing from the scope of the disclosure. Thus, it is intended that the present disclosure cover the modifications and variations of the present disclosure provided they come within the scope of the appended claims and their equivalents.

1. An organic light emitting diode, including:
a first electrode;
a second electrode facing the first electrode; and
an emissive layer disposed between the first electrode and the second electrode, the emissive layer including at least one emitting material layer that includes:
a first compound including a first organic compound represented by Chemical Formula 1, and
a second compound including an organometallic compound represented by Chemical Formula 4: 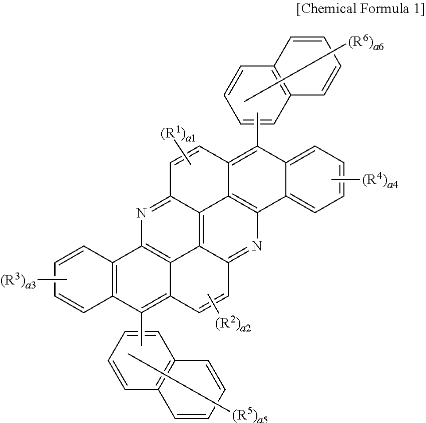
wherein, in the Chemical Formula 1,
each of R¹, R², R³, R⁴, R⁵, and R⁶ is independently a halogen atom, a cyano group, an unsubstituted or substituted C₁-C₂₀ alkyl group, an unsubstituted or substituted C₁-C₂₀ alkyl amino group, an unsubstituted or substituted C₆-C₃₀ aryl group, an unsubstituted or substituted C₃-C₃₀ heteroaryl group, an unsubstituted or substituted C₆-C₃₀ aryl amino group or an unsubstituted or substituted C₃-C₃₀ heteroaryl amino group, where each R¹ is identical to or different from each other when a1 is 2, each R² is identical to or different from each other when a2 is 2, each R³ is identical to or different from each other when a3 is 2, 3 or 4, each R⁴ is identical to or different from each other when a4 is 2, 3 or 4, each R⁵ is identical to or different from each other when a5 is 2, 3, 4, 5, 6 or 7, and each R⁶ is identical to or different from each other when a6 is 2, 3, 4, 5, 6 or 7;
each of a1 and a2 is independently 0, 1 or 2;
each of a3 and a4 is independently 0, 1, 2, 3 or 4; and
each of a5 and a6 is independently 0, 1, 2, 3, 4, 5, 6 or 7, 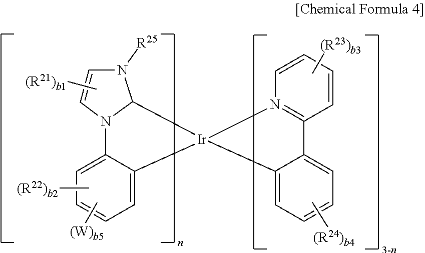
wherein, in the Chemical Formula 4,
each of R²¹, R²², R²³, and R²⁴ is independently an unsubstituted or substituted C₁-C₂₀ alkyl group, an unsubstituted or substituted C₁-C₂₀ alkyl amino group, an unsubstituted or substituted C₆-C₃₀ aryl group, an unsubstituted or substituted C₃-C₃₀ heteroaryl group, an unsubstituted or substituted C₆-C₃₀ aryl amino group or an unsubstituted or substituted C₃-C₃₀ heteroaryl amino group, where each R²¹ is identical to or different from each other when b1 is 2, each R²² is identical to or different from each other when b2 is 2 or 3, each R²³ is identical to or different from each other when b3 is 2, 3 or 4, and each R²⁴ is identical to or different from each other when b4 is 2, 3 or 4,
optionally,
two adjacent R²¹ are linked together to form an unsubstituted or substituted C₆-C₂₀ aromatic ring or an unsubstituted or substituted C₃-C₂₀ heteroaromatic ring when b1 is 2, two adjacent R²² are linked together to form an unsubstituted or substituted C₆-C₂₀ aromatic ring or an unsubstituted or substituted C₃-C₂₀ heteroaromatic ring when b2 is 2 or 3, two adjacent R²³ are linked together to form an unsubstituted or substituted C₆-C₂₀ aromatic ring or an unsubstituted or substituted C₃-C₂₀ heteroaromatic ring when b3 is 2, 3 or 4, and/or two adjacent R²⁴ are linked together to form an unsubstituted or substituted C₆-C₂₀ aromatic ring or an unsubstituted or substituted C₃-C₂₀ heteroaromatic ring when b4 is 2, 3 or 4;
R²⁵ is hydrogen or an unsubstituted or substituted C₁-C₂₀ alkyl group;
W is a cyano group, a nitro group, a halogen atom, a C₁-C₂₀ alkyl group, a C₆-C₃₀ aryl group or a C₃-C₃₀ heteroaryl group, where each of the C₁-C₂₀ alkyl group, the C₆-C₃₀ aryl group, and the C₃-C₃₀ heteroaryl group is optionally substituted with at least one group selected from a cyano group, a nitro group, and a halogen atom;
b1 is 0, 1 or 2;
b2 is 0, 1, 2 or 3;
each of b3 and b4 is independently 0, 1, 2, 3 or 4;
b5 is 1 or 2, where b2+b5=1, 2, 3 or 4; and
n is 1, 2 or 3.

2. The organic light emitting diode of claim 1, wherein the first organic compound is represented by Chemical Formula 2A or Chemical Formula 2B: 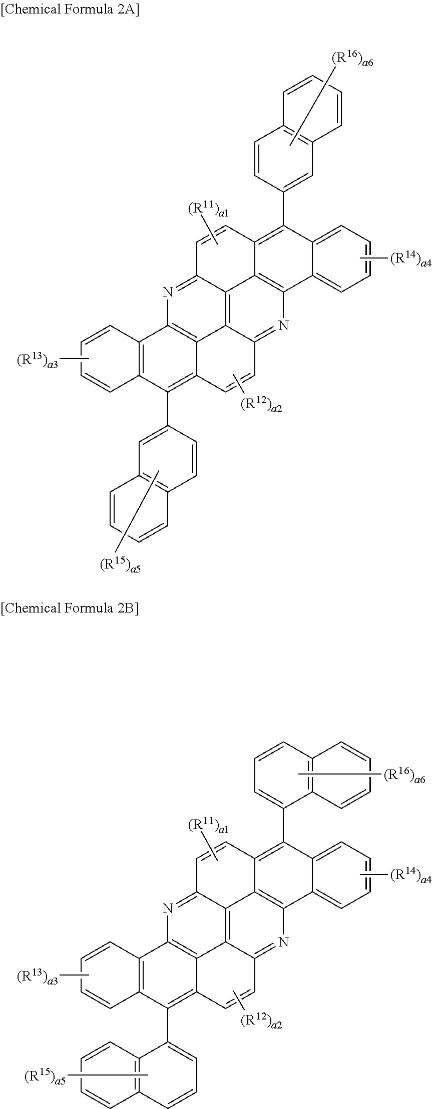
wherein, in the Chemical Formulae 2A and 2B,
each of a1, a2, a3, a4, a5, and a6 is as defined in the Chemical Formula 1,
each of R¹¹, R¹², R¹³, R¹⁴, R¹⁵ and R¹⁶ is independently an unsubstituted or a substituted C₁-C₁₀ alkyl group or an unsubstituted or C₁-C₁₀ alkyl-substituted C₆-C₃₀ aryl group, where each R¹¹ is identical to or different from each other when a1 is 2, each R¹² is identical to or different from each other when a2 is 2, each R¹³ is identical to or different from each other when a3 is 2, 3 or 4, each R¹⁴ is identical to or different from each other when a4 is 2, 3 or 4, each R¹⁵ is identical to or different from each other when a5 is 2, 3, 4, 5, 6 or 7, and each R¹⁶ is identical to or different from each other when a6 is 2, 3, 4, 5, 6 or 7.

3. The organic light emitting diode of claim 1, wherein each of a1 and a2 is 0, each of a3, a4, a5, and a6 is independently 0 or 1, and each of R³, R⁴, R⁵, and R⁶ is independently an unsubstituted or a substituted C₁-C₁₀ alkyl or an unsubstituted or C₁-C₁₀ alkyl-substituted C₆-C₃₀ aryl group.

4. The organic light emitting diode of claim 1, wherein each of a1 and a2 is 0, each of R³ and R⁴ is independently an unsubstituted or C₁-C₁₀ alkyl-substituted C₆-C₃₀ aryl group, each of a3 and a4 is independently 0 or 1, each of R⁵, and R⁶ is independently an unsubstituted or a substituted C₁-C₁₀ alkyl group, and each of a5 and a6 is independently 0 or 1.

5. The organic light emitting diode of claim 1, wherein the first organic compound includes at least one of the following compounds:

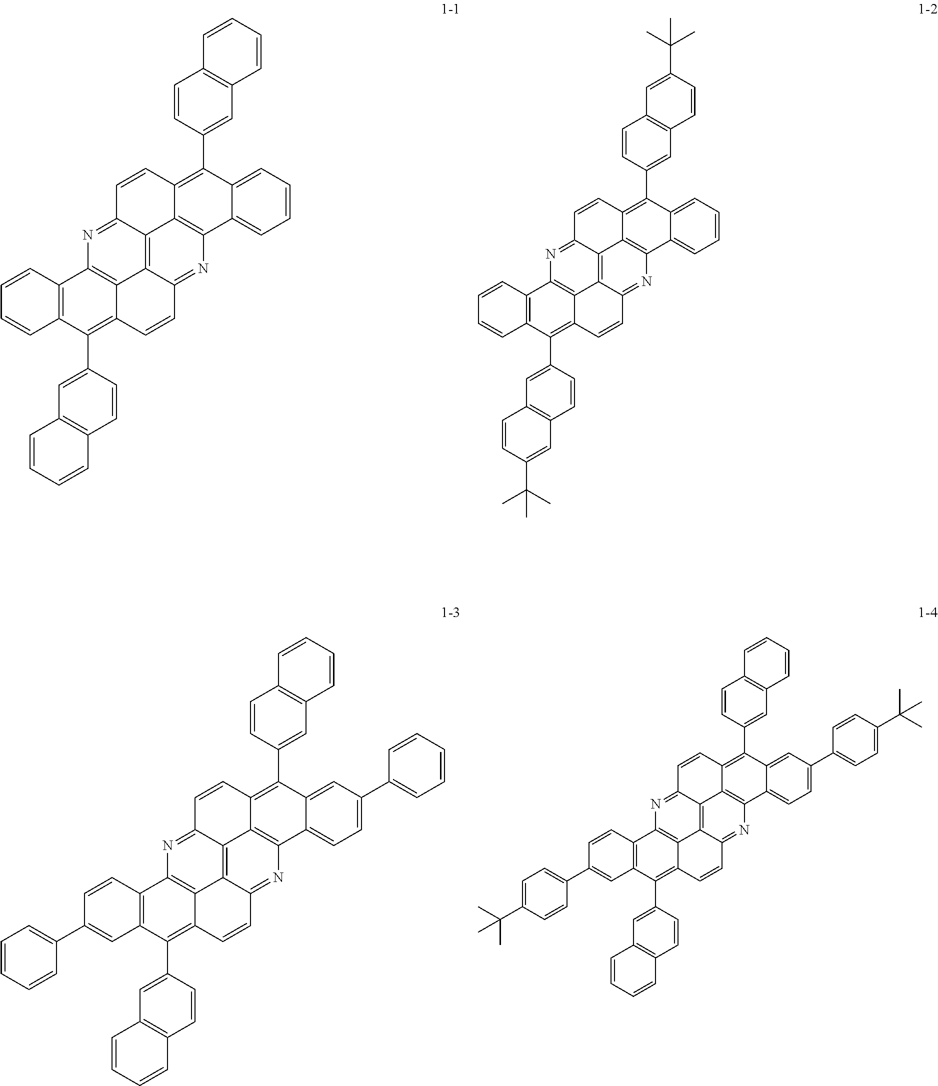 [SMILES: c1ccc2cc(-c3c4ccccc4c4nc5ccc6c(-c7ccc8ccccc8c7)c7ccccc7c7nc8ccc3c4c8c5c67)ccc2c1 ; CC(C)(C)c1ccc2cc(-c3c4ccccc4c4nc5ccc6c(-c7ccc8cc(C(C)(C)C)ccc8c7)c7ccccc7c7nc8ccc3c4c8c5c67)ccc2c1 ; c1ccc(-c2ccc3c(c2)c(-c2ccc4ccccc4c2)c2ccc4nc5c6ccc(-c7ccccc7)cc6c(-c6ccc7ccccc7c6)c6ccc7nc3c2c4c7c65)cc1 ; CC(C)(C)c1ccc(-c2ccc3c(c2)c(-c2ccc4ccccc4c2)c2ccc4nc5c6ccc(-c7ccc(C(C)(C)C)cc7)cc6c(-c6ccc7ccccc7c6)c6ccc7nc3c2c4c7c65)cc1]

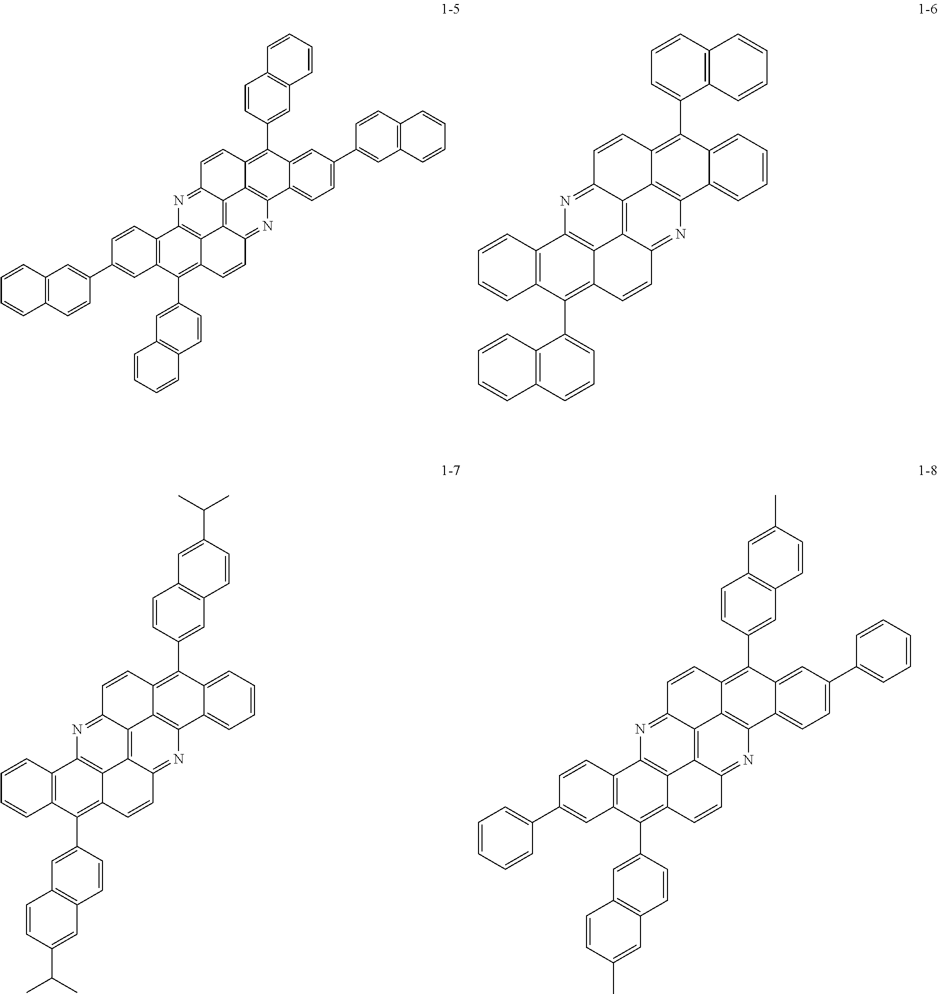 [SMILES: c1ccc2cc(-c3ccc4c(c3)c(-c3ccc5ccccc5c3)c3ccc5nc6c7ccc(-c8ccc9ccccc9c8)cc7c(-c7ccc8ccccc8c7)c7ccc8nc4c3c5c8c76)ccc2c1 ; c1ccc2c(-c3c4ccccc4c4nc5ccc6c(-c7cccc8ccccc78)c7ccccc7c7nc8ccc3c4c8c5c67)cccc2c1 ; CC(C)c1ccc2cc(-c3c4ccccc4c4nc5ccc6c(-c7ccc8cc(C(C)C)ccc8c7)c7ccccc7c7nc8ccc3c4c8c5c67)ccc2c1 ; Cc1ccc2cc(-c3c4cc(-c5ccccc5)ccc4c4nc5ccc6c(-c7ccc8cc(C)ccc8c7)c7cc(-c8ccccc8)ccc7c7nc8ccc3c4c8c5c67)ccc2c1]

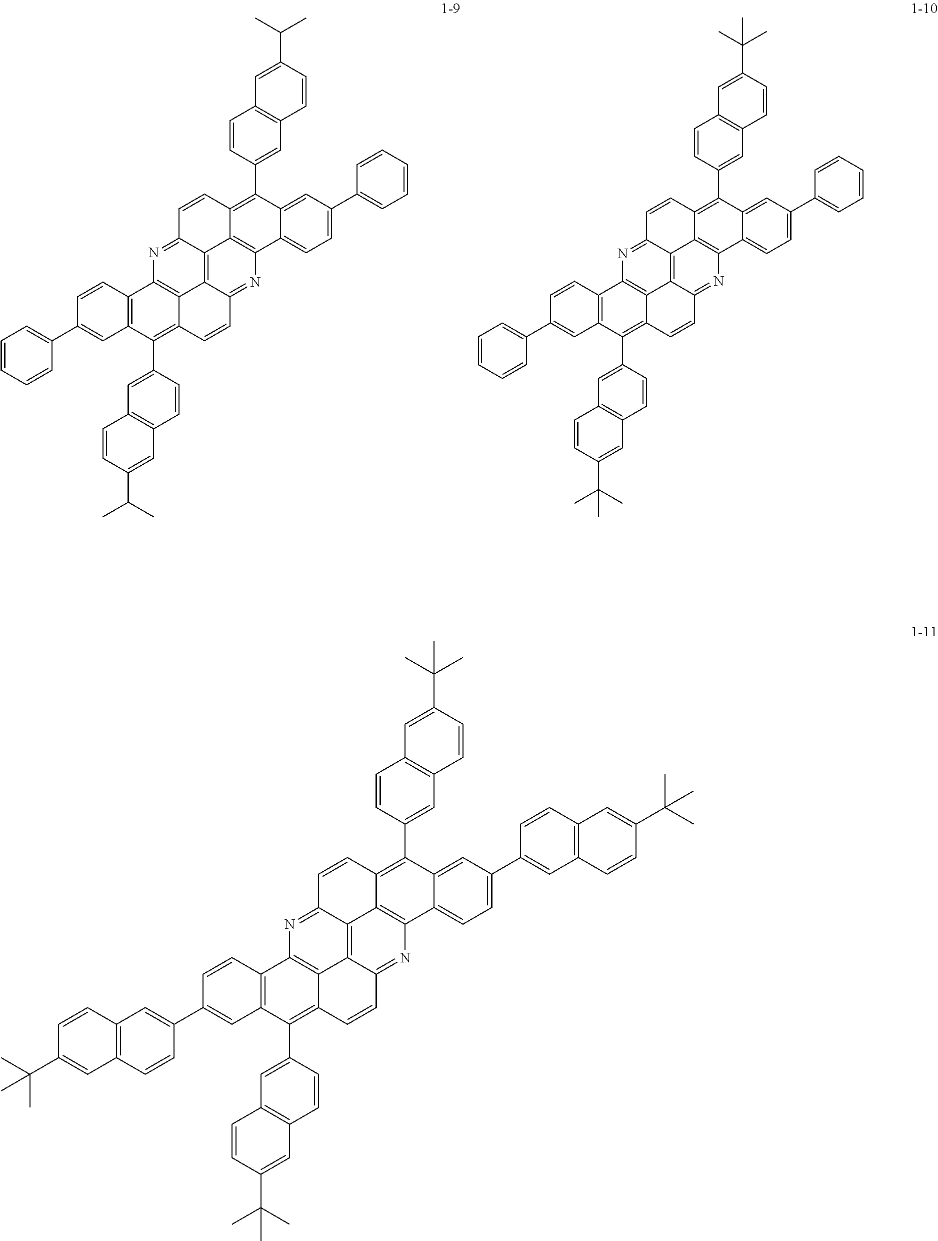 [SMILES: CC(C)c1ccc2cc(-c3c4cc(-c5ccccc5)ccc4c4nc5ccc6c(-c7ccc8cc(C(C)C)ccc8c7)c7cc(-c8ccccc8)ccc7c7nc8ccc3c4c8c5c67)ccc2c1 ; CC(C)(C)c1ccc2cc(-c3c4cc(-c5ccccc5)ccc4c4nc5ccc6c(-c7ccc8cc(C(C)(C)C)ccc8c7)c7cc(-c8ccccc8)ccc7c7nc8ccc3c4c8c5c67)ccc2c1 ; CC(C)(C)c1ccc2cc(-c3ccc4c(c3)c(-c3ccc5cc(C(C)(C)C)ccc5c3)c3ccc5nc6c7ccc(-c8ccc9cc(C(C)(C)C)ccc9c8)cc7c(-c7ccc8cc(C(C)(C)C)ccc8c7)c7ccc8nc4c3c5c8c76)ccc2c1]

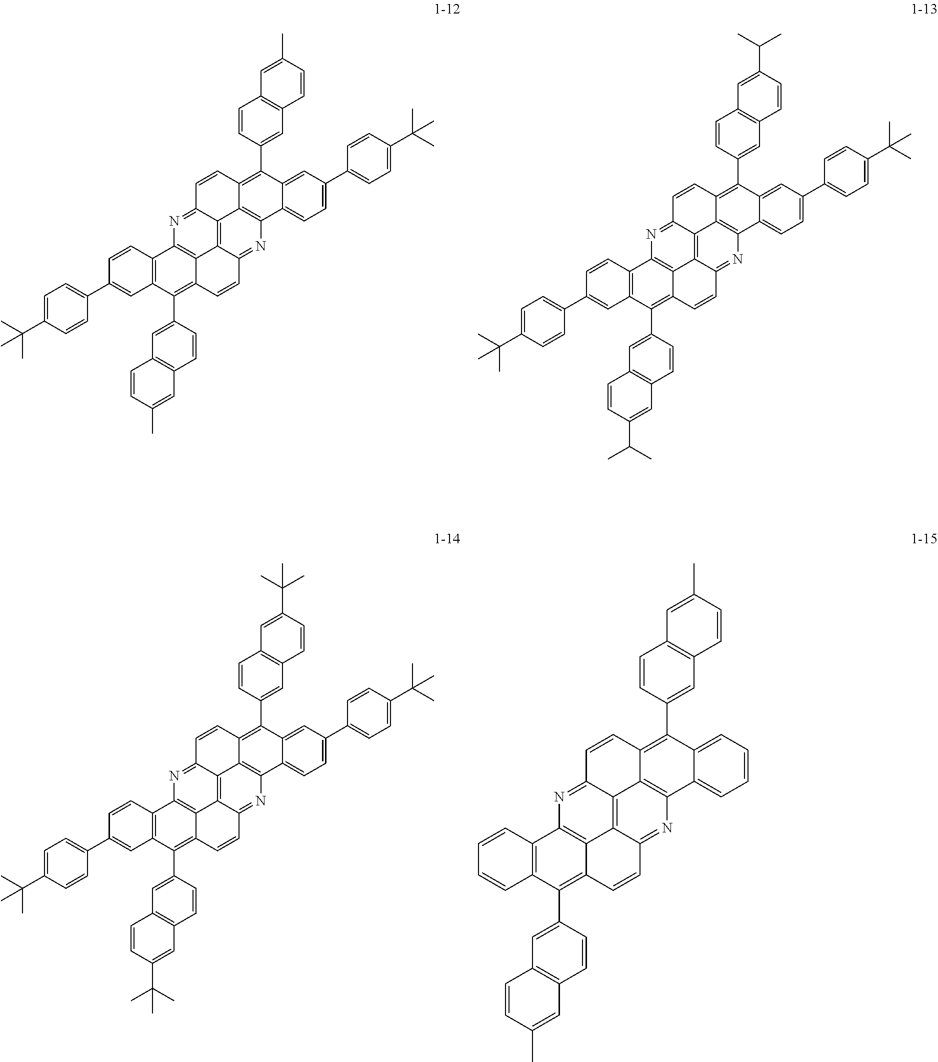 [SMILES: Cc1ccc2cc(-c3c4cc(-c5ccc(C(C)(C)C)cc5)ccc4c4nc5ccc6c(-c7ccc8cc(C)ccc8c7)c7cc(-c8ccc(C(C)(C)C)cc8)ccc7c7nc8ccc3c4c8c5c67)ccc2c1 ; CC(C)c1ccc2cc(-c3c4cc(-c5ccc(C(C)(C)C)cc5)ccc4c4nc5ccc6c(-c7ccc8cc(C(C)C)ccc8c7)c7cc(-c8ccc(C(C)(C)C)cc8)ccc7c7nc8ccc3c4c8c5c67)ccc2c1 ; CC(C)(C)c1ccc(-c2ccc3c(c2)c(-c2ccc4cc(C(C)(C)C)ccc4c2)c2ccc4nc5c6ccc(-c7ccc(C(C)(C)C)cc7)cc6c(-c6ccc7cc(C(C)(C)C)ccc7c6)c6ccc7nc3c2c4c7c65)cc1 ; Cc1ccc2cc(-c3c4ccccc4c4nc5ccc6c(-c7ccc8cc(C)ccc8c7)c7ccccc7c7nc8ccc3c4c8c5c67)ccc2c1]

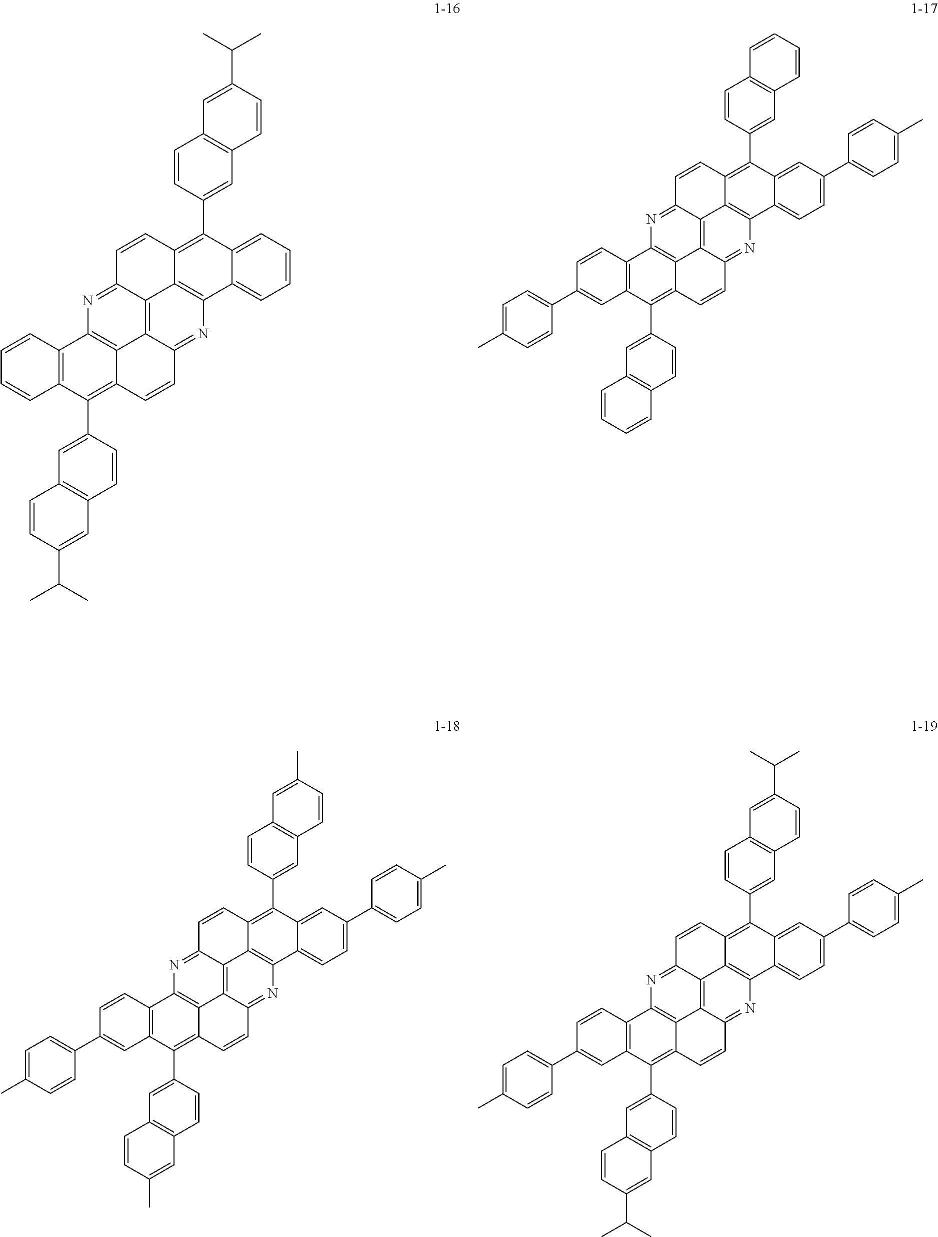

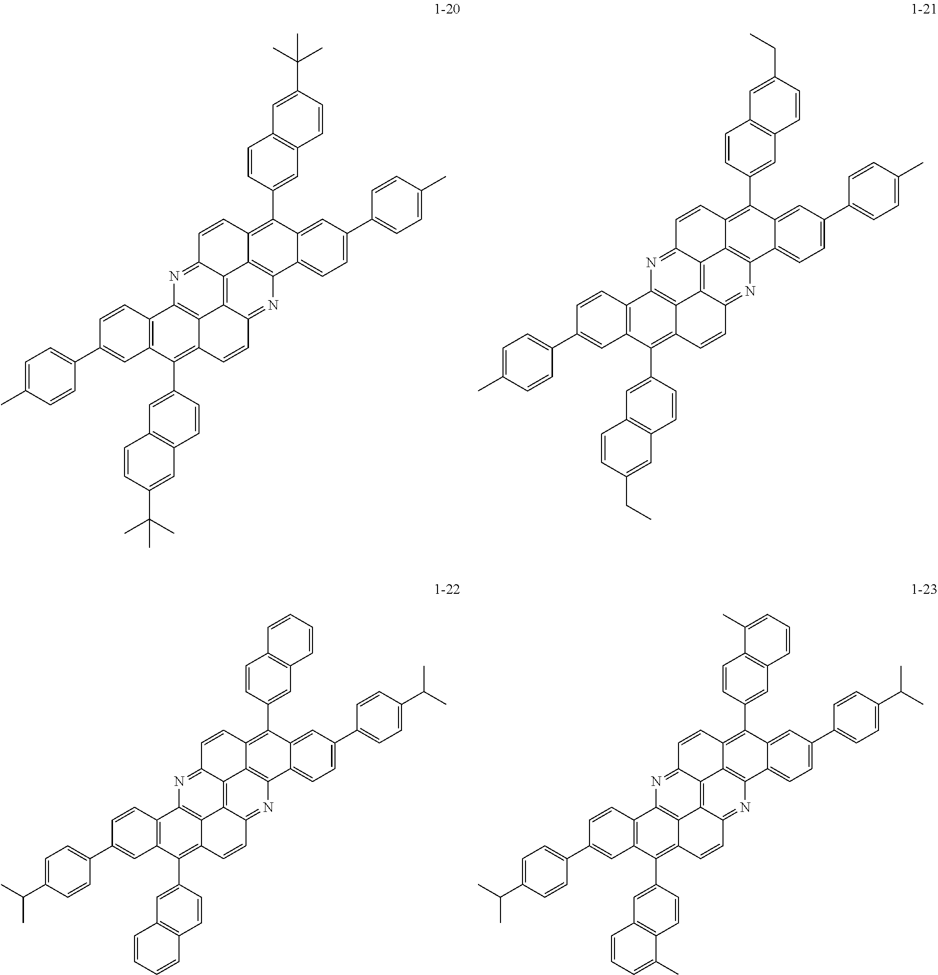

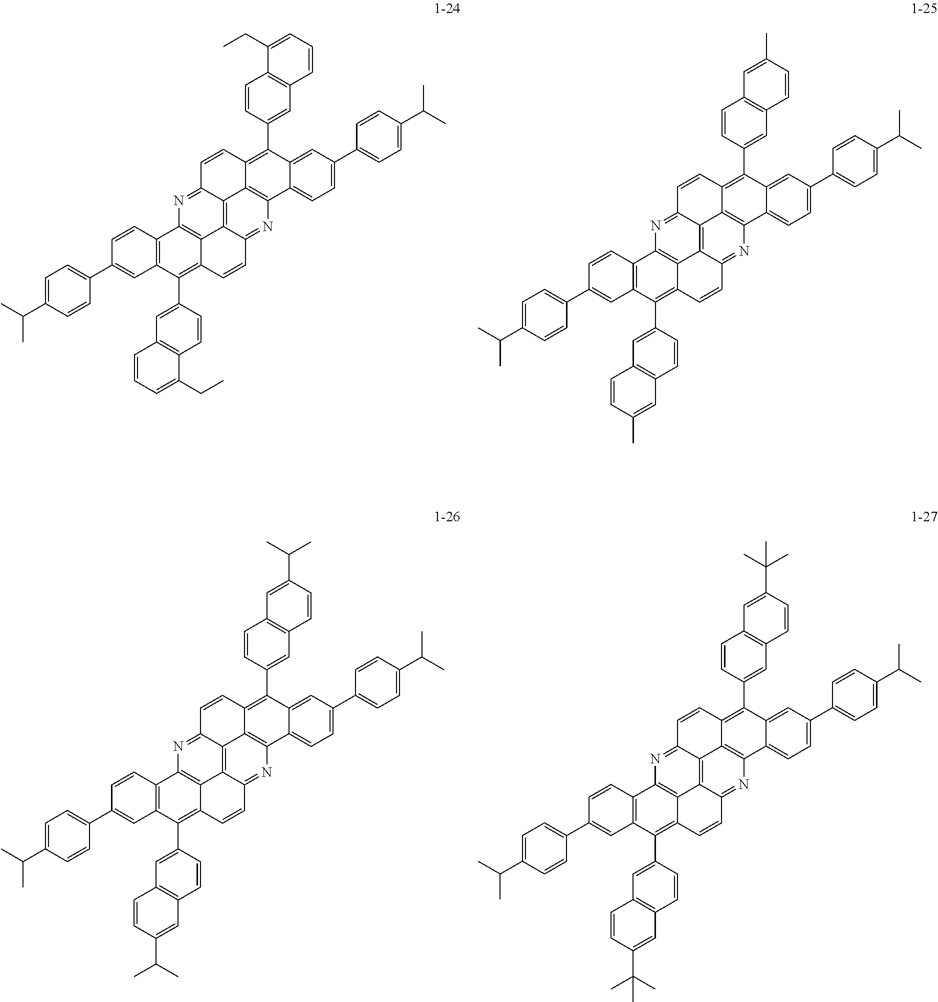

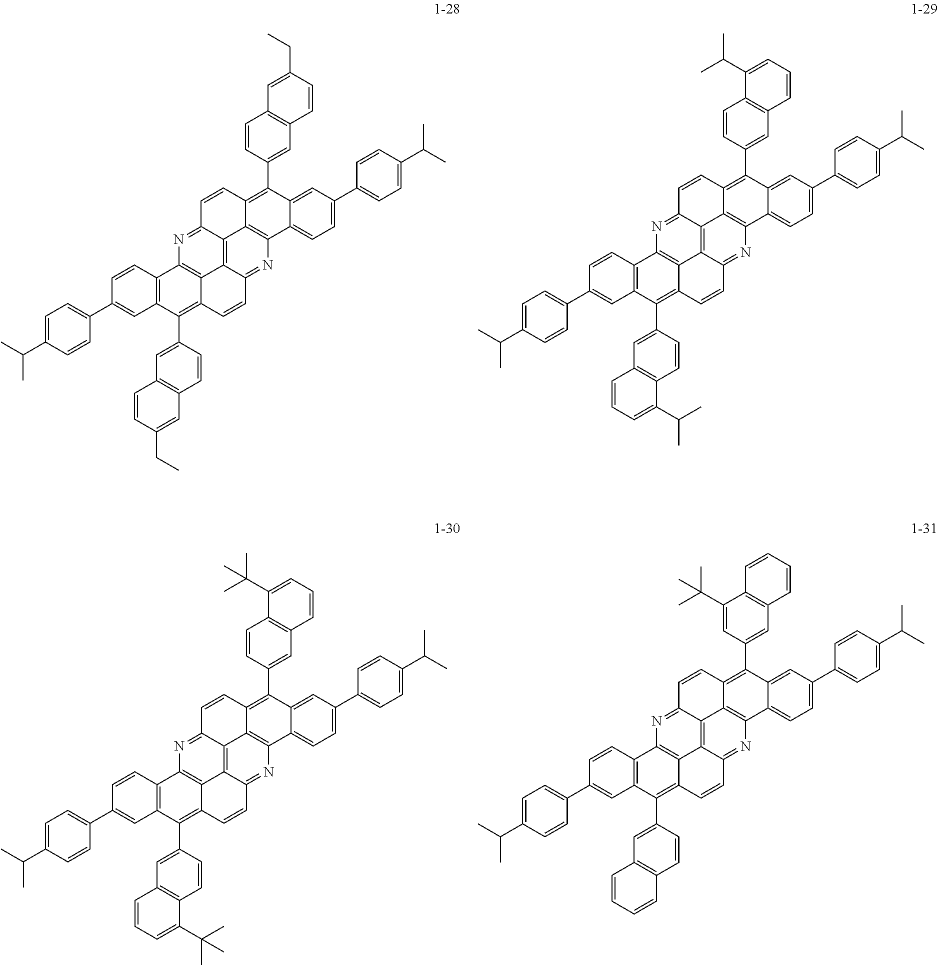

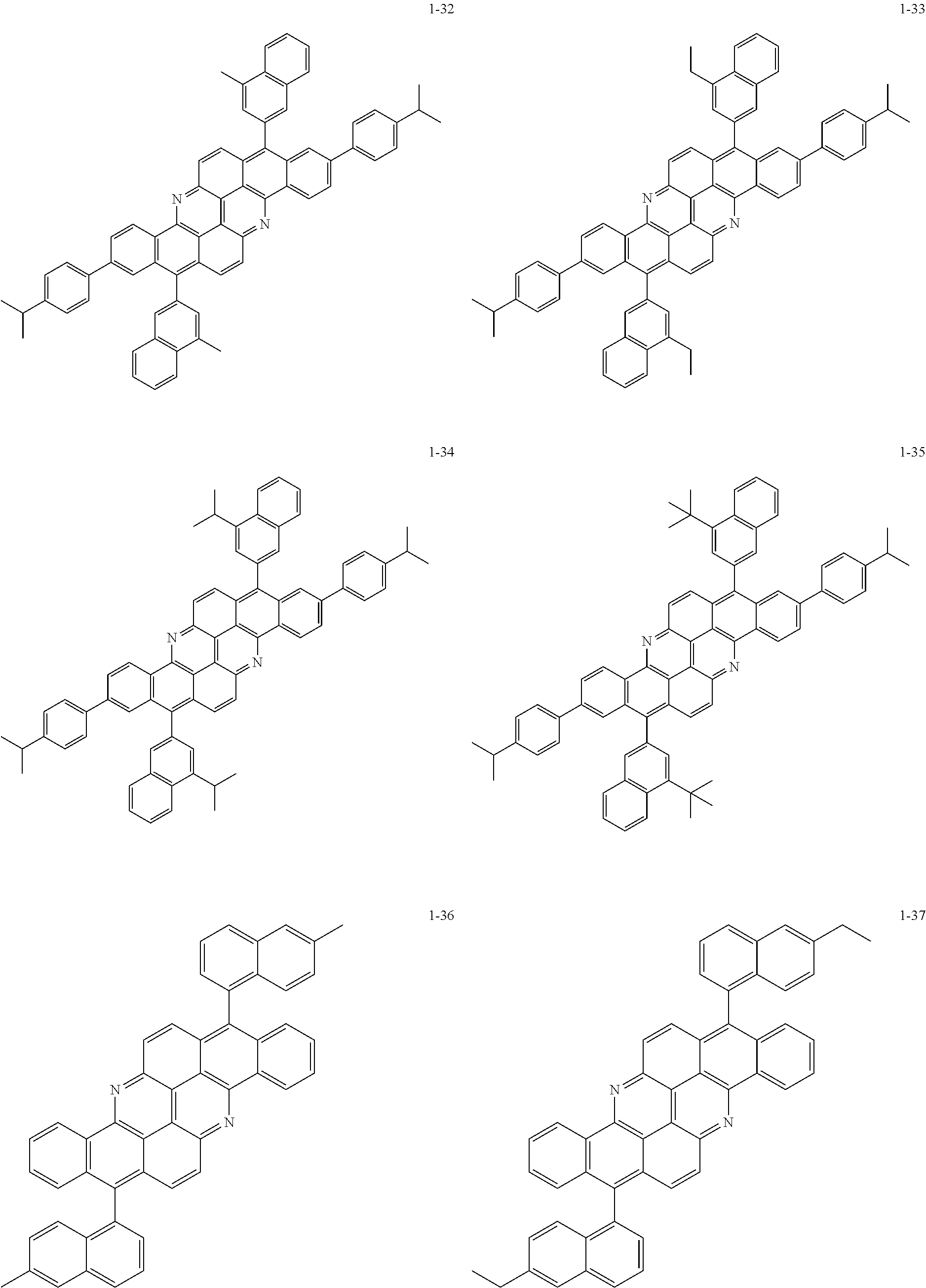

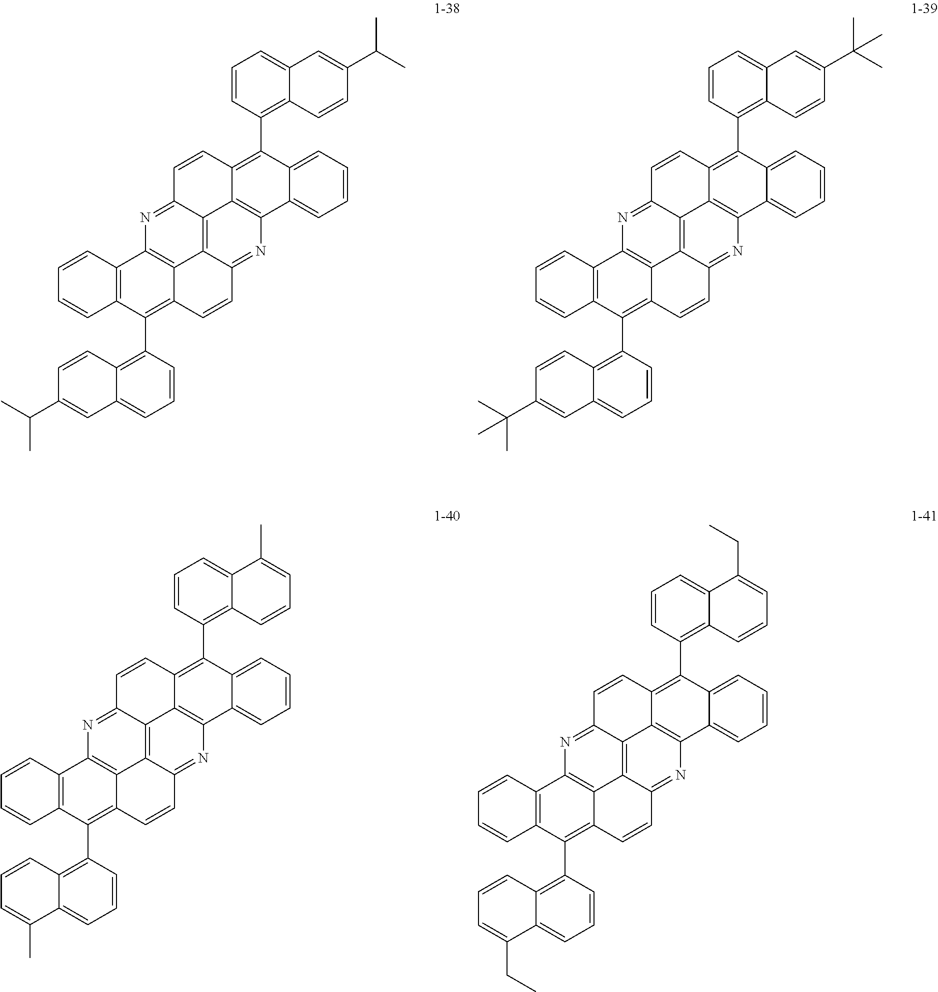 [SMILES: CC(C)c1ccc2c(-c3c4ccccc4c4nc5ccc6c(-c7cccc8cc(C(C)C)ccc78)c7ccccc7c7nc8ccc3c4c8c5c67)cccc2c1 ; CC(C)(C)c1ccc2c(-c3c4ccccc4c4nc5ccc6c(-c7cccc8cc(C(C)(C)C)ccc78)c7ccccc7c7nc8ccc3c4c8c5c67)cccc2c1 ; Cc1cccc2c(-c3c4ccccc4c4nc5ccc6c(-c7cccc8c(C)cccc78)c7ccccc7c7nc8ccc3c4c8c5c67)cccc12 ; CCc1cccc2c(-c3c4ccccc4c4nc5ccc6c(-c7cccc8c(CC)cccc78)c7ccccc7c7nc8ccc3c4c8c5c67)cccc12]

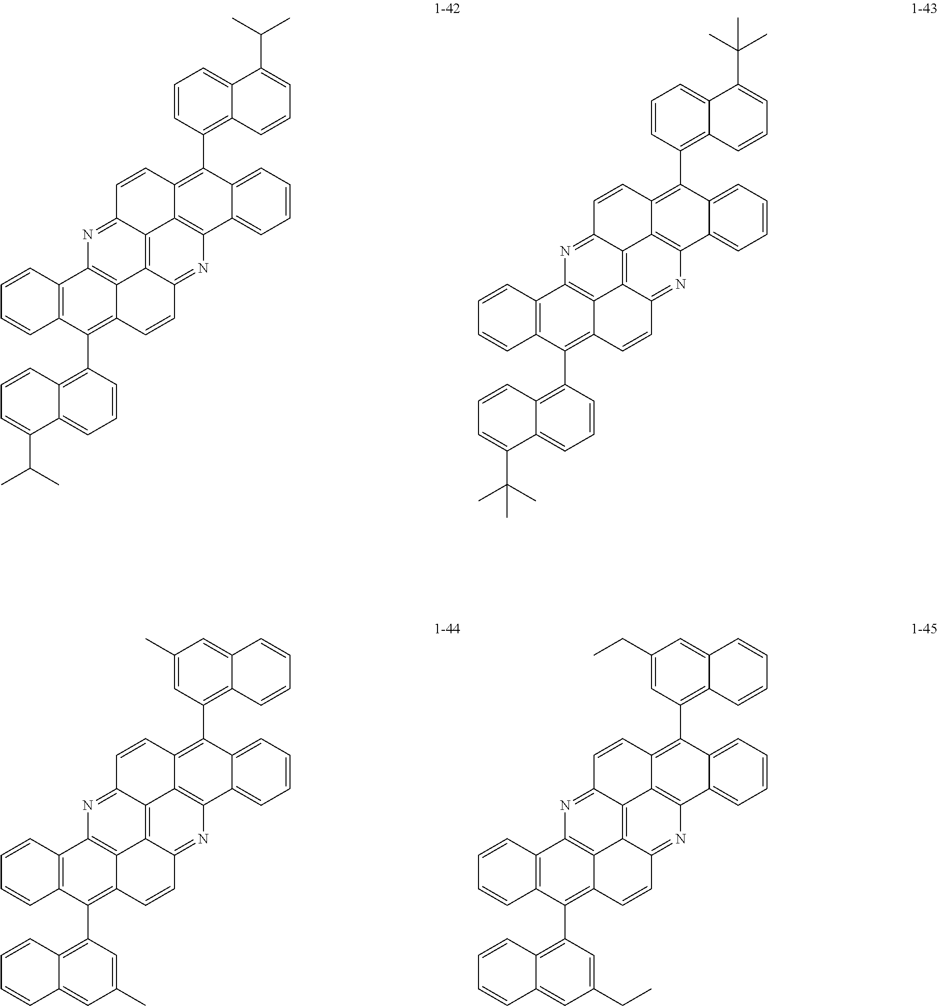 [SMILES: CC(C)c1cccc2c(-c3c4ccccc4c4nc5ccc6c(-c7cccc8c(C(C)C)cccc78)c7ccccc7c7nc8ccc3c4c8c5c67)cccc12 ; CC(C)(C)c1cccc2c(-c3c4ccccc4c4nc5ccc6c(-c7cccc8c(C(C)(C)C)cccc78)c7ccccc7c7nc8ccc3c4c8c5c67)cccc12 ; Cc1cc(-c2c3ccccc3c3nc4ccc5c(-c6cc(C)cc7ccccc67)c6ccccc6c6nc7ccc2c3c7c4c56)c2ccccc2c1 ; CCc1cc(-c2c3ccccc3c3nc4ccc5c(-c6cc(CC)cc7ccccc67)c6ccccc6c6nc7ccc2c3c7c4c56)c2ccccc2c1]

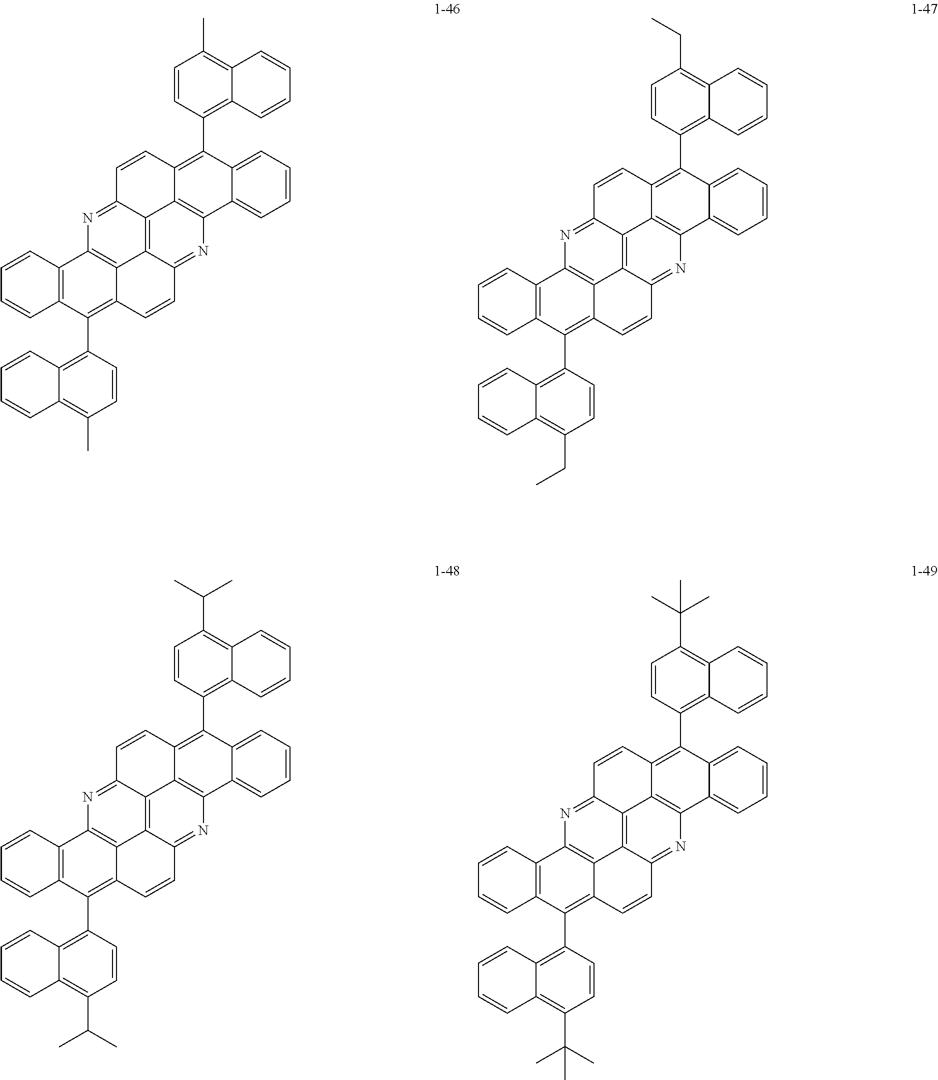 [SMILES: Cc1ccc(-c2c3ccccc3c3nc4ccc5c(-c6ccc(C)c7ccccc67)c6ccccc6c6nc7ccc2c3c7c4c56)c2ccccc12 ; CCc1ccc(-c2c3ccccc3c3nc4ccc5c(-c6ccc(CC)c7ccccc67)c6ccccc6c6nc7ccc2c3c7c4c56)c2ccccc12 ; CC(C)c1ccc(-c2c3ccccc3c3nc4ccc5c(-c6ccc(C(C)C)c7ccccc67)c6ccccc6c6nc7ccc2c3c7c4c56)c2ccccc12 ; CC(C)(C)c1ccc(-c2c3ccccc3c3nc4ccc5c(-c6ccc(C(C)(C)C)c7ccccc67)c6ccccc6c6nc7ccc2c3c7c4c56)c2ccccc12]

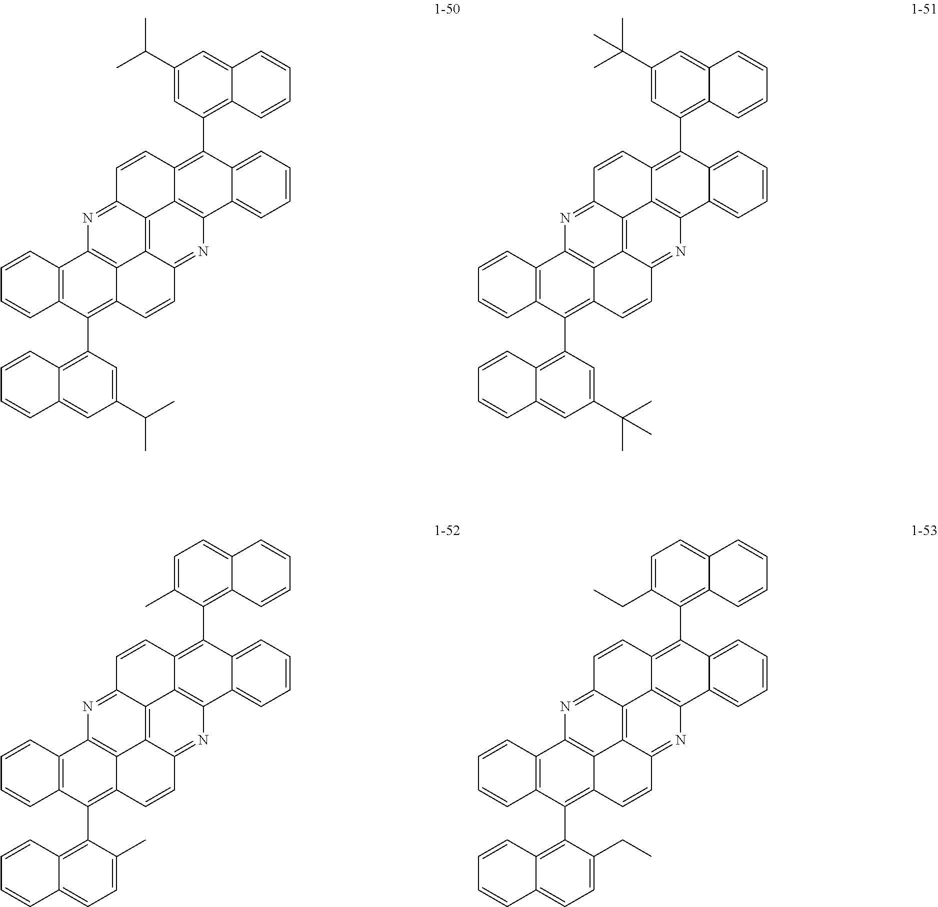 [SMILES: CC(C)c1cc(-c2c3ccccc3c3nc4ccc5c(-c6cc(C(C)C)cc7ccccc67)c6ccccc6c6nc7ccc2c3c7c4c56)c2ccccc2c1 ; CC(C)(C)c1cc(-c2c3ccccc3c3nc4ccc5c(-c6cc(C(C)(C)C)cc7ccccc67)c6ccccc6c6nc7ccc2c3c7c4c56)c2ccccc2c1 ; Cc1ccc2ccccc2c1-c1c2ccccc2c2nc3ccc4c(-c5c(C)ccc6ccccc56)c5ccccc5c5nc6ccc1c2c6c3c45 ; CCc1ccc2ccccc2c1-c1c2ccccc2c2nc3ccc4c(-c5c(CC)ccc6ccccc56)c5ccccc5c5nc6ccc1c2c6c3c45]

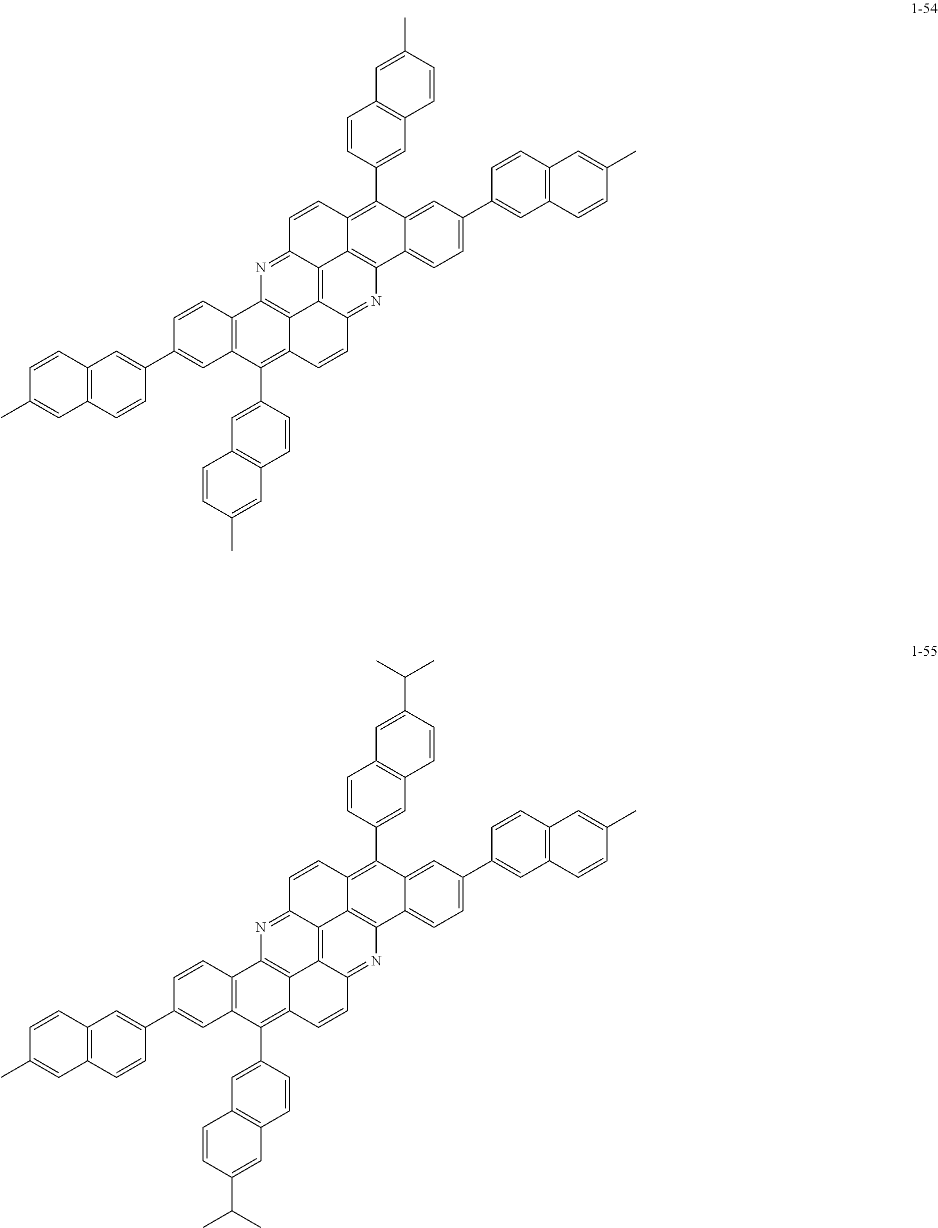

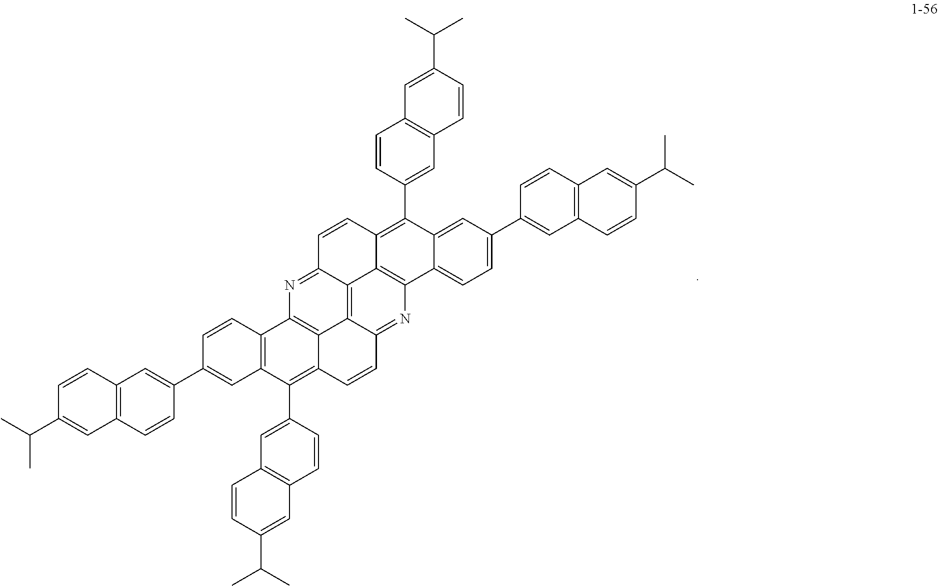 [SMILES: CC(C)c1ccc2cc(-c3ccc4c(c3)c(-c3ccc5cc(C(C)C)ccc5c3)c3ccc5nc6c7ccc(-c8ccc9cc(C(C)C)ccc9c8)cc7c(-c7ccc8cc(C(C)C)ccc8c7)c7ccc8nc4c3c5c8c76)ccc2c1]

6. The organic light emitting diode of claim 1, wherein the organometallic compound includes at least one of the following organometallic compounds:

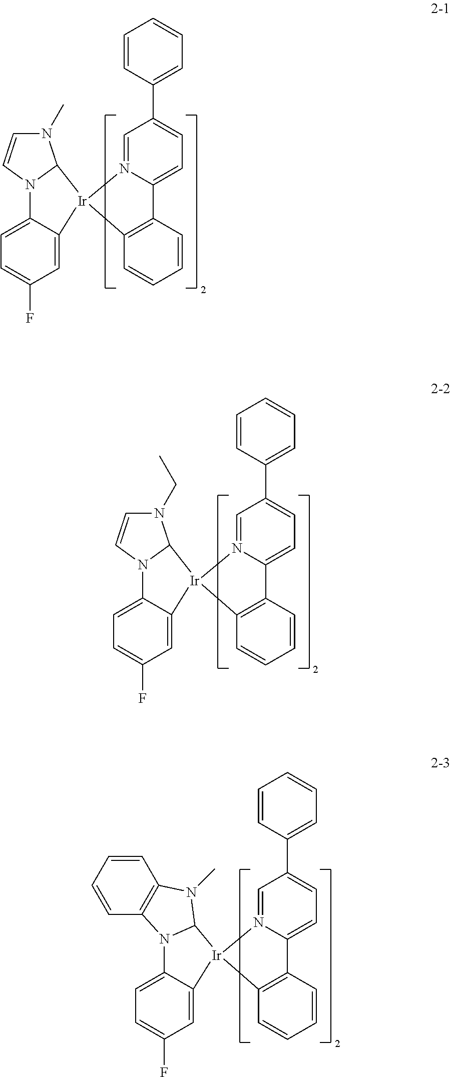

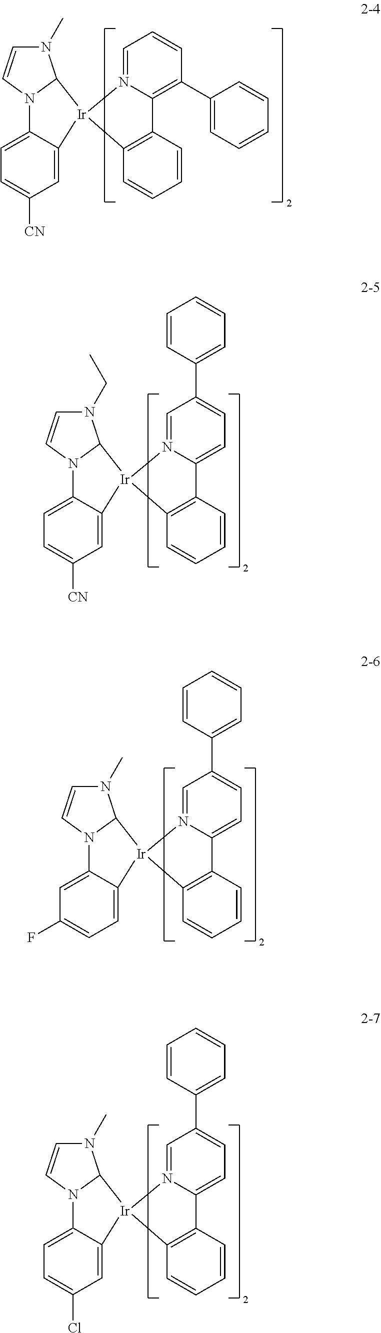

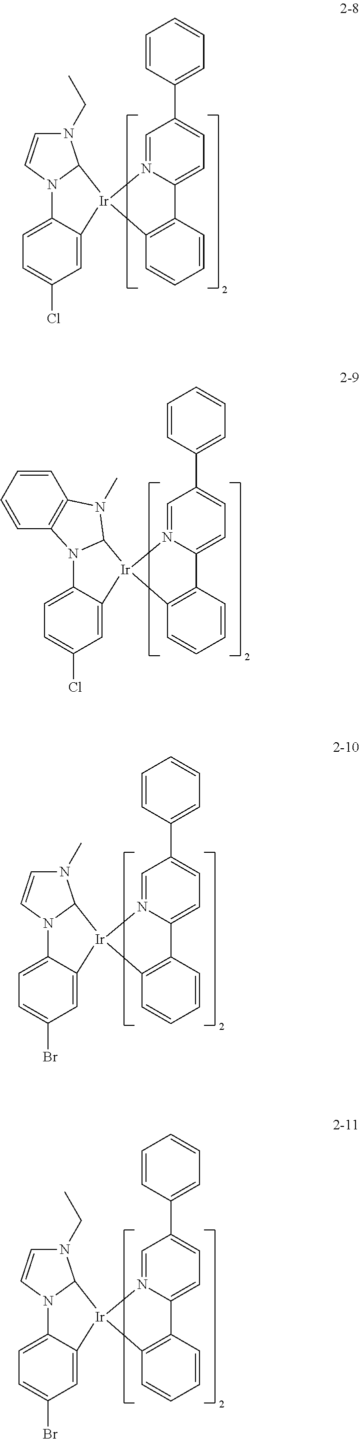

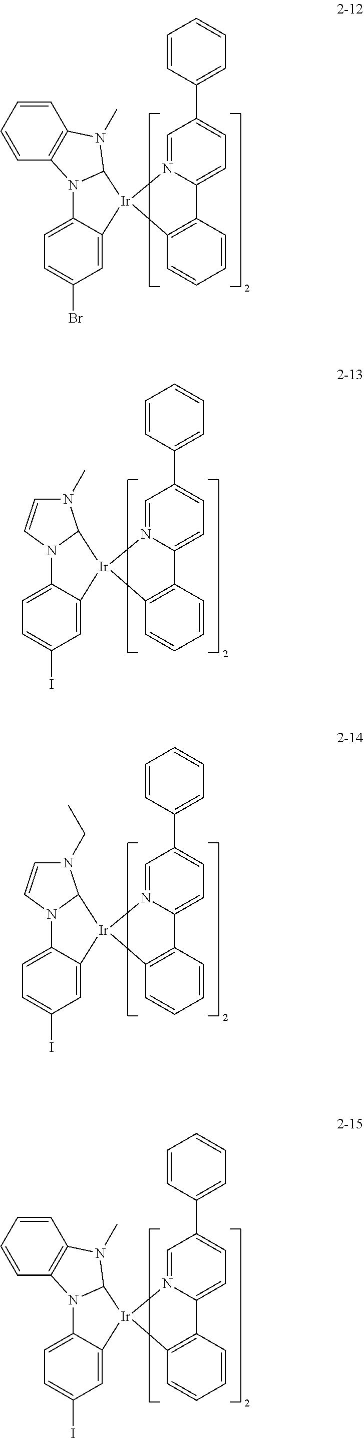

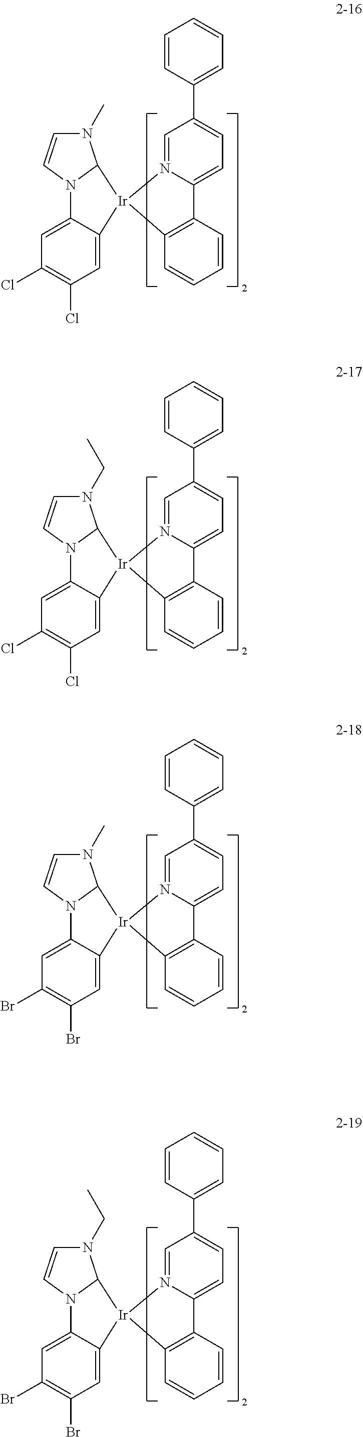

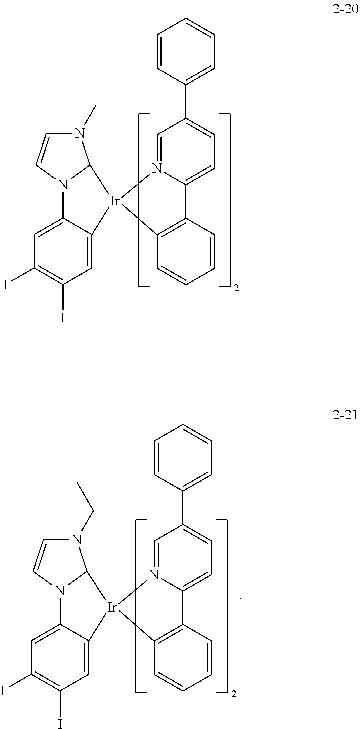

7. The organic light emitting diode of claim 1, wherein the first compound has an absorption spectrum that overlaps 30% or more of a luminescence spectrum of the second compound.

8. The organic light emitting diode of claim 1, wherein the first compound has a maximum absorption wavelength of 30 nm or less away from a maximum luminescence wavelength of the second compound.

9. The organic light emitting diode of claim 1, wherein the at least one emitting material layer further includes a third compound.

10. The organic light emitting diode of claim 9, wherein the third compound includes a second organic compound represented by Chemical Formula 6: 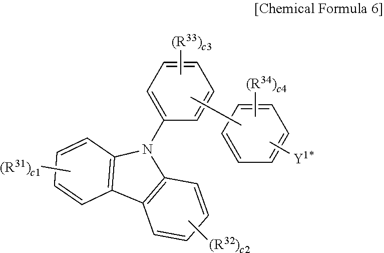
wherein, in the Chemical Formula 6,
each of R³¹ and R³² is independently an unsubstituted or substituted C₁-C₂₀ alkyl group or an unsubstituted or substituted C₆-C₃₀ aryl group, where each R³¹ is identical to or different from each other when c1 is 2, 3 or 4, and each R³² is identical to or different from each other when c2 is 2, 3 or 4;
each of R³³ and R³⁴ is independently an unsubstituted or substituted C₁-C₂₀ alkyl group or an unsubstituted or substituted C₆-C₃₀ aryl group, where each R³³ is identical to or different from each other when c3 is 2, 3 or 4 and each R³⁴ is identical to or different from each other when c4 is 2, 3 or 4, or R³³ or R³⁴ is linked to the adjacent 6-membered aromatic ring to form a heteroring that is optionally substituted with an unsubstituted or substituted C₆-C₃₀ aryl group;
Y¹ is represented by Chemical Formula 7A or Chemical Formula 7B;
each of c1, c2, c3 and c4 is independently 0, 1, 2, 3 or 4; and
an asterisk indicates a link position to the Chemical Formula 7A or Chemical Formula 7B, 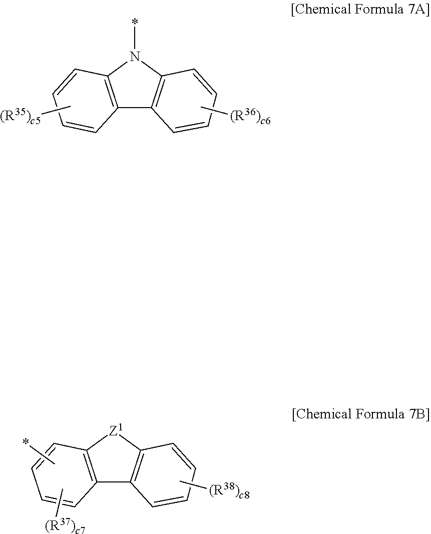
wherein, in the Chemical Formulae 7A and 7B,
each of R³⁵, R³⁶, R³⁷ and R³⁸ is independently an unsubstituted or substituted C₁-C₂₀ alkyl group or an unsubstituted or substituted C₆-C₃₀ aryl group, where each R³⁵ is identical to or different from each other when c5 is 2, 3 or 4, each R³⁶ is identical to or different from each other when c6 is 2, 3 or 4, each R³⁷ is identical to or different from each other when c7 is 2, or 3 and each R³⁸ is identical to or different from each other when c8 is 2, 3 or 4;
Z¹ is NR³⁹, O or S, where R³⁹ is hydrogen, an unsubstituted or substituted C₁-C₂₀ alkyl group or an unsubstituted or substituted C₆-C₃₀ aryl group;
each of c5, c6, and c8 is independently 0, 1, 2, 3 or 4;
c7 is 0, 1, 2 or 3; and
an asterisk indicates a link position to the Chemical Formula 6.

11. The organic light emitting diode of claim 10, wherein the second organic compound includes at least one of the following compounds:

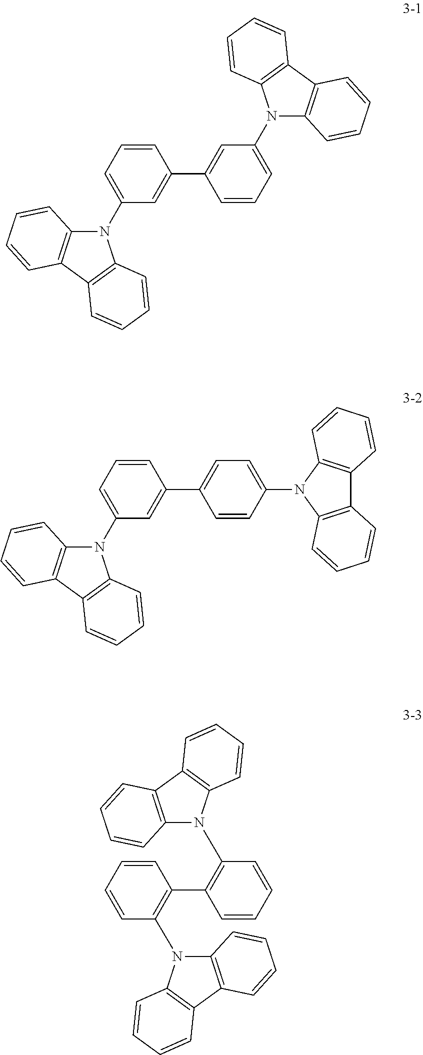 [SMILES: c1cc(-c2cccc(-n3c4ccccc4c4ccccc43)c2)cc(-n2c3ccccc3c3ccccc32)c1 ; c1cc(-c2ccc(-n3c4ccccc4c4ccccc43)cc2)cc(-n2c3ccccc3c3ccccc32)c1 ; c1ccc(-n2c3ccccc3c3ccccc32)c(-c2ccccc2-n2c3ccccc3c3ccccc32)c1]

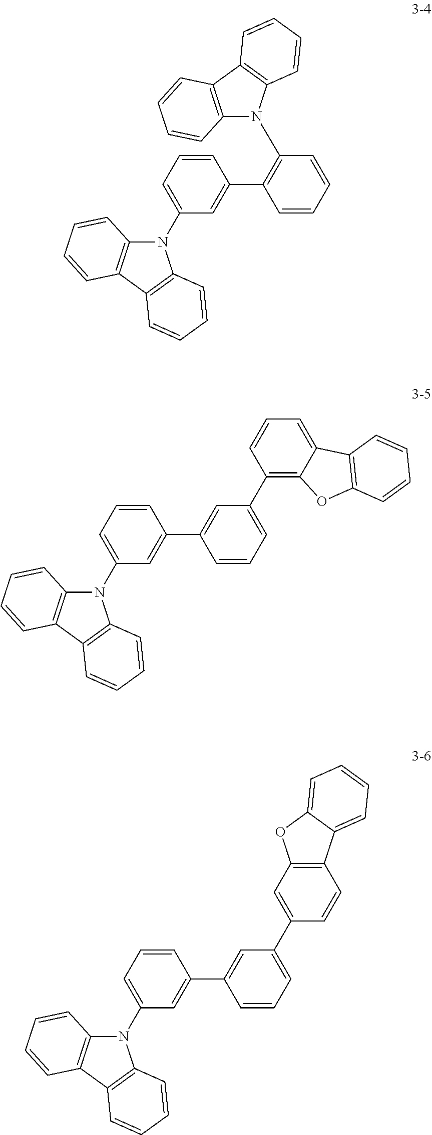 [SMILES: c1cc(-c2ccccc2-n2c3ccccc3c3ccccc32)cc(-n2c3ccccc3c3ccccc32)c1 ; c1cc(-c2cccc(-n3c4ccccc4c4ccccc43)c2)cc(-c2cccc3c2oc2ccccc23)c1 ; c1cc(-c2cccc(-n3c4ccccc4c4ccccc43)c2)cc(-c2ccc3c(c2)oc2ccccc23)c1]

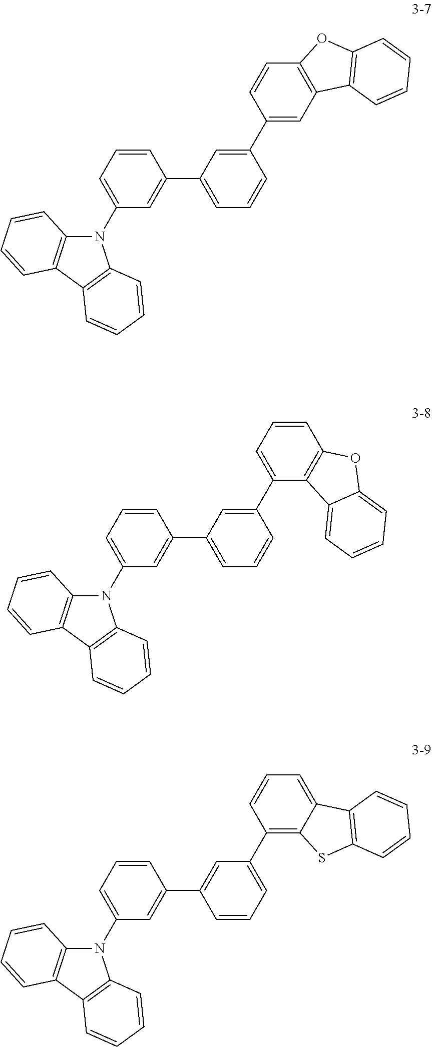 [SMILES: c1cc(-c2cccc(-n3c4ccccc4c4ccccc43)c2)cc(-c2ccc3oc4ccccc4c3c2)c1 ; c1cc(-c2cccc(-n3c4ccccc4c4ccccc43)c2)cc(-c2cccc3oc4ccccc4c23)c1 ; c1cc(-c2cccc(-n3c4ccccc4c4ccccc43)c2)cc(-c2cccc3c2sc2ccccc23)c1]

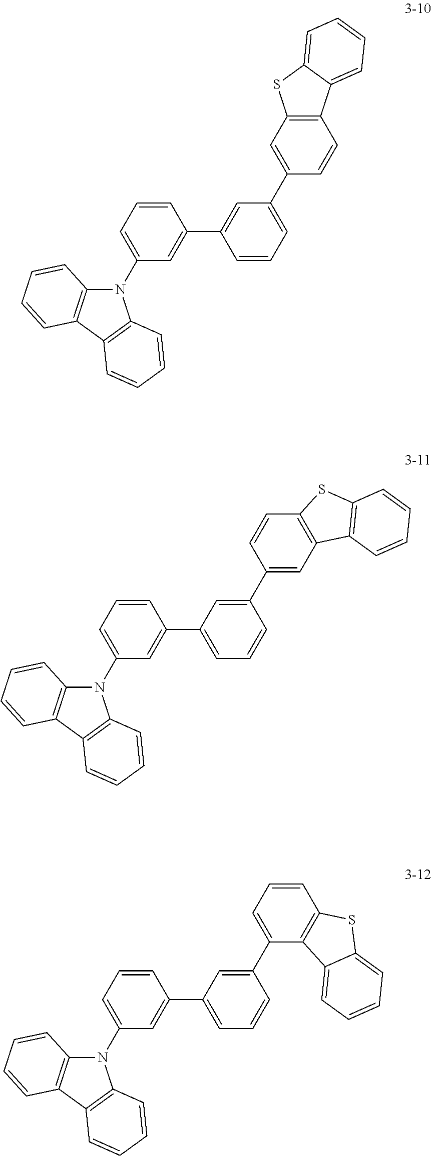 [SMILES: c1cc(-c2cccc(-n3c4ccccc4c4ccccc43)c2)cc(-c2ccc3c(c2)sc2ccccc23)c1 ; c1cc(-c2cccc(-n3c4ccccc4c4ccccc43)c2)cc(-c2ccc3sc4ccccc4c3c2)c1 ; c1cc(-c2cccc(-n3c4ccccc4c4ccccc43)c2)cc(-c2cccc3sc4ccccc4c23)c1]

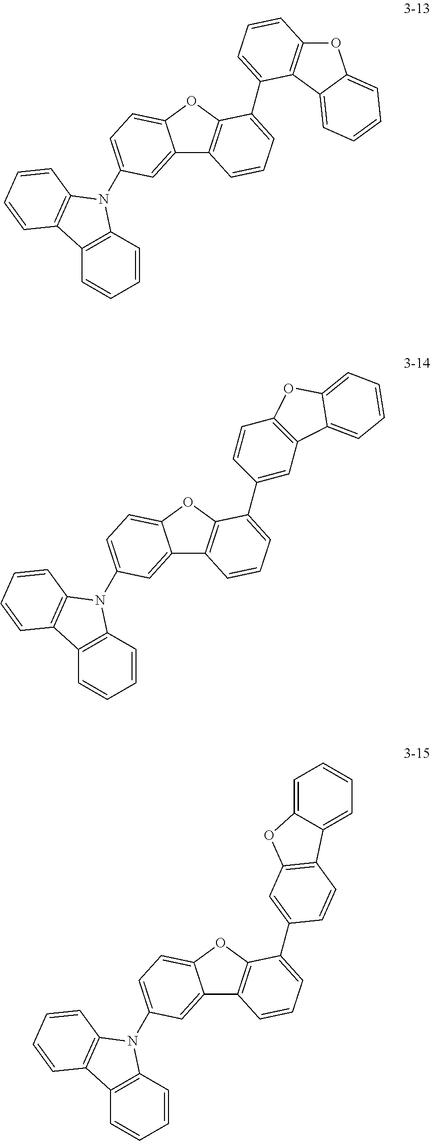 [SMILES: c1ccc2c(c1)oc1cccc(-c3cccc4c3oc3ccc(-n5c6ccccc6c6ccccc65)cc34)c12 ; c1ccc2c(c1)oc1ccc(-c3cccc4c3oc3ccc(-n5c6ccccc6c6ccccc65)cc34)cc12 ; c1ccc2c(c1)oc1cc(-c3cccc4c3oc3ccc(-n5c6ccccc6c6ccccc65)cc34)ccc12]

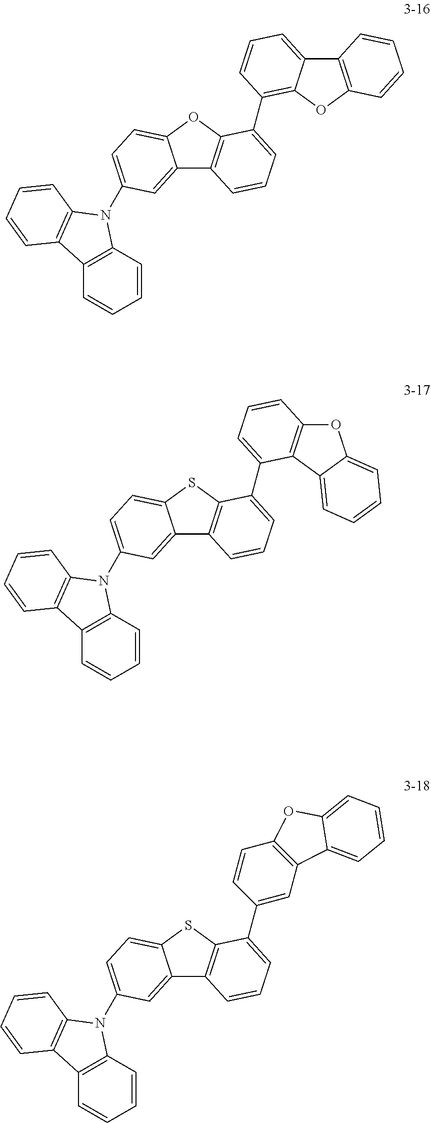 [SMILES: c1ccc2c(c1)oc1c(-c3cccc4c3oc3ccc(-n5c6ccccc6c6ccccc65)cc34)cccc12 ; c1ccc2c(c1)oc1cccc(-c3cccc4c3sc3ccc(-n5c6ccccc6c6ccccc65)cc34)c12 ; c1ccc2c(c1)oc1ccc(-c3cccc4c3sc3ccc(-n5c6ccccc6c6ccccc65)cc34)cc12]

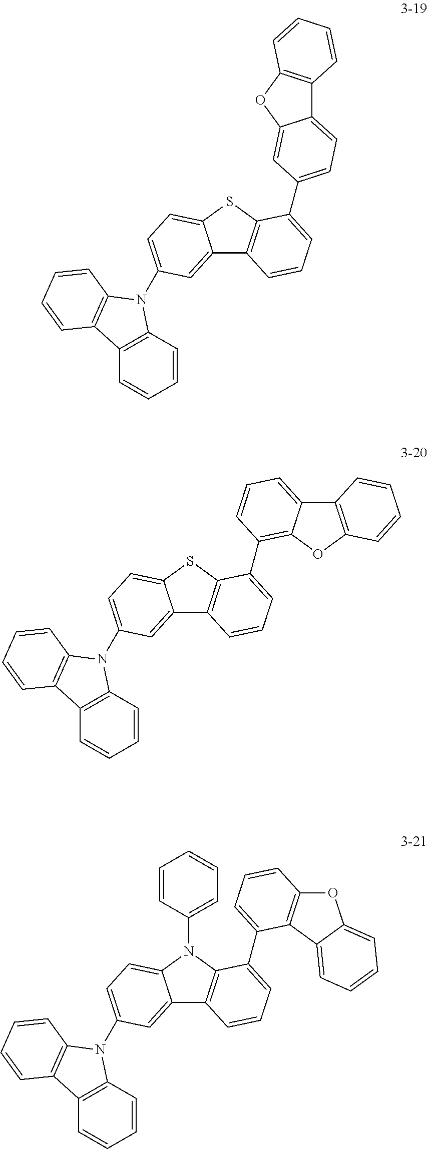 [SMILES: c1ccc2c(c1)oc1cc(-c3cccc4c3sc3ccc(-n5c6ccccc6c6ccccc65)cc34)ccc12 ; c1ccc2c(c1)oc1c(-c3cccc4c3sc3ccc(-n5c6ccccc6c6ccccc65)cc34)cccc12 ; c1ccc(-n2c3ccc(-n4c5ccccc5c5ccccc54)cc3c3cccc(-c4cccc5oc6ccccc6c45)c32)cc1]

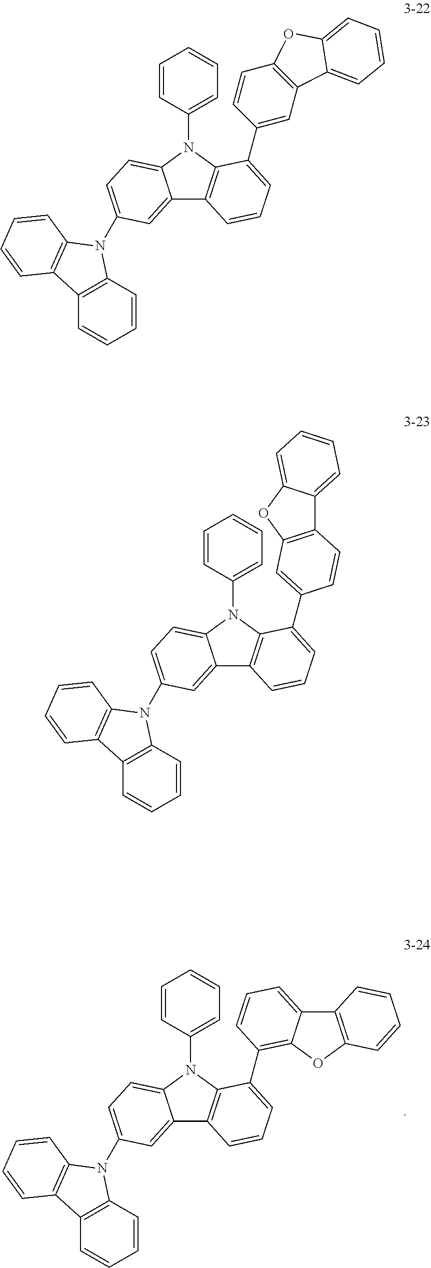 [SMILES: c1ccc(-n2c3ccc(-n4c5ccccc5c5ccccc54)cc3c3cccc(-c4ccc5oc6ccccc6c5c4)c32)cc1 ; c1ccc(-n2c3ccc(-n4c5ccccc5c5ccccc54)cc3c3cccc(-c4ccc5c(c4)oc4ccccc45)c32)cc1 ; c1ccc(-n2c3ccc(-n4c5ccccc5c5ccccc54)cc3c3cccc(-c4cccc5c4oc4ccccc45)c32)cc1]

12. The organic light emitting diode of claim 1, wherein the at least one emitting material layer further includes a fourth compound.

13. The organic light emitting diode of claim 12, wherein the fourth compound includes a third organic compound represented by Chemical Formula 9. 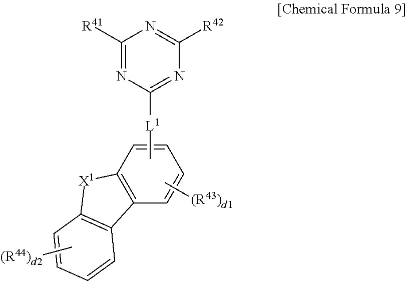
wherein, in the Chemical Formula 9,
X¹ is O or S;
each of R⁴¹, R⁴², R⁴³, and R⁴⁴ is independently an unsubstituted or substituted C₁-C₂₀ alkyl group, an unsubstituted or substituted C₁-C₂₀ alkyl amino group, an unsubstituted or substituted C₆-C₃₀ aryl group, an unsubstituted or substituted C₃-C₃₀ heteroaryl group, an unsubstituted or substituted C₆-C₃₀ aryl amino group or an unsubstituted or substituted C₃-C₃₀ heteroaryl amino group, where each R⁴³ is identical to or different from each other when d1 is 2 or 3, each R⁴⁴ is identical to or different from each other when d2 is 2, 3 or 4, or
optionally,
two adjacent R⁴³ are linked together to form an unsubstituted or substituted C₆-C₂₀ aromatic ring or an unsubstituted or substituted C₃-C₂₀ heteroaromatic ring when d1 is 2 or 3, and/or two adjacent R⁴⁴ are linked together to form an unsubstituted or substituted C₆-C₂₀ aromatic ring or an unsubstituted or substituted C₃-C₂₀ heteroaromatic ring when d2 is 2, 3 or 4;
L¹ is a single bond or an unsubstitued or substituted C₆-C₃₀ arylene group;
d1 is 0, 1, 2 or 3; and
d2 is 0, 1, 2, 3 or 4.

14. The organic light emitting diode of claim 13, wherein the third organic compound is represented by Chemical Formula 10: 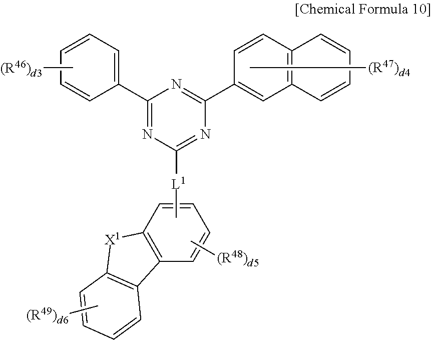
wherein, in the Chemical Formula 10,
each of X¹ and L¹ is as defined in the Chemical Formula 9;
each of R⁴⁶, R⁴⁷, R⁴⁸ and R⁴⁹ is independently an unsubstituted or substituted C₁-C₂₀ alkyl group, an unsubstituted or substituted C₆-C₃₀ aryl group or an unsubstituted or substituted C₃-C₃₀ heteroaryl group, where each R⁴⁶ is identical to or different from each other when d3 is 2, 3, 4 or 5, each R⁴⁷ is identical to or different from each other when d4 is 2, 3, 4, 5, 6 or 7, each R⁴⁸ is identical to or different from each other when d5 is 2 or 3 and each R⁴⁹ is identical to or different from each other when d6 is 2, 3 or 4, or
optionally,
two adjacent R⁴⁶ are linked together to form an unsubstituted or substituted C₆-C₂₀ aromatic ring when d3 is 2, 3, 4 or 5, and/or two adjacent R⁴⁷ are linked together to form an unsubstituted or substituted C₆-C₂₀ aromatic ring when d4 is 2, 3, 4, 5, 6 or 7;
d3 is 0, 1, 2, 3, 4 or 5;
d4 is 0, 1, 2, 3, 4, 5, 6 or 7;
d5 is 0, 1, 2 or 3; and
d6 is 0, 1, 2, 3 or 4.

15. The organic light emitting diode of claim 13, wherein the third organic compound includes at least one of the following compounds.

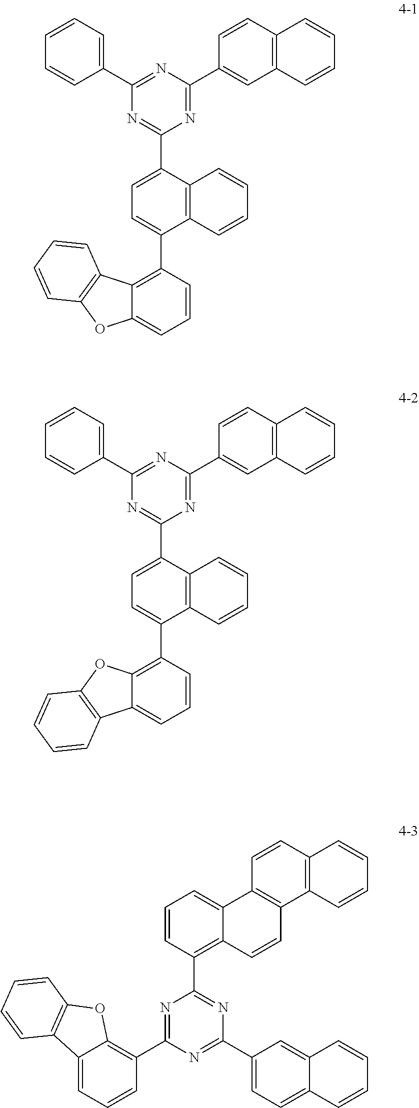 [SMILES: c1ccc(-c2nc(-c3ccc4ccccc4c3)nc(-c3ccc(-c4cccc5oc6ccccc6c45)c4ccccc34)n2)cc1 ; c1ccc(-c2nc(-c3ccc4ccccc4c3)nc(-c3ccc(-c4cccc5c4oc4ccccc45)c4ccccc34)n2)cc1 ; c1ccc2cc(-c3nc(-c4cccc5c4ccc4c6ccccc6ccc54)nc(-c4cccc5c4oc4ccccc45)n3)ccc2c1]

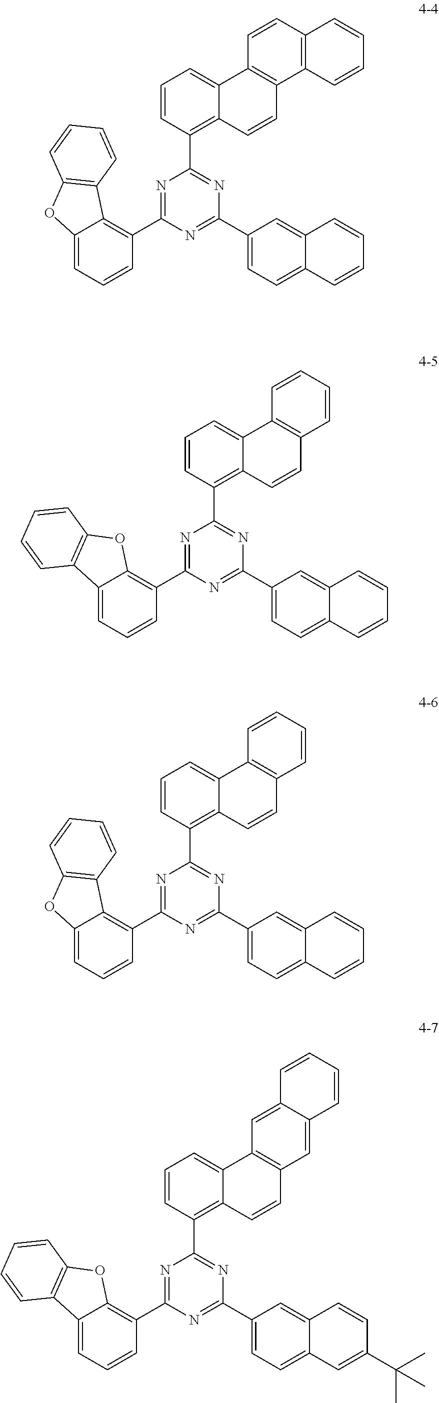 [SMILES: c1ccc2cc(-c3nc(-c4cccc5c4ccc4c6ccccc6ccc54)nc(-c4cccc5oc6ccccc6c45)n3)ccc2c1 ; c1ccc2cc(-c3nc(-c4cccc5c4ccc4ccccc45)nc(-c4cccc5c4oc4ccccc45)n3)ccc2c1 ; c1ccc2cc(-c3nc(-c4cccc5c4ccc4ccccc45)nc(-c4cccc5oc6ccccc6c45)n3)ccc2c1 ; CC(C)(C)c1ccc2cc(-c3nc(-c4cccc5c4ccc4cc6ccccc6cc45)nc(-c4cccc5c4oc4ccccc45)n3)ccc2c1]

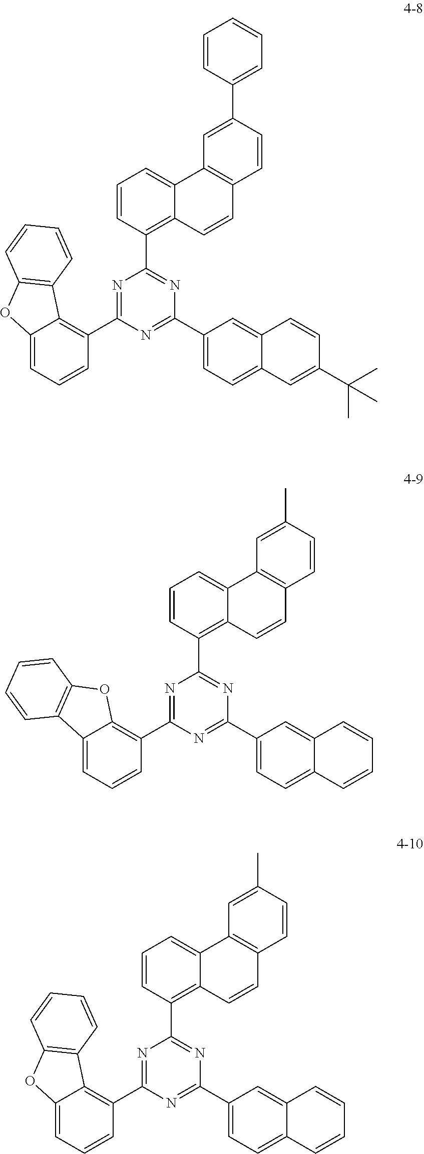 [SMILES: CC(C)(C)c1ccc2cc(-c3nc(-c4cccc5c4ccc4ccc(-c6ccccc6)cc45)nc(-c4cccc5oc6ccccc6c45)n3)ccc2c1 ; Cc1ccc2ccc3c(-c4nc(-c5ccc6ccccc6c5)nc(-c5cccc6c5oc5ccccc56)n4)cccc3c2c1 ; Cc1ccc2ccc3c(-c4nc(-c5ccc6ccccc6c5)nc(-c5cccc6oc7ccccc7c56)n4)cccc3c2c1]

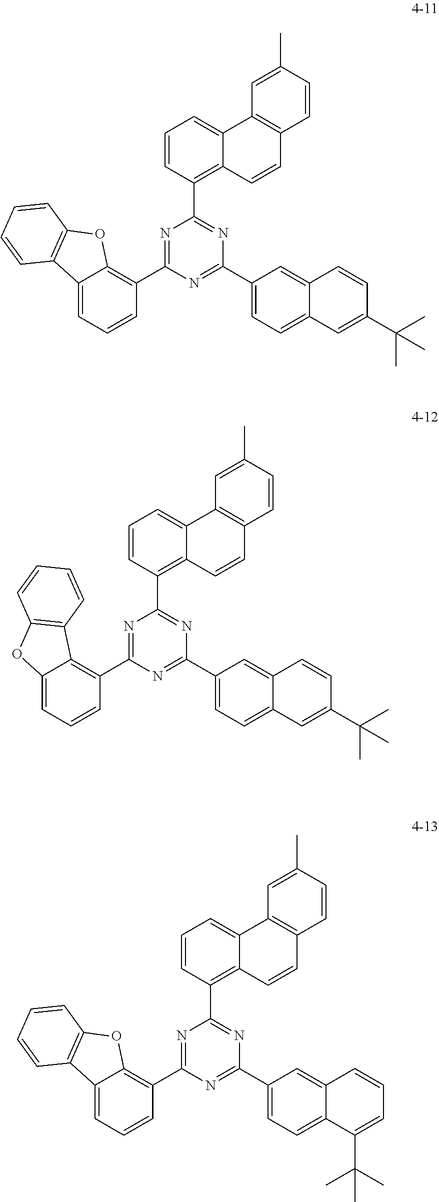 [SMILES: Cc1ccc2ccc3c(-c4nc(-c5ccc6cc(C(C)(C)C)ccc6c5)nc(-c5cccc6c5oc5ccccc56)n4)cccc3c2c1 ; Cc1ccc2ccc3c(-c4nc(-c5ccc6cc(C(C)(C)C)ccc6c5)nc(-c5cccc6oc7ccccc7c56)n4)cccc3c2c1 ; Cc1ccc2ccc3c(-c4nc(-c5ccc6c(C(C)(C)C)cccc6c5)nc(-c5cccc6c5oc5ccccc56)n4)cccc3c2c1]

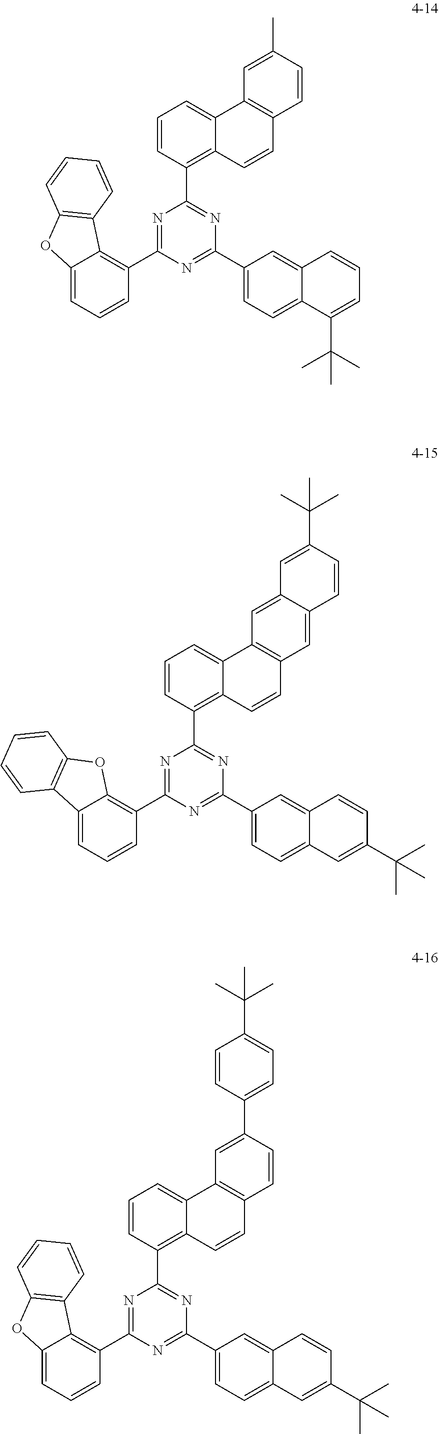 [SMILES: Cc1ccc2ccc3c(-c4nc(-c5ccc6c(C(C)(C)C)cccc6c5)nc(-c5cccc6oc7ccccc7c56)n4)cccc3c2c1 ; CC(C)(C)c1ccc2cc(-c3nc(-c4cccc5c4ccc4cc6ccc(C(C)(C)C)cc6cc45)nc(-c4cccc5c4oc4ccccc45)n3)ccc2c1 ; CC(C)(C)c1ccc(-c2ccc3ccc4c(-c5nc(-c6ccc7cc(C(C)(C)C)ccc7c6)nc(-c6cccc7oc8ccccc8c67)n5)cccc4c3c2)cc1]

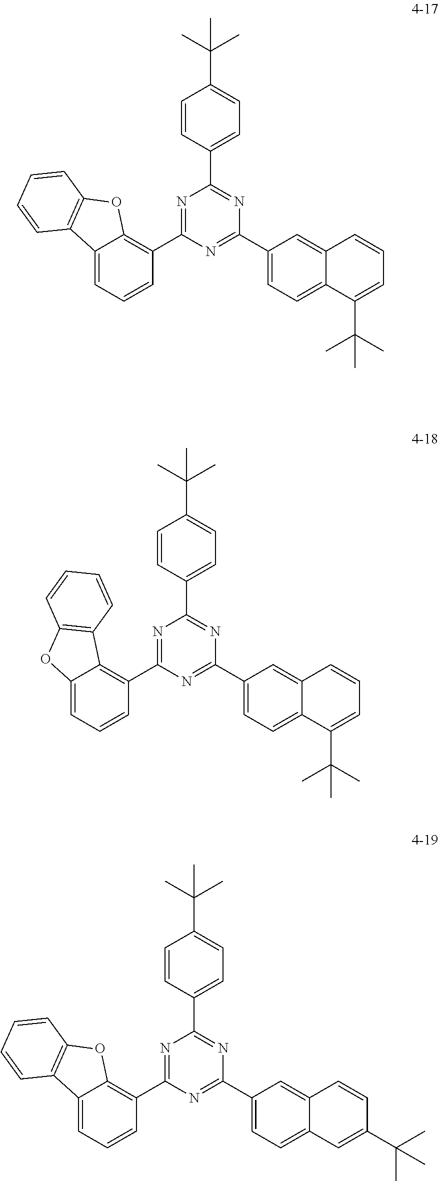 [SMILES: CC(C)(C)c1ccc(-c2nc(-c3ccc4c(C(C)(C)C)cccc4c3)nc(-c3cccc4c3oc3ccccc34)n2)cc1 ; CC(C)(C)c1ccc(-c2nc(-c3ccc4c(C(C)(C)C)cccc4c3)nc(-c3cccc4oc5ccccc5c34)n2)cc1 ; CC(C)(C)c1ccc(-c2nc(-c3ccc4cc(C(C)(C)C)ccc4c3)nc(-c3cccc4c3oc3ccccc34)n2)cc1]

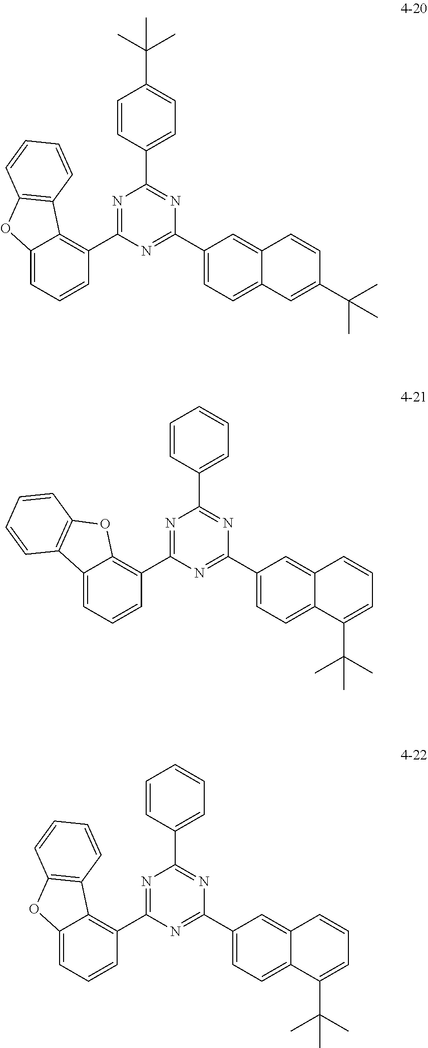 [SMILES: CC(C)(C)c1ccc(-c2nc(-c3ccc4cc(C(C)(C)C)ccc4c3)nc(-c3cccc4oc5ccccc5c34)n2)cc1 ; CC(C)(C)c1cccc2cc(-c3nc(-c4ccccc4)nc(-c4cccc5c4oc4ccccc45)n3)ccc12 ; CC(C)(C)c1cccc2cc(-c3nc(-c4ccccc4)nc(-c4cccc5oc6ccccc6c45)n3)ccc12]

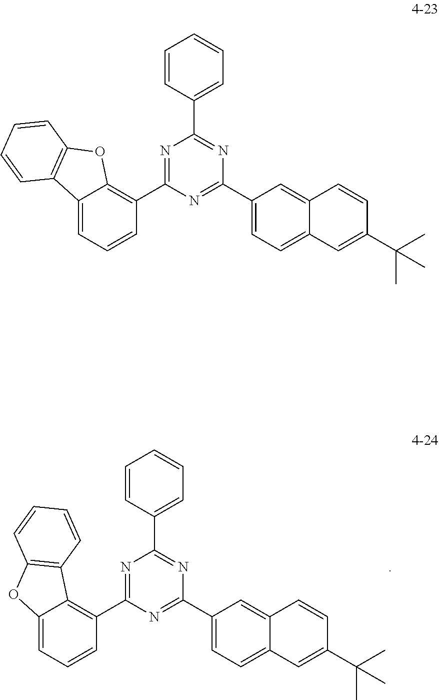 [SMILES: CC(C)(C)c1ccc2cc(-c3nc(-c4ccccc4)nc(-c4cccc5c4oc4ccccc45)n3)ccc2c1 ; CC(C)(C)c1ccc2cc(-c3nc(-c4ccccc4)nc(-c4cccc5oc6ccccc6c45)n3)ccc2c1]

16. The organic light emitting diode of claim 1, wherein the emissive layer has a single emitting part.

17. The organic light emitting diode of claim 1, wherein the emissive layer comprises:
a first emitting part disposed between the first and second electrodes and including a first emitting material layer;
a second emitting part disposed between the first emitting part and the second electrode and including a second emitting material layer; and
a first charge generation layer disposed between the first emitting part and the second emitting part,
wherein at least one of the first emitting material layer and the second emitting material layer includes the first compound and the second compound.

18. The organic light emitting diode of claim 17, wherein the second emitting material layer is the at least one emitting material layer, and the second emitting material layer includes:
a first layer disposed between the first charge generation layer and the second electrode; and
a second layer disposed between the first layer and the second electrode,
wherein at least one of the first layer and the second layer includes the first compound and the second compound.

19. The organic light emitting diode of claim 17, wherein the emissive layer further includes:
a third emitting part disposed between the second emitting part and the second electrode and including a third emitting material layer; and
a second charge generation layer disposed between the second emitting part and the third emitting part,
wherein the second emitting material layer includes the first compound and the second compound.

20. The organic light emitting diode of claim 19, wherein the second emitting material layer is the at least one emitting material layer, and the second emitting material layer includes:
a first layer disposed between the first charge generation layer and the second charge generation layer; and
a second layer disposed between the first layer and the second charge generation layer,
wherein at least one of the first layer and the second layer includes the first compound and the second compound.

21. The organic light emitting diode of claim 20, wherein the first layer includes the first compound.
